(19) United States
(12) Patent Application Publication
(10) Pub. No.: US 2026/0011695 A1
(43) Pub. Date: Jan. 8, 2026

(54) ISOLATION CHIP AND SIGNAL TRANSMISSION DEVICE

(71) Applicant: ROHM CO., LTD., Kyoto-shi (JP)

(72) Inventors: Junichi SEKITO, Kyoto-shi (JP); Koji SAITO, Kyoto-shi (JP)

(21) Appl. No.: 19/324,252

(22) Filed: Sep. 10, 2025

Related U.S. Application Data
(63) Continuation of application No. PCT/JP2024/005817, filed on Feb. 19, 2024.

(30) Foreign Application Priority Data
Mar. 17, 2023 (JP) 2023-043192

(51) Int. Cl. H01L 25/07; H01L 23/495; H10D 1/20

(52) U.S. Cl. CPC H01L 25/072; H01L 23/49575; H10D 1/20

(57) ABSTRACT

This insulating chip comprises: an insulating layer; a first coil and a second coil disposed in the insulating layer; and a second electrode electrically connected to the second coil. The second coil has an annular shape in a plan view as seen from the Z direction. The second electrode includes a second inner electrode that is disposed, when viewed in the plan view, over both an inner region surrounded by the second coil and a region overlapping the second coil. A passivation film formed on the upper surface of the insulating layer includes a second inner opening that exposes at least a portion of the second inner electrode. The second inner opening is formed at a position that is over the second inner electrode, and is over both the inner region and the region overlapping the second coil.

### CROSS-REFERENCE TO RELATED APPLICATIONS

This is the U.S. national stage of No. PCT/JP2024/005817, filed on Feb. 19, 2024, which is incorporated herein by reference, and which claims the benefit of priority from Japanese Patent Application No. 2023-043192, filed on Mar. 17, 2023. The present application likewise claims priority under 35 U.S.C. § 119 to Japanese Application No. 2023-043192, filed Mar. 17, 2023, the entire content of which is also incorporated herein by reference.

### BACKGROUND

### 1. Field

The present disclosure relates to an isolation chip and a signal transmission device.

### 2. Description of Related Art

A conventional signal transmission device is used for various applications such as a power supply device and a motor drive device and transmits pulse signals while electrically isolating the input and the output. A known example of a signal transmission device is an isolated gate driver that applies a gate voltage to the gate of a switching element such as a transistor. JP2018-78169A describes a known example of an isolation chip used for such a gate driver. The isolation chip includes a first coil and a second coil arranged in an element insulation layer facing each other in the thickness-wise direction of the element insulation layer.

### BRIEF DESCRIPTION OF THE DRAWINGS

FIG. 1 is a schematic circuit diagram showing the configuration of a signal transmission device in accordance with an embodiment.

FIG. 2 is a schematic plan view showing the configuration of the signal transmission device shown in FIG. 1.

FIG. 3 is a schematic cross-sectional view showing the configuration of the signal transmission device shown in FIG. 2.

FIG. 4 is a schematic perspective view of the isolation chip shown in FIG. 2.

FIG. 5 is a schematic plan view of the isolation chip shown in FIG. 4.

FIG. 6 is an enlarged schematic plan view showing a portion of the isolation chip shown in FIG. 5.

FIG. 7 is a schematic plan view of first coils of the isolation chip shown in FIG. 5.

FIG. 8 is a schematic plan view of second coils of the isolation chip shown in FIG. 5.

FIG. 9 is a schematic cross-sectional view of the isolation chip taken along line 9-9 in FIG. 5.

FIG. 10 is a schematic cross-sectional view of the isolation chip taken along line 10-10 in FIG. 5.

FIG. 11 is an enlarged schematic plan view showing a portion of the isolation chip shown in FIG. 5.

FIG. 12 is a schematic cross-sectional view of the isolation chip taken along line 12-12 in FIG. 11.

FIG. 13 is a schematic plan view showing the configuration of a first circuit chip shown in FIG. 2.

FIG. 14 is a block diagram showing an exemplary configuration of a reception circuit in the signal transmission device shown in FIG. 1.

FIG. 15 is a block diagram showing an exemplary configuration of the reception circuit shown in FIG. 14.

FIG. 16 is a circuit diagram showing an exemplary configuration of a nonlinear amplifier and an envelope detection circuit shown in FIG. 15.

FIG. 17 is a schematic diagram used to illustrate inspection of the isolation chip shown in FIG. 5.

FIG. 18 is an enlarged schematic plan view showing a portion of an isolation chip in a modified example.

FIG. 19 is a schematic enlarged cross-sectional view showing a portion of the isolation chip taken along line 19-19 in FIG. 18.

FIG. 20 is an enlarged schematic plan view showing a portion of an isolation chip in a modified example.

FIG. 21 is a schematic enlarged cross-sectional view showing a portion of the isolation chip taken along line 21-21 in FIG. 20.

FIG. 22 is an enlarged schematic plan view showing a portion of an isolation chip in a modified example.

FIG. 23 is a schematic enlarged cross-sectional view showing a portion of the isolation chip taken along line 23-23 in FIG. 22.

FIG. 24 is an enlarged schematic plan view showing a portion of an isolation chip in a modified example.

FIG. 25 is a schematic enlarged cross-sectional view showing a portion of the isolation chip taken along line 25-25 in FIG. 24.

FIG. 26 is an enlarged schematic plan view showing a portion of an isolation chip in a modified example.

FIG. 27 is a schematic enlarged cross-sectional view showing a portion of the isolation chip taken along line 27-27 in FIG. 26.

FIG. 28 is an enlarged schematic plan view showing a portion of an isolation chip in a modified example.

FIG. 29 is an enlarged schematic plan view showing a portion of an isolation chip in a modified example.

FIG. 30 is an enlarged schematic plan view showing a portion of an isolation chip in a modified example.

FIG. 31 is an enlarged schematic plan view showing a portion of an isolation chip in a modified example.

FIG. 32 is an enlarged schematic plan view showing a portion of an isolation chip in a modified example.

FIG. 33 is a schematic cross-sectional view of an isolation chip in a modified example.

FIG. 34 is a block diagram showing a reception circuit of a signal transmission device in a modified example.

FIG. 35 is a block diagram showing an exemplary configuration of the reception circuit shown in FIG. 34.

FIG. 36 is a circuit diagram showing an exemplary configuration of an envelope detection circuit and an addition circuit shown in FIG. 35.

FIG. 37 is a waveform diagram showing actions of a signal transmission device shown in FIG. 34.

FIG. 38 is a circuit diagram showing an exemplary configuration of a high-pass filter and a DC bias circuit.

FIG. 39 is a circuit diagram showing a circuit equivalent to a high-pass filter.

FIG. 40 is a diagram showing the characteristics of output impedance of a buffer.

FIG. 41 is a waveform diagram showing an adding process of an addition circuit in a modified example.

FIG. 42 is a schematic plan view showing the configuration of a signal transmission device in a modified example.

FIG. 43 is a schematic circuit diagram showing the configuration of a signal transmission device in a modified example.

FIG. 44 is a schematic plan view showing the configuration of the signal transmission device shown in FIG. 43.

FIG. 45 is a schematic plan view showing the configuration of a signal transmission device in a modified example.

FIG. 46 is a schematic plan view showing the configuration of a signal transmission device in a modified example.

FIG. 47 is a schematic plan view showing the configuration of a signal transmission device in a modified example.

### DETAILED DESCRIPTION

Embodiments of an isolation chip, a semiconductor device, and a signal transmission device according to the present disclosure will be described below with reference to the drawings. In the drawings, components may not be drawn to scale for simplicity and clarity of illustration. To aid understanding, hatching lines may not be shown in the cross-sectional drawings. The accompanying drawings illustrate exemplary embodiments in accordance with the present disclosure and are not intended to limit the present disclosure. Terms such as “first,” “second,” and “third” in this disclosure are used to distinguish subjects and not used for ordinal purposes.

The following detailed description includes exemplary embodiments of a device, a system, and a method according to the present disclosure. The detailed description is illustrative and is not intended to limit embodiments of the present disclosure or the application and use of the embodiments.

The phrase “at least one of” as used in this disclosure means “one or more” of a desired choice. As one example, the phrase “at least one of” as used in this disclosure means “only one of the two choices” or “both of the two choices” in a case where the number of choices is two. In another example, the phrase “at least one of” as used in this description means “only one single option” or “any combination of two or more options” if the number of options is three or more.

### Embodiment

### Schematic Configuration of Signal Transmission Device

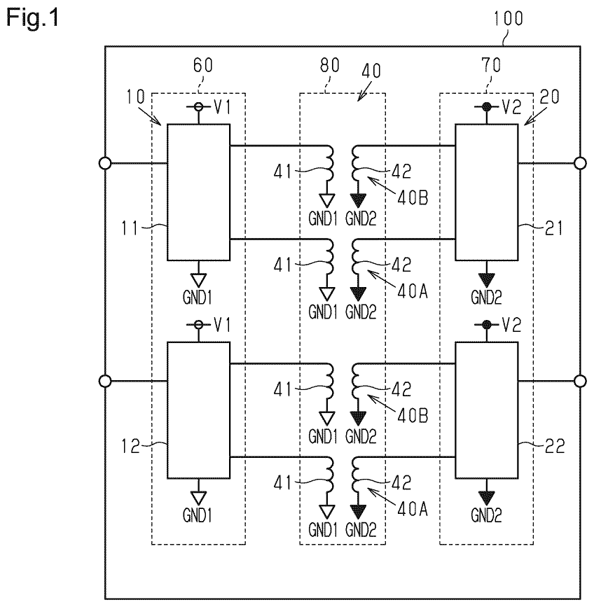

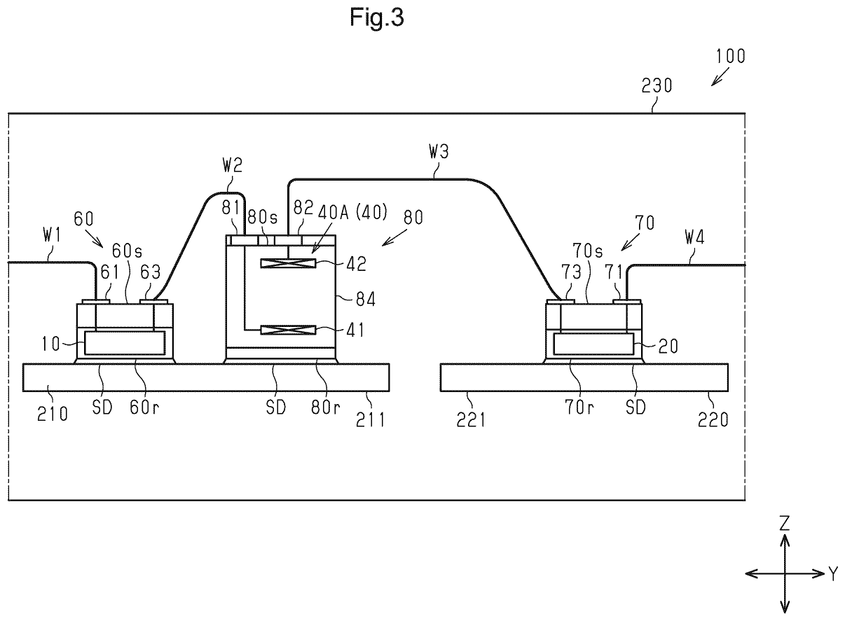

The schematic configuration of a signal transmission device 100 will now be described with reference to FIG. 1 and FIG. 3.

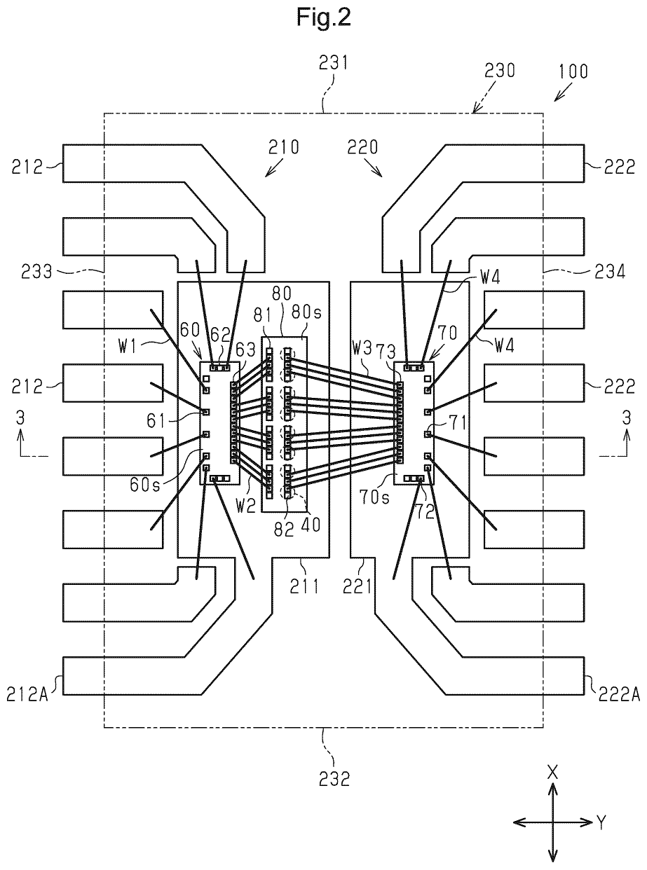

FIG. 1 is a schematic diagram showing a circuit configuration of the signal transmission device 100. FIG. 2 is a schematic diagram showing an example of the internal configuration (planar structure) of the signal transmission device 100. FIG. 3 is a schematic diagram showing an example of the internal configuration (cross-sectional structure) of the signal transmission device 100. To simplify illustration, FIG. 3 does not show hatching lines.

As shown in FIG. 1, the signal transmission device 100 includes a first circuit chip 60, a second circuit chip 70, and an isolation chip 80. The isolation chip 80 is connected between the first circuit chip 60 and the second circuit chip 70. The isolation chip 80 electrically isolates the first circuit chip 60 and the second circuit chip 70.

The first circuit chip 60 includes a first circuit 10 configured to be activated by a first voltage V1. In an example, the first circuit 10 includes a transmission circuit 11 and a reception circuit 12. The second circuit chip 70 includes a second circuit 20 configured to be activated by a second voltage V2. In an example, the second circuit 20 includes a reception circuit 21 and a transmission circuit 22. The first voltage V1 may be equal to or different from the second voltage V2. In an example, the second voltage V2 is equal to the first voltage V1. In an example, the first circuit chip 60 has the same configuration as the second circuit chip 70. The first circuit chip 60 and the second circuit chip 70 may each be referred to as a controller chip. The signal transmission device 100 may be referred to as a digital isolator.

The isolation chip 80 includes multiple transformers 40. The multiple transformers 40 include a first transformer 40A and a second transformer 40B that are connected to the transmission circuit 11 of the first circuit 10, and a third transformer 40A and a fourth transformer 40B connected to the reception circuit 12 of the first circuit 10. The first transformer 40A and the second transformer 40B are electrically connected between the transmission circuit 11 of the first circuit chip 60 and the reception circuit 21 of the second circuit chip 70. The third transformer 40A and the fourth transformer 40B are electrically connected between the reception circuit 12 of the first circuit chip 60 and the transmission circuit 22 of the second circuit chip 70.

The first to fourth transformers 40A and 40B each include a first coil 41 and a second coil 42. The first coils 41 of the first transformer 40A and the second transformer 40B are electrically connected to the transmission circuit 11 of the first circuit chip 60. The second coils 42 of the first transformer 40A and the second transformer 40B are electrically connected to the reception circuit 21 of the second circuit chip 70. The first coils 41 of the third transformer 40A and the fourth transformer 40B are electrically connected to the reception circuit 12 of the first circuit chip 60. The second coils 42 of the third transformer 40A and the fourth transformer 40B are electrically connected to the transmission circuit 22 of the second circuit chip 70.

When receiving an input signal, the transmission circuit 11 of the first circuit chip 60 applies pulsed drive to the first coil 41 of at least one of the first transformer 40A and the second transformer 40B. When receiving a signal excited by the second coil 42 of at least one of the first transformer 40A and the second transformer 40B, the reception circuit 21 of the second circuit chip 70 outputs an output signal. When receiving an input signal, the transmission circuit 22 of the second circuit chip 70 applies pulsed drive to the second coil 42 of at least one of the third transformer 40A and the fourth transformer 40B. When receiving a signal excited by the first coil 41 of at least one of the third transformer 40A and the fourth transformer 40B, the reception circuit 12 of the first circuit chip 60 outputs an output signal.

FIG. 2 shows an example of the internal structure of the signal transmission device 100. In FIG. 2, the circuit configuration of the signal transmission device 100 is simplified. Thus, the number of external terminals of the signal transmission device 100 shown in FIG. 2 is greater than the number of external terminals of the signal transmission device 100 shown in FIG. 1. The external terminals of the signal transmission device 100 include a connection terminal configured to connect an electronic component disposed outside the signal transmission device 100, and a power supply terminal configured to supply a power voltage to the first circuit chip 60 and the second circuit chip 70 of the signal transmission device 100. The external terminals may include a terminal configured not to be connected to an external component. FIG. 3 is an example of a cross-sectional view showing the internal configuration of the signal transmission device 100. FIG. 3 is a simplified cross-sectional view showing the internal configuration of the signal transmission device 100. The cross-sectional structure of each of the chips 60, 70, and 80 is simplified in the drawing. Thus, the cross-sectional structure of the isolation chip 80 shown in FIG. 3 differs from the cross-sectional structure of the isolation chip 80 described below.

As shown in FIG. 2, the signal transmission device 100 is a semiconductor device in which the first circuit chip 60, the second circuit chip 70, and the isolation chip 80 are arranged in two packages.

The package type of the signal transmission device 100 is small outline (SO). In an example, the signal transmission device 100 is a small outline package (SOP). The package type of the signal transmission device 100 may be changed in any manner. The package type is not limited to SOP and may be a quad for non lead package (QFN), a dual flat package (DFP), a dual inline package (DIP), a quad flat package (QFP), a single inline package (SIP), a small outline j-leaded package (SOJ), or other similar package structures.

The first circuit chip 60 is mounted on a first support member 210. The second circuit chip 70 is mounted on a second support member 220. In an example, the isolation chip 80 is mounted on the first support member 210. An encapsulation resin 230 encapsulates a portion of the first support member 210, a portion of the second support member 220, and the chips 60, 70, and 80. In FIG. 2, the encapsulation resin 230 is indicated by double-dashed lines to illustrate the internal structure of the signal transmission device 100.

The encapsulation resin 230 is formed from an electrical insulating material. An example of the resin includes an epoxy resin. The resin may be colored black. The encapsulation resin 230 has the form of a rectangular shape having a thickness-wise direction aligned with a Z-direction. The encapsulation resin 230 includes four resin side surfaces 231 to 234. More specifically, the resin side surfaces 231 and 232 are two end surfaces of the encapsulation resin 230 in an X-direction. The resin side surfaces 233 and 234 are two end surfaces of the encapsulation resin 230 in a Y-direction. The X-direction and the Y-direction are orthogonal to the Z-direction. The X-direction and the Y-direction are orthogonal to each other. The X-direction corresponds to a “first direction.” The Y-direction corresponds to a “second direction.” In the description hereafter, a plan view means a view in the Z-direction.

The first support member 210 and the second support member 220 are each electrically conductive. The first support member 210 and the second support member 220 are formed of a material including copper (Cu), iron (Fe), or the like. The support members 210 and 220 each extend from the inside to the outside of the encapsulation resin 230.

The first support member 210 includes a first die pad 211 disposed in the encapsulation resin 230 and multiple first lead terminals 212 extending from the inside to the outside of the encapsulation resin 230.

The first circuit chip 60 and the isolation chip 80 are mounted on the first die pad 211. In plan view, the first die pad 211 is arranged so that the center of the first die pad 211 in the Y-direction is located closer to the resin side surface 233 than the center of the encapsulation resin 230 in the Y-direction is. The first die pad 211 is not exposed from the encapsulation resin 230. In plan view, the first die pad 211 is rectangular so that the long sides extend in the X-direction and the short sides extend in the Y-direction.

The first lead terminals 212 are separated from each other in the X-direction. The first lead terminals 212 include a first lead terminal 212A integrated with the first die pad 211. Each of the first lead terminals 212 partially projects from the resin side surface 233 toward the outside of the encapsulation resin 230.

The second support member 220 includes a second die pad 221 disposed in the encapsulation resin 230 and multiple second lead terminals 222 extending from the inside to the outside of the encapsulation resin 230.

The second circuit chip 70 is mounted on the second die pad 221. In plan view, the second die pad 221 is located closer in the Y-direction to the resin side surface 234 than the first die pad 211 is. The second die pad 221 is not exposed from the encapsulation resin 230. In plan view, the second die pad 221 is rectangular so that the long sides extend in the X-direction and the short sides extend in the Y-direction.

The first die pad 211 and the second die pad 221 are separated from each other in the Y-direction. Thus, the Y-direction may be referred to as the arrangement direction of the die pads 211 and 221.

The dimension of the first die pad 211 and the second die pad 221 in the Y-direction is set in accordance with the size and the number of semiconductor chips that are mounted. The first circuit chip 60 and the isolation chip 80 are mounted on the first die pad 211. The second circuit chip 70 is mounted on the second die pad 221. Thus, the dimension of the first die pad 211 in the Y-direction is greater than the dimension of the second die pad 221 in the Y-direction.

The second lead terminals 222 are separated from each other in the X-direction. The second lead terminals 222 include a second lead terminal 222A integrated with the second die pad 221. Each of the second lead terminals 222 partially projects from the resin side surface 234 toward the outside of the encapsulation resin 230.

The second lead terminals 222 are equal in number to the first lead terminals 212. As shown in FIG. 2, the first lead terminals 212 and the second lead terminals 222 are arranged in a direction (the X-direction) orthogonal to the arrangement direction (the Y-direction) of the first die pad 211 and the second die pad 221. The number of the second lead terminals 222 and the number of the first lead terminals 212 may be changed in any manner.

The first support member 210 and the second support member 220 are each formed of a lead frame. In a manufacturing process of the signal transmission device 100, the first die pad 211, the first lead terminals 212, the second die pad 221, and the second lead terminals 222 are formed of the same lead frame.

The lead frame includes an outer frame surrounding the first support member 210 and the second support member 220. The first lead terminals 212 and the second lead terminals 222 are joined to the outer frame. In the manufacturing process of the signal transmission device 100, the first lead terminals 212 and the second lead terminals 222 are separated from the outer frame.

The first die pad 211 is connected to the first lead terminal 212A, which is one of the first lead terminals 212. The first die pad 211 and the first lead terminal 212A are formed integrally as an integrated structure. The first die pad 211 is supported by the first lead terminal 212A. The second die pad 221 is connected to the second lead terminal 222A, which is one of the second lead terminals 222. The second die pad 221 and the second lead terminal 222A are formed integrally as an integrated structure. The second die pad 221 is supported by the second lead terminal 222A. Hence, the die pads 211 and 221 are not provided with a suspension lead exposed from the resin side surfaces 231 and 232. This increases the insulation distance (creepage distance) between the first support member 210 and the second support member 220.

In addition, since the first die pad 211 is supported by a single first lead terminal 212A, the other first lead terminals 212 may be used as terminals that input or output a signal. Also, since the second die pad 221 is supported by a single second lead terminal 222A, the other second lead terminals 222 may be used as terminals that input or output a signal.

The first circuit chip 60, the second circuit chip 70, and the isolation chip 80 are separated from each other in the Y-direction. In the Y-direction, the first circuit chip 60, the isolation chip 80, and the second circuit chip 70 are arranged in this order in a direction from the first lead terminals 212 toward the second lead terminals 222.

The first circuit chip 60 includes the first circuit 10 shown in FIG. 1. In plan view, the first circuit chip 60 is rectangular and has short sides and long sides. In plan view, the first circuit chip 60 is mounted on the first die pad 211 such that the long sides extend in the X-direction and the short sides extend in the Y-direction.

As shown in FIG. 3, the first circuit chip 60 includes a chip main surface 60s and a chip back surface 60r facing opposite directions in the Z-direction. The chip back surface 60r of the first circuit chip 60 is bonded to the first die pad 211 by a conductive bonding material SD. The conductive bonding material SD is solder, silver (Ag) paste, or the like.

As shown in FIG. 2, multiple first electrodes 61, multiple second electrodes 62, and multiple third electrodes 63 are formed on the chip main surface 60s of the first circuit chip 60. The first electrodes 61, the second electrodes 62, and the third electrodes 63 are electrically connected to the first circuit 10.

The first electrodes 61 are located on the chip main surface 60s closer to the first lead terminals 212 than the center of the chip main surface 60s in the Y-direction is. The first electrodes 61 are arranged in the X-direction. The second electrodes 62 are arranged on opposite ends of the chip main surface 60s in the X-direction. The third electrodes 63 are arranged on one of the two ends of the chip main surface 60s in the Y-direction located closer to the isolation chip 80. The third electrodes 63 are arranged in the X-direction.

The second circuit chip 70 includes the second circuit 20 shown in FIG. 1. In plan view, the second circuit chip 70 is rectangular and has short sides and long sides. In plan view, the second circuit chip 70 is mounted on the second die pad 221 such that the long sides extend in the X-direction and the short sides extend in the Y-direction.

As shown in FIG. 3, the second circuit chip 70 includes a chip main surface 70s and a chip back surface 70r facing opposite directions in the Z-direction. The chip back surface 70r of the second circuit chip 70 is bonded to the second die pad 221 by the conductive bonding material SD.

Multiple first electrodes 71, multiple second electrodes 72, and multiple third electrodes 73 are formed in the chip main surface 70s of the second circuit chip 70. The first electrodes 71, the second electrodes 72, and the third electrodes 73 are electrically connected to the second circuit 20.

The multiple first electrodes 71 are arranged on one of the two ends of the chip main surface 70s in the Y-direction located farther from the isolation chip 80. In other words, the multiple first electrodes 71 are arranged on one of the two ends of the chip main surface 70s in the Y-direction located closer to the second lead terminals 222. The first electrodes 71 are arranged in the X-direction. The second electrodes 72 are arranged on opposite ends of the chip main surface 70s in the X-direction. The third electrodes 73 are arranged on one of the two ends of the chip main surface 70s in the Y-direction located closer to the isolation chip 80. The multiple third electrodes 73 are arranged in the X-direction.

The isolation chip 80 includes the transformers 40 shown in FIG. 1. In plan view, the isolation chip 80 is rectangular and has short sides and long sides. In plan view, the isolation chip 80 is mounted on the first die pad 211 such that the long sides extend in the X-direction and the short sides extend in the Y-direction.

The isolation chip 80 is arranged next to the first circuit chip 60 in the Y-direction. The isolation chip 80 is arranged closer to the second circuit chip 70 than the first circuit chip 60 is. In other words, the isolation chip 80 is located between the first circuit chip 60 and the second circuit chip 70 in the Y-direction.

As shown in FIG. 3, the isolation chip 80 includes a chip main surface 80s and a chip back surface 80r facing opposite directions in the Z-direction. The chip back surface 80r of the isolation chip 80 is bonded to the first die pad 211 by the conductive bonding material SD.

As shown in FIG. 2, the isolation chip 80 includes multiple first electrodes 81 and multiple second electrodes 82. The first electrodes 81 and the second electrodes 82 are arranged on the chip main surface 80s of the isolation chip 80. The first electrodes 81 are arranged on one of the two ends of the isolation chip 80 in the Y-direction located closer to the first circuit chip 60. The first electrodes 81 are arranged in the X-direction. The second electrodes 82 are arranged near the center of the isolation chip 80 in the Y-direction. The second electrodes 82 are arranged in the X-direction.

As shown in FIG. 2, the support members 210 and 220 are closest to each other at the first die pad 211 and the second die pad 221. Therefore, the first die pad 211 and the second die pad 221 need to be separated from each other to allow the signal transmission device 100 to have a predetermined breakdown voltage. Hence, in plan view, the distance between the second circuit chip 70 and the isolation chip 80 is greater than the distance between the first circuit chip 60 and the isolation chip 80.

Wires W1 to W4 are connected to the first circuit chip 60, the isolation chip 80, and the second circuit chip 70. Each of the wires W1 to W4 is a bonding wire formed by a wire bonder and is, for example, formed from a conductor including gold (Au), aluminum (Al), Cu, or the like.

The first circuit chip 60 is electrically connected to the first lead terminals 212 by the wires W1. More specifically, the first electrodes 61 and the second electrodes 62 of the first circuit chip 60 are connected to the first lead terminals 212 by the wires W1. The second electrodes 62 of the first circuit chip 60 are electrically connected to the first lead terminal 212A, which is one of the first lead terminals 212 integrated with the first die pad 211, by the wires W1. Thus, the first circuit 10 is electrically connected to the first lead terminals 212. The first lead terminal 212A, which is integrated with the first die pad 211, serves as a ground terminal. The first circuit 10 is electrically connected to the first die pad 211 by the wire W1. Thus, the first die pad 211 has the same potential as a first ground GND1 of the first circuit 10.

The second circuit chip 70 is electrically connected to the second lead terminals 222 of the second support member 220 by the wires W4. More specifically, the multiple first electrodes 71 and the multiple second electrodes 72 of the second circuit chip 70 are connected to the second lead terminals 222 by the wires W4. Thus, the second circuit 20 is electrically connected to the second lead terminals 222. The second lead terminal 222A, which is integrated with the second die pad 221, serves as a ground terminal. The second circuit 20 is electrically connected to the second die pad 221 by the wire W4. Thus, the second die pad 221 has the same potential as a second ground GND2 of the second circuit 20.

The isolation chip 80 is connected to the first circuit chip 60 by the wires W2. The isolation chip 80 is connected to the second circuit chip 70 by the wires W3. More specifically, the first electrodes 81 of the isolation chip 80 are connected to the third electrodes 63 of the first circuit chip 60 by the wires W2. The second electrodes 82 of the isolation chip 80 are connected to the third electrodes 73 of the second circuit chip 70 by the wires W3.

The first coils 41 (refer to FIG. 1) of the transformers 40A and 40B are electrically connected to the first ground GND1 of the first circuit chip 60 by the wires W2. The second coils 42 (refer to FIG. 1) of the transformers 40A and 40B are electrically connected to the second ground GND2 of the second circuit chip 70 by the wires W3.

FIG. 1 shows an example of the configuration of the signal transmission device 100. The circuit configurations included in the first circuit chip 60 and the second circuit chip 70 may be changed. In an example, the first circuit 10 may include only the transmission circuit 11, and the second circuit 20 may include only the reception circuit 21. The first circuit 10 may include a circuit other than the transmission circuit 11 and the reception circuit 12. The second circuit 20 may include a circuit other than the reception circuit 21 and the transmission circuit 22.

In an example, the first circuit 10 may include an analog-digital conversion circuit. In this case, the signal transmission device 100 is used as an isolated A/D converter.

The second circuit 20 may include a driver circuit that drives the gate of a switching element. The driver circuit may be connected to a terminal (e.g., second lead terminal 222 shown in FIG. 2) of the signal transmission device 100. In this case, the signal transmission device 100 is used as an isolated gate driver that drives the switching element. The switching element may include a power semiconductor element such as a Si metal-oxide-semiconductor field-effect transistor (SiMOSFET), a SiCMOSFET, or an insulated gate bipolar transistor (IGBT). The switching element is used for a motor driver circuit in an inverter device. The driver circuit typically includes a half-bridge circuit where a low-side switching element and a high-side switching element are connected in a totem-pole configuration.

When used as an isolated gate driver, the signal transmission device 100 applies a drive voltage signal to a control terminal of a switching element. In this case, the transmission circuit 11 of the first circuit 10 converts, for example, a control signal input from a control device into a pulse signal. When the reception circuit 21 receives a signal through the transformers 40A and 40B, the driver circuit of the second circuit 20 outputs a drive voltage signal to the control terminal of the switching element. The transmission circuit 22 of the second circuit 20 and the reception circuit 12 of the first circuit 10 may be used to, for example, transmit a detection signal of a temperature sensor arranged in the vicinity of a motor to the controller.

As described above, in the first circuit 10 of the signal transmission device 100 used as an isolated gate driver, the power voltage of the first circuit 10 configured to receive a signal from the controller is 5 V or 3.3 V with reference to the ground potential. The second circuit 20 is connected to a high-side switching element and transiently receives a voltage (e.g., 600 V or higher) equivalent to the voltage applied to the drain of the high-side switching element. Thus, the signal transmission device 100 needs a breakdown voltage between the first circuit 10 and the second circuit 20; more specifically, between the first coil 41 and the second coil 42 of the transformers 40A and 40B. The breakdown voltage needed for the signal transmission device 100 is in a range of 2500 Vrms to 7500 Vrms, inclusive. In an example, the breakdown voltage of the signal transmission device 100 is approximately 5000 Vrms. However, the breakdown voltage of the signal transmission device 100 is not limited to these values and may be any specific numerical value.

### Configuration of Isolation Chip

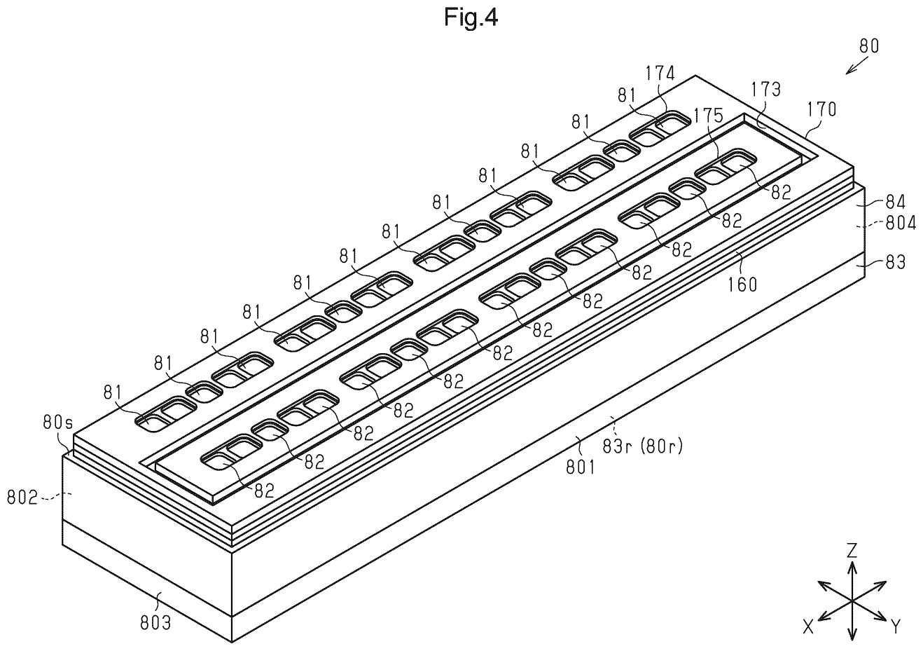

An example of the configuration of the isolation chip 80 will now be described with reference to FIGS. 4 to FIG. 12.

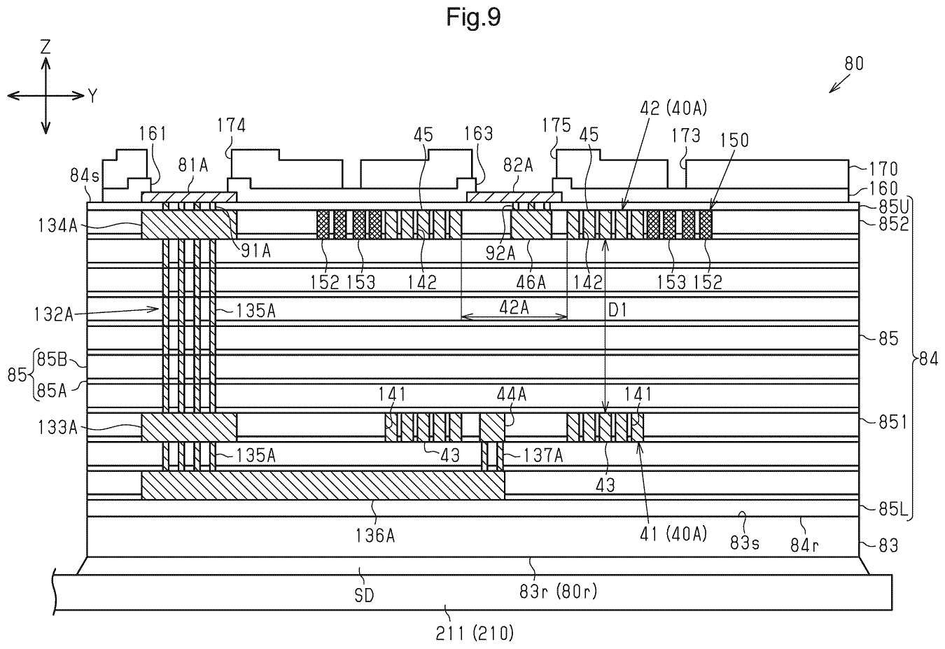

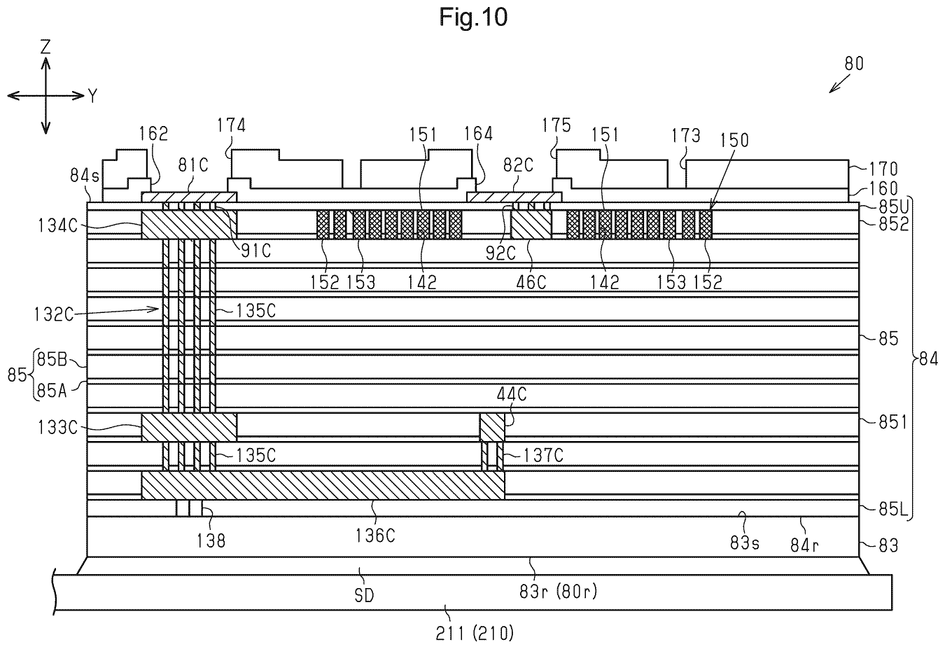

In the description hereafter, referring to FIG. 9 and FIG. 10, the direction extending from the chip back surface 80r of the isolation chip 80 toward the chip main surface 80s will be referred to as the upward direction, and the direction extending from the chip main surface 80s toward the chip back surface 80r will be referred to as the downward direction.

FIG. 4 is a perspective view showing the outer appearance of the isolation chip 80.

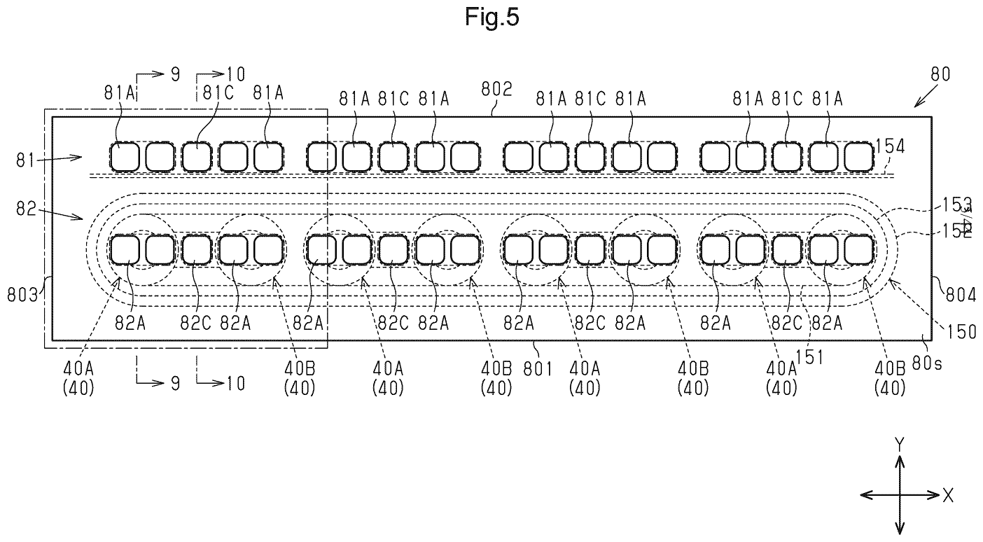

FIG. 5 is a plan view of the isolation chip 80. In FIG. 5, for illustrative purposes, the passivation film 160 is indicated by double-dashed lines, and the transformers 40A and 40B and a dummy wire 150, which will be described later, are indicated by broken lines.

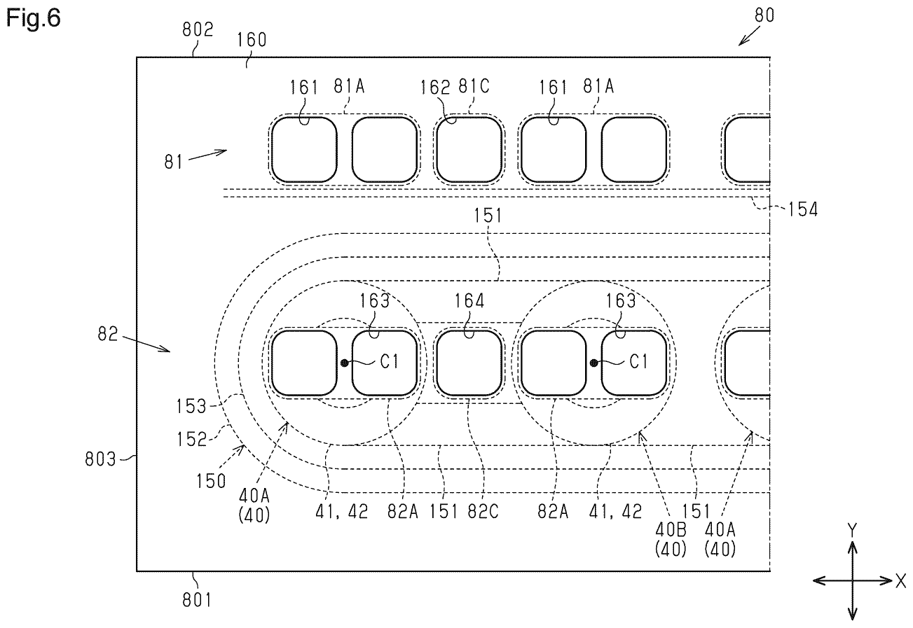

FIG. 6 is an enlarged plan view showing a portion of the isolation chip 80 shown in FIG. 5. In FIG. 6, the transformers 40A and 40B are enlarged.

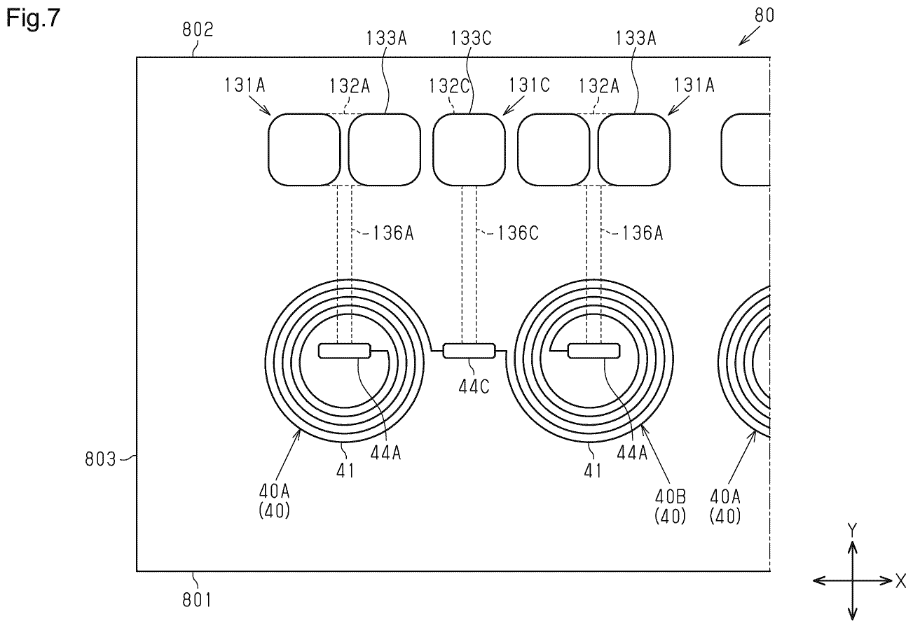

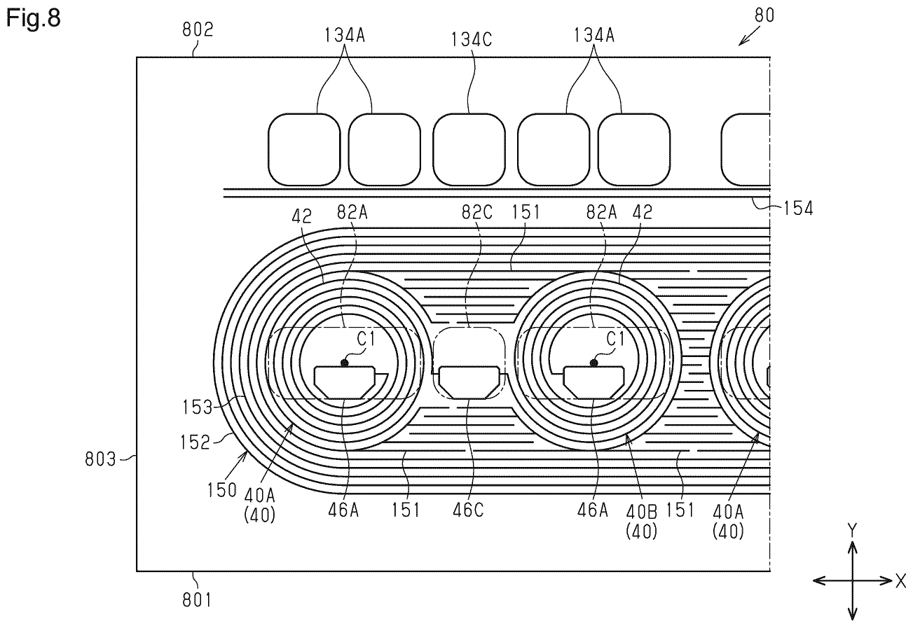

FIG. 7 is a cross-sectional view of the isolation chip 80 cut along an XY-planar through a position of the first coil 41 in the Z-direction and shows the connection relationship of the first coil 41. FIG. 8 is a cross-sectional view of the isolation chip 80 cut along an XY-plane through a position of the second coil 42 in the Z-direction and shows the connection relationship of the second coil 42. FIG. 7 and FIG. 8 do not show hatching for clarity.

FIG. 9 is a cross-sectional view of the isolation chip 80 taken along line 9-9 in FIG. 5 showing cross-sectional structures of the first coil 41, the second coil 42, the dummy wire 150, a first inner electrode 81A, and a second inner electrode 82A. FIG. 10 is a cross-sectional view of the isolation chip 80 taken along line 10-10 in FIG. 5 showing cross-sectional structures of the dummy wire 150, a first outer electrode 81C, and a second outer electrode 82C. FIG. 9 and FIG. 10 do not show hatching lines for some of the components to simplify illustration.

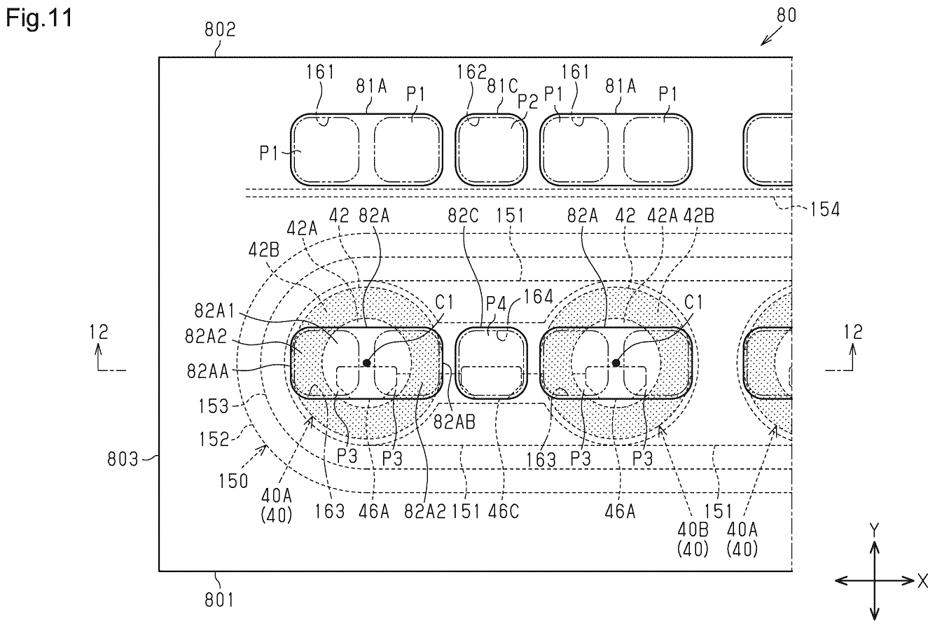

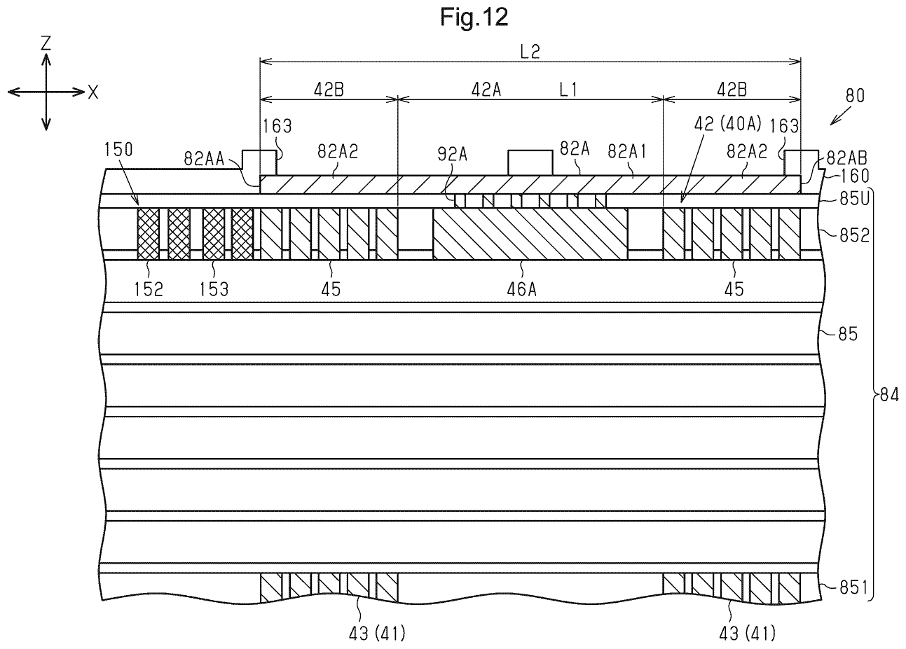

FIG. 11 is a partial enlarged schematic plan view of the isolation chip 80 showing second inner electrodes 82A, the first outer electrode 81C, and second coils 42. FIG. 12 is a cross-sectional view of the isolation chip 80 taken along line 12-12 in FIG. 11 showing cross-sectional structures of the second coil 42 and the second inner electrode 82A.

### Schematic Layout of Transformers and Electrodes

As shown in FIG. 5, the isolation chip 80 includes four pairs of transformers 40A and 40B. More specifically, the isolation chip 80 is a single semiconductor chip including four pairs of transformers 40A and 40B. That is, the isolation chip 80 is arranged separately from the first circuit chip 60 and the second circuit chip 70 (refer to FIG. 2).

The transformers 40A and 40B are arranged near the center of the chip main surface 80s in the Y-direction. The first electrodes 81 and the second electrodes 82 are electrically connected to the transformers 40A and 40B.

### Second Electrode

The second electrodes 82 include the second inner electrodes 82A, which overlap inner regions 42A of the transformers 40A and 40B, and second outer electrodes 82C, which are located outside the transformers 40A and 40B, in plan view. Each second inner electrode 82A is connected to an inner end wire 46A connected to an inner end of the second coil 42. Each second outer electrode 82C is connected to an outer end wire 46C connected to an outer end of the second coil 42. The second inner electrode 82A and the second outer electrode 82C are formed from a material including one or more selected from Cu, Al, nickel (Ni), palladium (Pd), and tungsten (W).

The transformers 40A and 40B are each electrically connected to a second inner electrode 82A. The second electrodes 82 include a second inner electrode 82A that is connected to a transformer 40A and a second inner electrode 82A that is connected to a transformer 40B. In an example, the second outer electrode 82C is arranged between the transformer 40A and the transformer 40B. The transformer 40A and the transformer 40B are electrically connected to a second outer electrode 82C. The second outer electrode 82C may be referred to as a common pad of the two transformers 40A and 40B.

In plan view, the second inner electrode 82A is shaped so that the dimension in the Y-direction, which is orthogonal to the X-direction, is smaller than the dimension in the X-direction, in which the second electrodes 82 are arranged. In an example, the second inner electrode 82A is rectangular and elongated in the X-direction. In plan view, the second outer electrode 82C is shaped so that the dimension in the X-direction, in which the second electrodes 82 are arranged, is equal to the dimension in the Y-direction. In an example, the second outer electrode 82C is square.

### First Electrode

In plan view, the first electrodes 81 are arranged so that two first electrodes 81 are aligned with one transformer 40A with respect to the X-direction, two first electrodes 81 are aligned with one transformer 40B with respect to the X-direction, and one first electrode 81 is located between the transformer 40A and the transformer 40B in the X-direction. The first electrodes 81 are located closer in the Y-direction to a chip side surface 802 than the transformers 40A and 40B are. In other words, the first electrodes 81 are located between the chip side surface 802 and the transformers 40A and 40B in the Y-direction. In other words, in plan view, the first electrodes 81 are located closer to the first lead terminals 212 (refer to FIG. 2) than the transformers 40A and 40B are.

The first electrodes 81 include a first inner electrode 81A corresponding to the second inner electrode 82A of the second electrodes 82 and a first outer electrode 81C corresponding to the second outer electrode 82C of the second electrodes 82. The first inner electrode 81A is connected to an inner end wire 44A; that is, an inner end of the first coil 41. The first outer electrode 81C is connected to an outer end wire 44C; that is, an outer end of the first coil 41. The first inner electrode 81A and the first outer electrode 81C are formed from a material including one or more selected from Cu, Al, Ni, Pd, and W.

The transformers 40A and 40B are each electrically connected to a first inner electrode 81A. The isolation chip 80 includes a first inner electrode 81A that is electrically connected to the transformer 40A and a first inner electrode 81A that is electrically connected to the transformer 40B. The transformers 40A and the transformers 40B are electrically connected to a first outer electrode 81C. The first outer electrode 81C may be referred to as a common pad of the two transformers 40A and 40B.

In plan view, the first inner electrode 81A is shaped so that the dimension in the Y-direction, which is orthogonal to the X-direction, is smaller than the dimension in the X-direction, in which the first electrodes 81 are arranged. In an example, the first inner electrode 81A is rectangular and elongated in the X-direction. In plan view, the first outer electrode 81C is shaped so that the dimension in the X-direction, in which the second electrodes 82 are arranged, is equal to the dimension in the Y-direction. In an example, the first outer electrode 81C is square.

The first inner electrode 81A overlaps the transformers 40A and 40B as viewed in the Y-direction. As viewed in the Y-direction, the first outer electrode 81C overlaps a portion located between the transformer 40A and the transformer 40B in the X-direction. Thus, the first electrodes 81 (81A, 81C) are aligned with each other with respect to the Y-direction and separated from each other in the X-direction.

One pair of transformers 40A and 40B has the same configuration as another pair of transformers 40A and 40B. The transformer 40B and the transformer 40A have the same structure. Thus, the structure of the transformer 40A will be described in detail, and the transformer 40B will not be described.

### Detailed Configuration of Isolation Chip

As shown in FIG. 4, the isolation chip 80 includes four chip side surfaces 801, 802, 803, and 804 orthogonal to each of the chip main surface 80s and the chip back surface 80r. The chip side surfaces 801 to 804 are arranged between the chip main surface 80s and the chip back surface 80r in the Z-direction. The chip side surfaces 801 and 802 define opposite surfaces of the isolation chip 80 in the Y-direction. The chip side surfaces 803 and 804 define opposite surfaces of the isolation chip 80 in the X-direction. In plan view, the chip side surfaces 801 and 802 define the long sides of the isolation chip 80. The chip side surfaces 803 and 804 define the short sides of the isolation chip 80. In an example, the chip side surface 801 is located closer to the second circuit chip 70 (refer to FIG. 2) than the chip side surface 802 is. The chip side surface 802 is located closer to the first circuit chip 60 (refer to FIG. 2) than the chip side surface 801 is.

As shown in FIGS. 4, FIG. 9, and FIG. 10, the isolation chip 80 includes a substrate 83 and an insulation layer 84 formed on the substrate 83.

The substrate 83 is composed of, for example, a semiconductor substrate. The substrate 83 is formed from a material including, for example, silicon (Si). The Si substrate serving as the substrate 83 may be a semiconductor substrate formed from a single-crystal intrinsic semiconductor material, a p-type semiconductor substrate including an acceptor impurity, an n-type semiconductor substrate including a donor impurity, or the like. The substrate 83 may be an epitaxial substrate including a Si substrate and an epitaxial layer formed on the Si substrate. A functional device may be formed on the substrate 83. The functional device may include a passive element such as a resistor, an active element such as a transistor, a circuit network formed of multiple elements, and the like.

As the semiconductor substrate, a wide-bandgap semiconductor or a compound semiconductor may be used for the substrate 83. Instead of the semiconductor substrate, the substrate 83 may be an insulating substrate formed from a material including glass. The wide-bandgap semiconductor is a semiconductor substrate having a band gap that is greater than or equal to 2.0 eV. The wide-bandgap semiconductor may include silicon carbide (SiC), gallium nitride (GaN), gallium oxide (Ga₂O₃), or the like. The compound semiconductor may be a group III-V compound semiconductor. The compound semiconductor may include at least one of aluminum nitride (AlN), indium nitride (InN), GaN, and gallium arsenide (GaAs).

The substrate 83 includes a substrate main surface 83s and a substrate back surface 83r facing opposite directions in the Z-direction. The substrate back surface 83r includes the chip back surface 80r of the isolation chip 80.

As shown in FIG. 9 and FIG. 10, the insulation layer 84 includes an upper surface 84s and a lower surface 84r that face in opposite directions.

The insulation layer 84 includes multiple insulation films 85 stacked on the substrate main surface 83s of the substrate 83 in the Z-direction. Thus, the Z-direction may be referred to as the thickness-wise direction of the insulation layer 84. Also, the Z-direction may be referred to as a stacking direction of the insulation films 85. The insulation layer 84 is formed on the substrate main surface 83s of the substrate 83.

Each insulation film 85 includes a first insulation film 85A and a second insulation film 85B formed on the first insulation film 85A. The first insulation film 85A is a thin film and is, for example, an etching stopper layer. The first insulation film 85A is formed from a material including silicon nitride (SiN), SiC, nitrogen-added silicon carbide (SiCN), or the like. The first insulation film 85A is formed from a material including SiN. The second insulation film 85B is, for example, an interlayer insulation film. The second insulation film 85B is formed from a material including silicon oxide (SiO₂). The second insulation film 85B is thicker than the first insulation film 85A. The thickness of the first insulation film 85A may be greater than or equal to 100 nm and less than 1000 nm. The thickness of the second insulation film 85B may be in a range of 1000 nm to 3000 nm. The thickness of the first insulation film 85A is, for example, approximately 300 nm. The thickness of the second insulation film 85B is, for example, approximately 2000 nm.

The second insulation films 85B include a lowermost insulation film 85L, which is in contact with the substrate main surface 83s of the substrate 83, and an uppermost insulation film 85U. In an example, both the lowermost insulation film 85L and the uppermost insulation film 85U are thinner than the other insulation films 85. The thickness of each of the lowermost insulation film 85L and the uppermost insulation film 85U is in a range of the thickness of the first insulation film 85A to the thickness of the second insulation film 85B.

The thickness of the lowermost insulation film 85L and the uppermost insulation film 85U may be changed in any manner. In an example, the thickness of each of the lowermost insulation film 85L and the uppermost insulation film 85U may be greater than the thickness of the second insulation film 85B or may be greater than or equal to the thickness of an insulation film 85 that includes the first insulation film 85A and the second insulation film 85B.

### First Coil

As shown in FIG. 7, the first coils 41 of the transformers 40A and 40B are formed of a first coil wire 43. In plan view, the first coil wire 43 is annular and, for example, has a circular spiral shape. The first coil 41 is formed from a material including one or more selected from titanium (Ti), titanium nitride (TiN), Au, Ag, Cu, Al, and W. A first inner end wire 44A is located at an inner side of the first coil wire 43. A first outer end wire 44C is located at an outer side of the first coil wire 43. One end of the first coil wire 43 is electrically connected to the first inner end wire 44A. The other end of the first coil wire 43 is electrically connected to the first outer end wire 44C.

The first inner end wire 44A and the first outer end wire 44C are formed from a material including one or more selected from Ti, TiN, Au, Ag, Cu, Al, and W. The first outer end wire 44C serves as a common end wire of the first coils 41 of the transformers 40A and 40B. Alternatively, an outer end wire may be arranged for each of the first coils 41 of the transformers 40A and 40B.

As shown in FIG. 7 and FIG. 9, the first inner end wire 44A is connected to the first inner electrode 81A by an interconnect 131A. The interconnect 131A is formed from a material including one or more selected from Ti, TiN, Au, Ag, Cu, Al, and W.

As shown in FIG. 9, the interconnect 131A includes a first interconnect part 132A extending through the insulation films 85 in the Z-direction and a second interconnect part 136A extending in the Y-direction.

The first interconnect part 132A is arranged to overlap the first inner electrode 81A in plan view and is connected to the first inner electrode 81A. The first interconnect part 132A extends through the insulation films 85 from the insulation film 85 that is located immediately below the uppermost insulation film 85U to the insulation film 85 that is located above the lowermost insulation film 85L with one insulation film 85 interposed. The first interconnect part 132A includes flat interconnect pieces 133A and 134A and multiple vias 135A. The interconnect pieces 133A and 134A are located at the same positions as the insulation films 851 and 852 in which the coils 41 and 42 are arranged. The vias 135A are arranged between the two interconnect pieces in the Z-direction, between the upper interconnect piece 134A and the first inner electrode 81A, and between the lower interconnect piece 133A and the second interconnect part 136A. The interconnect pieces 133A and 134A are formed from the same conductive material as the first coil 41 and the second coil 42.

The second interconnect part 136A is located closer to the substrate 83 than the first interconnect part 132A is. The second interconnect part 136A is located closer to the substrate 83 than the first coil 41 is. The second interconnect part 136A is arranged in the insulation film 85 located immediately above the lowermost insulation film 85L among the insulation films 85. Of opposite ends of the second interconnect part 136A in the Y-direction, a first end is located closer to the chip side surface 802 of the isolation chip 80 and overlaps the first interconnect part 132A in plan view. The second interconnect part 136A is connected to the first interconnect part 132A. The second interconnect part 136A includes a second end opposite to the first end. In plan view, the second end is arranged to overlap the first coil 41 of the transformer 40A. More specifically, in plan view, the second end overlaps the first inner end wire 44A, which is connected to the first coil 41 of the transformer 40A. The second interconnect part 136A includes multiple vias 137A connecting the second interconnect part 136A and the first inner end wire 44A.

As shown in FIG. 7 and FIG. 10, the first outer end wire 44C is electrically connected to the first outer electrode 81C by an interconnect 131C. The interconnect 131C is formed from a material including one or more selected from Ti, TiN, Au, Ag, Cu, Al, and W.

As shown in FIG. 10, the interconnect 131C includes a first interconnect part 132C extending through the insulation films 85 in the Z-direction and a second interconnect part 136C extending in the Y-direction.

The first interconnect part 132C and the first interconnect part 132A of the interconnect 131A have the same structure.

The first interconnect part 132C is arranged to overlap the first outer electrode 81C in plan view and is connected to the first outer electrode 81C. The first interconnect part 132C extends through the insulation films 85 from the insulation film 85 that is located immediately below the uppermost insulation film 85U to the insulation film 85 that is located above the lowermost insulation film 85L with one insulation film 85 interposed. The first interconnect part 132C includes flat interconnect pieces 133C and 134C and multiple vias 135C. The interconnect pieces 133C and 134C are located at the same positions as the insulation films 851 and 852 in which the coils 41 and 42 are arranged. The vias 135C are arranged between the two interconnect pieces in the Z-direction, between the upper interconnect piece and the first outer electrode 81C, and between the lower interconnect piece and the second interconnect part 136C. The interconnect pieces 133C and 134C are formed from the same conductive material as the first coil 41 and the second coil 42.

The second interconnect part 136C is located closer to the substrate 83 than the first interconnect part 132C is. The second interconnect part 136C is located closer to the substrate 83 than the first coil 41 is. The second interconnect part 136C is arranged in the insulation film 85 located immediately above the lowermost insulation film 85L among the insulation films 85. Of opposite ends of the second interconnect part 136C in the X-direction, a first end is located closer to the chip side surface 802 of the isolation chip 80 and overlaps the first interconnect part 132C in plan view. The second interconnect part 136C is connected to the first interconnect part 132C. The second interconnection piece 133C has a second end opposite to the first end. The second end does not overlap the first coil 41 of the transformer 40A in plan view. More specifically, in plan view, the second end overlaps the first outer end wire 44C, which is connected to the first coil 41 of the transformer 40A. The second interconnect part 136C includes multiple vias 137C connecting the second interconnect part 136C and the first outer end wire 44C. The second interconnect part 136C of the interconnect 131C is electrically connected to the substrate 83 by vias 138 that extend through the lowermost insulation film 85L. The vias 138 may be omitted.

### Second Coil

As shown in FIG. 8, the second coils 42 of the transformers 40A and 40B each include a second coil wire 45. In plan view, the second coil wire 45 is annular and, for example, has a circular spiral shape. The second coil 42 is formed from a material including one or more selected from Ti, TiN, Au, Ag, Cu, Al, and W. A second inner end wire 46A is located in an inner region 42A surrounded by the second coil wire 45. A second outer end wire 46C is located at an outer side of the second coil wire 45. One end of the second coil wire 45 is electrically connected to the second inner end wire 46A. The other end of the second coil wire 45 is electrically connected to the second outer end wire 46C.

The second inner end wire 46A and the second outer end wire 46C are formed from a material including one or more selected from Ti, TiN, Au, Ag, Cu, Al, and W. The second outer end wire 46C serves as a common end wire of the transformers 40A and 40B and the second coil 42. Alternatively, the second outer end wire 46C may be arranged for each of the second coils 42 of the transformers 40A and 40B.

In plan view, the second coil wire 45 has the same winding direction as the first coil wire 43 shown in FIG. 7. In an example, the second coil wire 45 has the same number of wiring turns as the first coil wire 43. Alternatively, the number of wiring turns may differ between the second coil wire 45 and the first coil wire 43.

As shown in FIG. 9, the first coil 41 and the second coil 42 of the transformer 40A (40B) are opposed to each other in the Z-direction with one or more of the insulation films 85 interposed. The first coil 41 and the second coil 42 are opposed to each other in the Z-direction with two or more of the insulation films 85 interposed.

The first coil 41 is formed as a conductive layer embedded in one of the insulation films 85. More specifically, the first coil 41 is embedded in an insulation film 851. The insulation film 851 includes a wire groove 141 (first wire groove) extending through the first insulation film 85A and the second insulation film 85B in the Z-direction. A conductive layer is embedded in the wire groove 141 of the insulation film 851 to form the first coil 41. The insulation film 851, in which the first coil 41 is embedded, is covered by insulation films 85 located next to the insulation film 851 in the Z-direction. In other words, the first coil 41 is embedded in the insulation films 85.

The second coil 42 is formed as a conductive layer embedded in one of the insulation films 85. More specifically, the second coil 42 is embedded in an insulation film 852. The insulation film 852 includes a wire groove 142 (second wire groove) extending through the first insulation film 85A and the second insulation film 85B in the Z-direction. A conductive layer is embedded in the wire groove 142 of the insulation film 852 to form the second coil 42. The insulation film 852, in which the second coil 42 is embedded, is covered by insulation films 85 located next to the insulation film 852 in the Z-direction. In other words, the second coil 42 is embedded in the insulation films 85.

The second coil 42 is located farther from the substrate 83 than the first coil 41 is in the Z-direction. That is, the second coil 42 is located upward from the first coil 41. In other words, the first coil 41 is located closer to the substrate 83 than the second coil 42 is. A distance D1 between the first coil 41 and the second coil 42 in the Z-direction is greater than the distance between the first coil 41 and the substrate main surface 83s of the substrate 83.

As shown in FIG. 9, the first inner electrode 81A is formed on the uppermost insulation film 85U. That is, the first inner electrode 81A is formed on the upper surface 84s of the insulation layer 84. Vias 91A extend through the insulation film 85U and electrically connect the first inner electrode 81A to the interconnect piece 134A of the first interconnect part 132A.

As shown in FIG. 10, the first outer electrode 81C is formed on the uppermost insulation film 85U. That is, the first outer electrode 81C is formed on the upper surface 84s of the insulation layer 84. Vias 91C extend through the insulation film 85U and electrically connect the first outer electrode 81C to the interconnect piece 134C of the first interconnect part 132C.

As shown in FIG. 9, the second inner electrode 82A is formed on the uppermost insulation film 85U. That is, the second inner electrode 82A is formed on the upper surface 84s of the insulation layer 84. Vias 92A extend through the insulation film 85U and electrically connect the second inner electrode 82A to the second inner end wire 46A.

As shown in FIG. 10, the second outer electrode 82C is formed on the uppermost insulation film 85U. That is, the second outer electrode 82C is formed on the upper surface 84s of the insulation layer 84. Vias 92C extend through the insulation film 85U and electrically connect the second outer electrode 82C and the second outer end wire 46C.

### Dummy Wire

As shown in FIG. 5 and FIGS. 8 to FIG. 10, the isolation chip 80 includes the dummy wire 150 arranged around the first coils 41 of the transformers 40A and 40B. The dummy wire 150 may be omitted.

As shown in FIG. 5 and FIG. 8, the dummy wire 150 includes a first dummy wire 151, a second dummy wire 152, and a third dummy wire 153. The first dummy wire 151, the second dummy wire 152, and the third dummy wire 153 are formed from a material including one or more selected from Ti, TiN, Au, Ag, Cu, Al, and W.

As shown in FIG. 5 and FIG. 8, in plan view, the first dummy wire 151 is arranged in a region between the second coil 42 of the transformer 40A and the second coil 42 of the transformer 40B in the X-direction. The first dummy wire 151 is patterned differently from the second coil 42. The first dummy wire 151 is electrically connected to the second outer end wire 46C. The first dummy wire 151 is a wiring pattern configured not to allow current to flow. The first dummy wire 151 may be electrically connected to at least one of the four second outer end wires 46C shown in FIG. 5. Hence, the first dummy wire 151 has the same potential as the second coil 42. Thus, when a second reference potential of the second coil 42 changes, the voltage of the first dummy wire 151 may become higher than the voltage of the first coil 41 in the same manner as the second coil 42.

As shown in FIG. 10, the first dummy wire 151 is located at the same position as the second dummy wire 152 and the third dummy wire 153 in the Z-direction. As shown in FIG. 9, the second dummy wire 152 and the third dummy wire 153 are located at the same position as the second coil 42 in the Z-direction. Therefore, although not shown in the drawings, the first dummy wire 151 is located at the same position as the second coil 42 in the Z-direction. That is, the first dummy wire 151 is located farther from the substrate 83 than the first coil 41 is. In other words, the dummy wire 150 is arranged around the coils of the transformers 40A and 40B located closer to the chip main surface 80s of the isolation chip 80. When the first dummy wire 151 and the second coil 42 are at the same voltage, the voltage drop between the second coil 42 and the first dummy wire 151 is limited. This avoids concentration of an electric field on the second coil 42.

As shown in FIG. 8, in plan view, the third dummy wire 153 surrounds the second coils 42 of the transformers 40A and 40B. The third dummy wire 153 is electrically connected to the first dummy wire 151. Thus, in the same manner as the first dummy wire 151, when the second reference potential of the second coil 42 changes, the voltage of the third dummy wire 153 may become higher than the voltage of the first coil 41.

As shown in FIG. 10, the third dummy wire 153 is located at the same position as the second coil 42 in the Z-direction. Thus, the third dummy wire 153 is located farther from the substrate 83 than the first coil 41 is. As described above, the first to third dummy wires 151 to 153 are aligned with each other with respect to the Z-direction. When the third dummy wire 153 and the second coil 42 are at the same voltage, the voltage drop between the second coil 42 and the third dummy wire 153 is limited. This avoids concentration of an electric field on the second coil 42.

As shown in FIG. 8, in plan view, the second dummy wire 152 surrounds the third dummy wire 153. The second dummy wire 152 is isolated from the second coil 42. That is, the second dummy wire 152 may be electrically disconnected from the second coil 42.

As shown in FIG. 9 and FIG. 10, the second dummy wire 152 is aligned with the second coil 42 with respect to the Z-direction. Thus, the second dummy wire 152 is located farther from the substrate 83 than the first coil 41 is. The second dummy wire 152 limits increases in the electric field strength around the second coil 42 and limits concentration of the electric field on the second electrodes 82 (i.e., the second inner electrode 82A and the second outer electrode 82C).

As shown in FIG. 6 and FIG. 8, the isolation chip 80 includes the fourth dummy wire 154. The fourth dummy wire 154 may be omitted. The fourth dummy wire 154 is formed from a material including one or more selected from Ti, TiN, Au, Ag, Cu, Al, and W.

As shown in FIG. 6 and FIG. 8, in plan view, the fourth dummy wire 154 is arranged between the second coil 42 and the first electrodes 81. The fourth dummy wire 154 extends in the X-direction. In plan view, the fourth dummy wire 154 extends along the first electrodes 81. The fourth dummy wire 154 may include multiple wires. The fourth dummy wire 154 is electrically isolated from the second coil 42. In other words, the fourth dummy wire 154 is not electrically connected to the second coil 42. The fourth dummy wire 154 separates the first electrodes 81 from the second coil 42.

### Passivation Film and Resin Layer

As shown in FIG. 9 and FIG. 10, the isolation chip 80 includes the passivation film 160. The passivation film 160 is formed on the upper surface 84s of the insulation layer 84. The passivation film 160 protects the insulation layer 84. the passivation film 160 is a surface protection film for the isolation chip 80. The passivation film 160 is formed from a material including, for example, silicon oxide or silicon nitride. The material including silicon nitride includes, for example, SiN and SiCN. The passivation film 160 includes the chip main surface 80s of the isolation chip 80.

The first electrodes 81 and the second electrodes 82 are covered by the passivation film 160. The passivation film 160 includes openings that partially expose the first electrodes 81 and the second electrodes 82. Thus, the first electrodes 81 each have an exposed surface used to connect a wire W2. The second electrodes 82 each have an exposed surface used to connect a wire W3.

In FIG. 11, the openings of the passivation film 160 are indicated by double-dashed lines.

The first electrodes 81 include the first inner electrode 81A and the first outer electrode 81C. The passivation film 160 includes a first inner opening 161 partially exposing the first inner electrode 81A and a first outer opening 162 partially exposing the first outer electrode 81C.

The first inner electrode 81A is rectangular and is longer in the X-direction than in the Y-direction. The passivation film 160 includes two first inner openings 161 partially exposing the first inner electrode 81A. The two first inner openings 161 are arranged in the X-direction in conformance with the shape of the first inner electrode 81A. In an example, the two first inner openings 161 are each square and equal in length in the X-direction and the Y-direction.

The first inner electrode 81A includes two exposed surfaces exposed from the two first inner openings 161 in the passivation film 160. The two exposed surfaces of the first inner electrode 81A serve as first pads P1 used for external connection of the first coil 41. The first inner electrode 81A includes two first pads P1 in the two first inner openings 161.

The first outer electrode 81C is square and has the same length in the Y-direction and the X-direction. The passivation film 160 includes one first outer opening 162 partially exposing the first outer electrode 81C. The first outer opening 162 is square and has the same length in the X-direction and the Y-direction in conformance with the shape of the first outer electrode 81C. In an example, the first outer opening 162 is equal in size to the first inner opening 161.

The first outer electrode 81C includes one exposed surface exposed from the one first outer opening 162 in the passivation film 160. The exposed surface of the first outer electrode 81C serves as a second pad P2 used for external connection of the first coil 41. The first outer electrode 81C includes one second pad P2 in the one first outer opening 162.

The second electrodes 82 include the second inner electrode 82A and the second outer electrode 82C. The passivation film 160 includes a second inner opening 163 partially exposing the second inner electrode 82A and a second outer opening 164 partially exposing the first outer electrode 81C. The second inner opening 163 corresponds to a “second opening.”

The second inner electrode 82A is rectangular and is longer in the X-direction than in the Y-direction. The passivation film 160 includes two second inner openings 163 partially exposing the second inner electrode 82A. The two second inner openings 163 are arranged in the X-direction in conformance with the shape of the second inner electrode 82A. In an example, the two second inner openings 163 are each square and equal in length in the X-direction and the Y-direction.

The second inner electrode 82A includes two exposed surfaces exposed from the two second inner openings 163 in the passivation film 160. The two exposed surfaces of the second inner electrode 82A serve as third pads P3 used for external connection of the second coil 42. The second inner electrode 82A includes two third pads P3 in the two second inner openings 163

The second outer electrode 82C is square and has the same length in the Y-direction and the X-direction. The passivation film 160 includes one second outer opening 164 partially exposing the second outer electrode 82C. The second outer opening 164 is square and has the same length in the X-direction and the Y-direction in conformance with the shape of the second outer electrode 82C. In an example, the second outer opening 164 is equal in size to the first inner opening 161.

The second outer electrode 82C includes one exposed surface exposed from the one second outer opening 164 in the passivation film 160. The exposed surface of the second outer electrode 82C serves as a fourth pad P4 used for external connection of the second coil 42. The second outer electrode 82C includes one fourth pad P4 in the second outer opening 164.

The isolation chip 80 includes a resin layer 170 formed on the passivation film 160. The resin layer 170 is formed from, for example, a material including polyimide (PI). The resin layer 170 is separated into an inner resin layer and an outer resin layer by a separation trench 173. As shown in FIG. 4, in plan view, the separation trench 173 extends around the transformers 40A and 40B. The resin layer 170 includes a first resin opening 174 exposing the first electrode 81 and a second resin opening 175 exposing the second electrode 82.

### Detail of the Second Electrode (Second Inner Electrode, Second Outer Electrode)

As shown in FIG. 11 and FIG. 12, in plan view, the second inner electrode 82A is rectangular and longer in the X-direction than the Y-direction in plan view. In plan view, the second inner electrode 82A overlaps the inner end wire 46A.

The second inner electrode 82A is electrically connected to the inner end wire 46A. In plan view, the second inner electrode 82A overlaps the inner region 42A surrounded by the second coil 42. The inner region 42A is circular in conformance with the circular spiral shape of the second coil 42 (second coil wire 45).

The second inner electrode 82A is rectangular and elongated in the X-direction, in which the second coils 42 of the isolation chip 80 are arranged. The second inner electrode 82A has a length L2 in the X-direction. The inner region 42A surrounded by the second coil 42 has a dimension L1 in the X-direction. The length L2 is greater than the dimension L1. In other words, the dimension of the inner region 42A surrounded by the second coil 42 in the X-direction is smaller than the length of the second inner electrode 82A in the X-direction. Thus, the second inner electrode 82A has opposite ends 82AA and 82AB overlapping the second coil 42 in plan view. In plan view, the second inner electrode 82A includes a first overlap portion 82A1 overlapping the inner region 42A surrounded by the second coil 42 and a second overlap portion 82A2 overlapping the second coil 42. The first overlap portion 82A1 corresponds to a “first region.” The second overlap portion 82A2 corresponds to a “second region.” Thus, the second inner electrode 82A is arranged at a position overlapping the inner region 42A and a region 42B overlapping the second coil 42. In an example, the second overlap portion 82A2 is greater in area than the first overlap portion 82A1.

The passivation film 160 includes two second inner openings 163 partially exposing the second inner electrode 82A. The two second inner openings 163 extend above the second inner electrode 82A, and over the inner region 42A and a region that overlaps the second coil 42.

As shown in FIG. 11, in plan view, the second outer electrode 82C is square and has the same length in the Y-direction and the X-direction. In plan view, the second outer electrode 82C is located between the second coils 42 arranged in the X-direction. In plan view, the two second coils 42 are located at opposite sides of the second outer electrode 82C, which is smaller in length in the X-direction than the second inner electrode 82A.

### Detail of the First Electrode (First Inner Electrode, First Outer Electrode)

As shown in FIG. 11, in plan view, the first inner electrode 81A is rectangular and longer in the X-direction than the Y-direction in plan view. In an example, the first inner electrode 81A is equal to the second inner electrode 82A in length in the X-direction. The first inner electrode 81A is located at the same position as the second inner electrode 82A in the X-direction.

In plan view, the first outer electrode 81C is square and has the same length in the Y-direction and the X-direction. In an example, the first outer electrode 81C is equal to the second outer electrode 82C in length in the X-direction. The first outer electrode 81C is located at the same position as the second outer electrode 82C in the X-direction.

### First Circuit Chip and Second Circuit Chip

The first circuit chip 60 and the second circuit chip 70 will now be described. The first circuit chip 60 and the second circuit chip 70 have the same configuration. Thus, the first circuit chip 60 will be described below so that the description of the second circuit chip 70 is omitted.

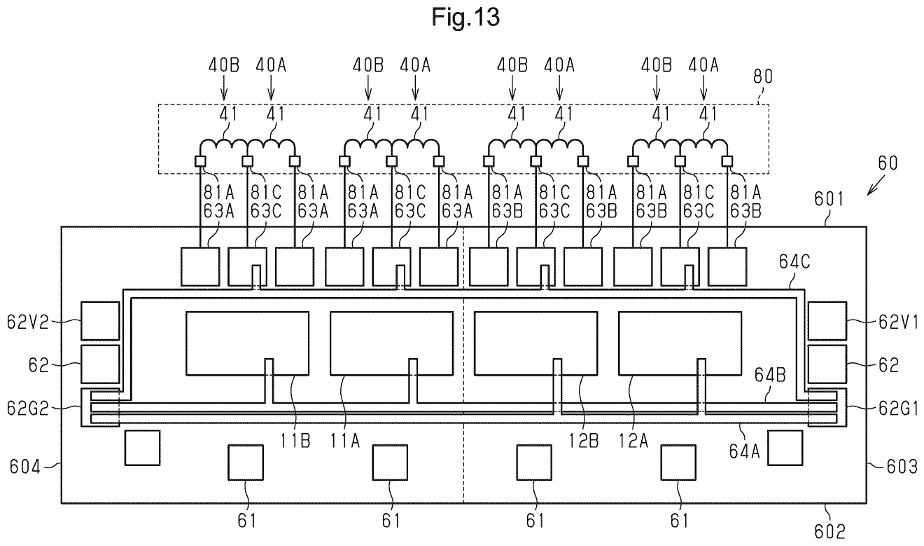

FIG. 13 is a plan view showing the configuration of the first circuit chip 60. In FIG. 13, the functional blocks and the wires of the first circuit chip 60 are indicated by solid lines for the sake of illustration. This does not mean that the functional blocks and the wires are arranged above the first to third electrodes 61 to 63.

As shown in FIG. 13, the first circuit chip 60 has the shape of a rectangular box that is longer in the X-direction than in the Y-direction. The first circuit chip 60 includes a chip main surface 60s and a chip back surface 60r facing opposite directions in the Z-direction. The first circuit chip 60 includes four chip side surfaces 601, 602, 603, and 604 orthogonal to the chip main surface 60s and the chip back surface 60r. The chip side surfaces 601 and 602 define opposite end surfaces of the first circuit chip 60 in the Y-direction. The chip side surfaces 603 and 604 define opposite end surfaces of the first circuit chip 60 in the X-direction. In plan view, the chip side surfaces 601 and 602 define the long sides of the first circuit chip 60, and the chip side surfaces 603 and 604 define the short sides of the first circuit chip 60. In an example, the chip side surface 601 is located closer to the isolation chip 80 than the chip side surface 602 is. The chip side surface 602 is located closer to the first lead terminals 212, which are shown in FIG. 2, than the chip side surface 601 is.

The first circuit chip 60 includes the first electrodes 61, the second electrodes 62, and the third electrodes 63 formed on the chip main surface 60s. The first electrodes 61 are arranged on the chip main surface 60s along the chip side surface 602. The second electrodes 62 are arranged on the chip main surface 60s along the chip side surfaces 603 and 604. The third electrodes 63 are arranged on the chip main surface 60s along the chip side surface 601.

The first circuit chip 60 includes the transmission circuits 11A and 11B and the reception circuits 12A and 12B as functional blocks. The reception circuits 12A and 12B and the transmission circuits 11A and 11B are arranged between the first electrodes 61 and the third electrodes 63. The reception circuits 12A and 12B and the transmission circuits 11A and 11B are arranged in the first circuit chip 60 from the chip side surface 603 toward the chip side surface 604.

Some of the first electrodes 61 are electrically connected to the transmission circuits 11A and 11B. The transmission circuits 11A and 11B receive a pulse signal from the first electrodes 61. Some of the first electrodes 61 are connected to the reception circuits 12A and 12B. The reception circuits 12A and 12B output a pulse signal to the first electrodes 61.

The second electrodes 62 include ground pads 62G1 and 62G2 electrically connected to the first grounds GND1 (refer to FIG. 1) of the transmission circuits 11A and 11B and the reception circuits 12A and 12B. The ground pads 62G1 and 62G2 correspond to a “grounding pad.” The second electrodes 62 include power pads 62V1 and 62V2 configured to apply a first voltage (refer to FIG. 1) to the transmission circuits 11A and 11B and the reception circuits 12A and 12B.

The third electrodes 63 include transmission pads 63A electrically connected to the transmission circuits 11A and 11B and reception pads 63B electrically connected to the reception circuits 12A and 12B. The third electrodes 63 include ground pads 63C electrically connected to the ground pads 62G1 and 62G2. Two transmission pads 63A connected to each of the transmission circuits 11A and 11B are located at opposite sides of a ground pad 63C. Two reception pads 63B connected to the reception circuits 12A and 12B are located at opposite sides of a ground pad 63C. The transmission pad 63A and the reception pad 63B each correspond to a “signal pad.”

The isolation chip 80 includes three ground wires 64A, 64B, and 64C. The three ground wires 64A, 64B, and 64C are electrically connected between the two ground pads 62G1 and 62G2. The first ground wire 64A and the second ground wire 64B each correspond to a “first grounding wire.” The third ground wire 64C corresponds to a “second grounding wire.” The first ground wire 64A corresponds to a “reception grounding wire.” The second ground wire 64B corresponds to a “transmission grounding wire.” The three ground wires 64A to 64C may be electrically connected to one of the ground pad 62G1 and the ground pad 62G2.

The three ground wires 64A to 64C are separated from each other between the two ground pads 62G1 and 62G2. In other words, the three ground wires 64A to 64C are laid out in different paths between the two ground pads 62G1 and 62G2. The three ground wires 64A to 64C are isolated from each other.

The reception circuits 12A and 12B are electrically connected to the first ground wire 64A. The transmission circuits 11A and 11B are electrically connected to the second ground wire 64B. The ground pads 63C of the third electrodes 63 are electrically connected to the third ground wire 64C.

In the first circuit chip 60, two transmission pads 63A electrically connected to each of the transmission circuits 11A and 11B are located at opposite sides of a ground pad 63C. Thus, a drive signal supplied to the first coil 41 of the transformer 40A through the transmission pads 63A has only a negligible effect on the potential of the transmission pads 63A. Also, a drive signal supplied to the first coil 41 of the transformer 40B through the transmission pads 63A has only a negligible effect on the potential of the transmission pads 63A. This reduces mutual interferences between the drive signal of the transmission circuits 11A and 11B for driving the first coil 41 of the transformer 40A and the drive signal of the transmission circuits 11A and 11B for driving the first coil 41 of the transformer 40B. In the same manner, mutual interferences between reception signals through the reception pads 63B are reduced in the reception circuits 12A and 12B. Thus, transmission properties of the signal transmission device 100 are improved.

A comparative example in which the transmission circuits 11A and 11B, the reception circuits 12A and 12B, and the ground pads 63C are connected to a common ground wire will be described. The ground wire is the first ground GND1 shown in FIG. 1. For example, when the transmission circuit 11A uses an input pulse signal to drive the first coils 41 of the transformers 40A and 40B, the operation of the transmission circuit 11A may result in fluctuation of the potential of the first ground GND1. When the ground wire is common to the transmission circuits 11A and 11B and the reception circuits 12A and 12B, the potential changes at the first ground GND1 of the reception circuits 12A and 12B. The change in the potential may cause erroneous operations of the reception circuits 12A and 12B. The fluctuation in the potential of the first ground GND1 results in fluctuation in the potential of the ground pads 63C. This affects reception signals received by the first coils 41 of the transformers 40A and 40B. More specifically, an error may occur in a reception signal and an output pulse signal in the reception circuits 12A and 12B. This may adversely affect the transmission properties. The fluctuation in the potential of the first ground GND1 may also be caused by an operation of the reception circuits 12A and 12B. In this case, the fluctuation in the potential of the first ground GND1 may cause erroneous operation of the transmission circuits 11A and 11B and an error in a drive signal output from the transmission circuits 11A and 11B.

In the first circuit chip 60, the transmission circuits 11A and 11B, the reception circuits 12A and 12B, and the ground pads 63C are electrically connected to the ground pads 62G1 and 62G2 by the first to third ground wires 64A to 64C, which are isolated from each other. Thus, the fluctuation in the potential of the first ground GND1 caused by an operation of the transmission circuits 11A and 11B has only a negligible effect on the reception circuits 12A and 12B. Also, the fluctuation in the potential of the first ground GND1 caused by an operation of the reception circuits 12A and 12B has only a negligible effect on the transmission circuits 11A and 11B. As a result, the effect on the drive signal and the output pulse signal is reduced. Thus, the transmission properties of the signal transmission device 100 are improved.

### Circuit Configuration of Signal Transmission Device

The circuit configuration of the signal transmission device 100 will now be described.

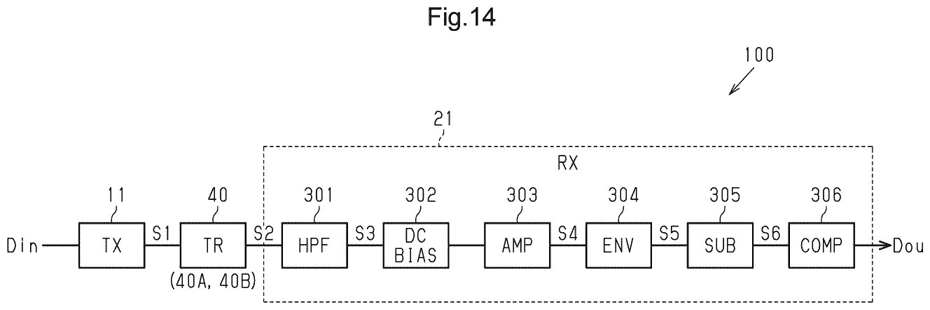

FIG. 14 is a schematic diagram showing the electrical configuration of the signal transmission device 100. FIG. 14 shows the transmission circuit 11 of the first circuit chip 60, the transformers 40A and 40B of the isolation chip 80, and the reception circuit 21 of the second circuit chip 70, which are shown in FIG. 1. The transmission circuit 22 of the second circuit chip 70 and the reception circuit 12 of the first circuit chip 60, which are shown in FIG. 1, have the same configuration and thus will not be described and will not be shown in the drawing.

When receiving an input pulse signal Din, the transmission circuit 11 outputs a transmission pulse signal S1 to the transformers 40A and 40B. Then, the transformers 40A and 40B transmit the transmission pulse signal S1 as a reception pulse signal S2 while isolating the transmission circuit 11 from the reception circuit 21. When receiving the reception pulse signal S2 from the transformers 40A and 40B, the reception circuit 21 outputs an output pulse signal Dout.

The reception circuit 21 includes a high-pass filter 301, a DC bias circuit 302, a nonlinear amplifier 303, an envelope detection circuit 304, a subtraction circuit 305, and a comparison circuit 306.

The high-pass filter 301 blocks low-frequency components of the reception pulse signal S2 that are lower than a cut-off frequency fc, and passes high-frequency components of the reception pulse signal S2 that are higher than the cut-off frequency fc to generate a filtered reception pulse signal S3.

The DC bias circuit 302 is connected to an output end of the high-pass filter 301 and sets a DC-bias of the filtered reception pulse signal S3.

The nonlinear amplifier 303 amplifies the filtered reception pulse signal S3 in a nonlinear region to generate an amplified reception pulse signal S4.

The envelope detection circuit 304 detects an envelope of the amplified reception pulse signal S4 and generates an envelope signal S5.

The subtraction circuit 305 mitigates undershoot of the envelope signal S5. When receiving the envelope signal S5, the subtraction circuit 305 generates a subtraction envelope signal S6.

The comparison circuit 306 compares the subtraction envelope signal S6 with a predetermined threshold value to generate the output pulse signal Dout.

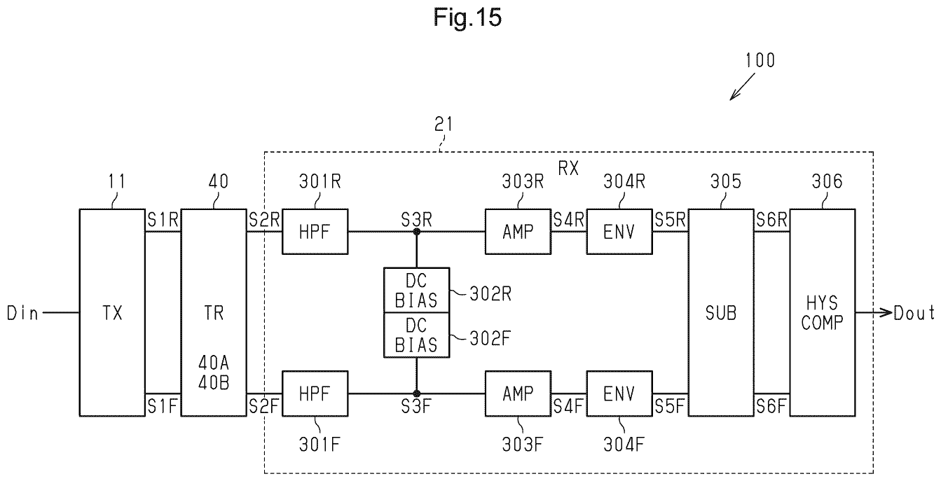

FIG. 15 is an example of a detailed electrical configuration of the signal transmission device 100.

In an example, the signal transmission device 100 generates a first signal triggered by a rising edge of the input pulse signal Din and a second signal triggered by a falling edge of the input pulse signal Din. The signal transmission device 100 processes the first signal and the second signal to output the output pulse signal Dout. That is, the signals S1 to S6 shown in FIG. 14 include signals corresponding to a “first signal” and a “second signal.” In the following description, a signal corresponding to the first signal is denoted by “R,” and a signal corresponding to the second signal is denoted by “F.”

When receiving the input pulse signal Din, the transmission circuit 11 generates each of a first transmission pulse signal S1R and a second transmission pulse signal S1F. In an example, the transmission circuit 11 uses a rising edge of the input pulse signal Din as a trigger to generate the first transmission pulse signal S1R. The first transmission pulse signal S1R may include one or more pulses. The transmission circuit 11 uses a falling edge of the input pulse signal Din as a trigger to generate the second transmission pulse signal S1F. The second transmission pulse signal S1F may include one or more pulses.

The reception circuit 21 processes a first reception pulse signal S2R and a second reception pulse signal S2F, which are output from the transformers 40A and 40B, to generate the output pulse signal Dout. In an example, the reception circuit 21 outputs a high-level output pulse signal Dout in accordance with pulse driving of the first reception pulse signal S2R. In an example, the reception circuit 21 outputs a low-level output pulse signal Dout in accordance with pulse driving of the second reception pulse signal S2F.

The transformers 40A and 40B transmit the first transmission pulse signal S1R as the first reception pulse signal S2R while isolating the transmission circuit 11 from the reception circuit 21. The transformers 40A and 40B transmit the second transmission pulse signal SIF as the second reception pulse signal S2F while isolating the transmission circuit 11 from the reception circuit 21.

The reception circuit 21 includes high-pass filters 301R and 301F, DC bias circuits 302R and 302F, nonlinear amplifiers 303R and 303F, the envelope detection circuits 304R and 304F, the subtraction circuit 305, and the comparison circuit 306.

The high-pass filter 301R blocks low-frequency components of the first reception pulse signal S2R that are lower than the cut-off frequency fc, and passes high-frequency components of the first reception pulse signal S2R that are higher than the cut-off frequency fc to generate a filtered first reception pulse signal S3R. The high-pass filter 301F blocks low-frequency components of the second reception pulse signal S2F that are lower than the cut-off frequency fc and passes high-frequency components of the second reception pulse signal S2F that are higher than the cut-off frequency fc to generate a filtered second reception pulse signal S3F.

The DC bias circuit 302R is connected to an output end of the high-pass filter 301R and sets a DC-bias of the filtered first reception pulse signal S3R. The DC bias circuit 302F is connected to an output end of the high-pass filter 301F and sets a DC-bias of the filtered second reception pulse signal S3F.

The nonlinear amplifier 303R amplifies the filtered first reception pulse signal S3R in a nonlinear region to generate a filtered first amplified reception pulse signal S4R. The nonlinear amplifier 303F amplifies the filtered second reception pulse signal S3F in a nonlinear region to generate a second amplified reception pulse signal S4F.

The envelope detection circuit 304R detects a positive-side envelope (i.e., envelope of the first amplified received pulse signal S4R that lies at the positive side of the DC bias) from the first amplified reception pulse signal S4R, which oscillates positively and negatively with respect to the DC bias, to generate a first positive envelope signal S5R. The envelope detection circuit 304F detects a positive-side envelope (i.e., envelope of the second amplified reception pulse signal S4F that lies at the positive side of the DC bias) from the second amplified reception pulse signal S4F, which oscillates positively and negatively with respect to the DC bias, to generate a second positive envelope signal S5F.

The subtraction circuit 305 mitigates undershoot of the first positive envelope signal S5R and the second positive envelope signal S5F. When receiving the first positive envelope signal S5R and the second positive envelope signal S5F, the subtraction circuit 305 generates a first subtraction envelope signal S6R and a second subtraction envelope signal S6F.

The comparison circuit 306 may include a differential-input hysteresis comparator configured to compare a difference value (=S6R−S6F) between the first subtraction envelope signal S6R and the second subtraction envelope signal S6F with a predetermined threshold value to generate the output pulse signal Dout. The comparison circuit 306 also serves as an in-phase noise canceler for the first subtraction envelope signal S6R and the second subtraction envelope signal S6F.

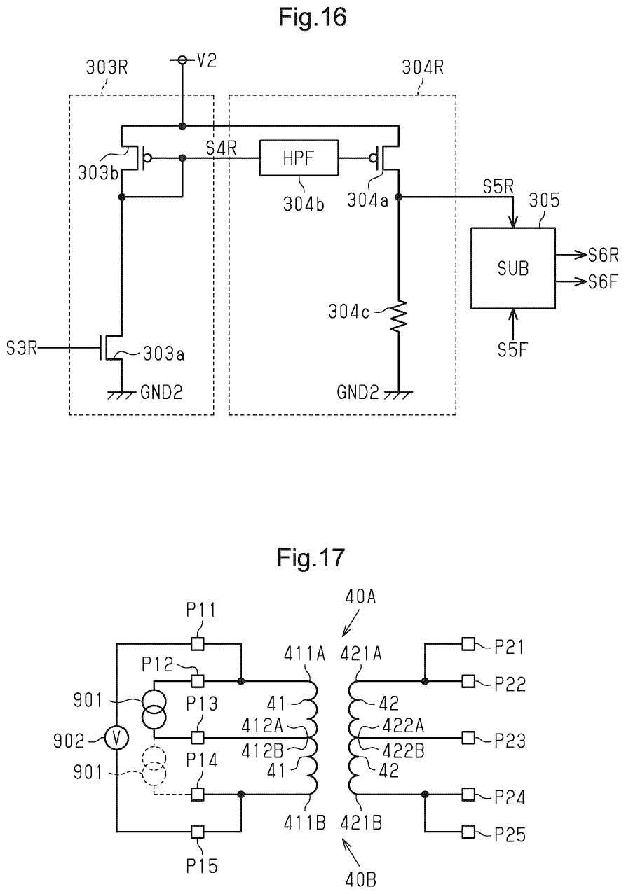

FIG. 16 is a diagram showing an exemplary configuration of the nonlinear amplifier 303R and the envelope detection circuit 304R.

The nonlinear amplifier 303R includes transistors 303a and 303b. The transistor 303a is, for example, an N-channel type MOSFET (NMOSFET). The transistor 303b is, for example, a P-channel type MOSFET (PMOSFET).

The filtered first reception pulse signal S3R is input into a gate terminal of the transistor 303a. A source terminal of the transistor 303a is connected to the second ground GND2. A drain terminal of the transistor 303a is connected to a drain terminal of the transistor 303b. The second voltage V2 is applied to a source terminal of the transistor 303b. A gate transistor of the transistor 303b is connected to a drain terminal of the transistor 303b. The nonlinear amplifier 303R generates the filtered first amplified reception pulse signal S4R having the levels of the gate terminal and the drain terminal of the transistor 303b.

The envelope detection circuit 304R includes a transistor 304a, a high-pass filter 304b, and a register 304c. The transistor 304a is, for example, a PMOSFET.

The filtered first amplified reception pulse signal S4R is input to the high-pass filter 304b. The high-pass filter 304b includes an output terminal connected to a gate terminal of the transistor 304a. The second voltage V2 is applied to a source terminal of the transistor 304a. A drain terminal of the transistor 304a is connected to a first end of the register 304c. The second ground GND2 is connected to a second end of the register 304c. The envelope detection circuit 304R generates the first positive envelope signal S5R having the level between the transistor 304a and the register 304c.

The nonlinear amplifier 303F and the envelope detection circuit 304F, which are shown in FIG. 15, basically have the same configuration as the nonlinear amplifier 303R and the envelope detection circuit 304R and thus will not be described and will not be shown in the drawing.

The signal transmission device 100 transmits the input pulse signal Din as the output pulse signal Dout while isolating the transmission circuit 11 from the reception circuit 21.

### Operation

The operation of the isolation chip 80 and the signal transmission device 100 will now be described.

The isolation chip 80 includes the insulation layer 84, the first coil 41 and the second coil 42 arranged in the insulation layer 84, and the second electrode 82 electrically connected to the second coil 42. The second coil 42 is annular in plan view as viewed in the Z-direction. The second electrode 82 includes the second inner electrode 82A extending over the inner region 42A surrounded by the second coil 42 and the region 42B that overlaps the second coil 42 in plan view. The passivation film 160, formed on the upper surface 84s of the insulation layer 84, includes the second inner opening 163 at least partially exposing the second inner electrode 82A. The second inner opening 163 extends above the second inner electrode 82A, and over the inner region 42A and the region 42B, which overlaps the second coil 42.

With the isolation chip 80 having the configuration described above, the inner region 42A surrounded by the second coil 42 is decreased in size in plan view as compared to, for example, a configuration in which the second coil 42 is formed to surround the second electrode 82. Ultimately, the area of the second coil 42 in plan view is reduced. The first coil 41 is opposed to the second coil 42 in the Z-direction. This decreases the area of the first coil 41 in plan view.

The first coil 41 and the second coil 42 are magnetically coupled to each other in the Z-direction. The magnetically coupling of the first coil 41 and the second coil 42 allows for transmission of a pulse signal. The first coil 41 and the second coil 42 are opposed to each other in the Z-direction. Thus, parasitic capacitance is formed between the first coil 41 and the second coil 42. The parasitic capacitance may cause noise in a signal transmitted between the first coil 41 and the second coil 42. As the parasitic capacitance is increased, common mode transient immunity (CMTI) of the signal transmission is decreased.

With the isolation chip 80 of the embodiment, the area of the second coil 42 and the first coil 41 in plan view is reduced. Thus, the isolation chip 80 reduces the parasitic capacitance between the second coil 42 and the first coil 41. This reduces noise on a signal transmitted between the first coil 41 and the second coil 42, thereby improving the common mode transient immunity (CMTI) of signal transmission. In other words, the signal transmission property of the signal transmission the isolation chip 80 and the signal transmission device 100 is improved.

As described above, in the isolation chip 80, the area of the second coil 42 and the first coil 41 in plan view is reduced. Hence, the isolation chip 80 is reduced in size. In addition, while minimizing an increase in the size of the isolation chip 80, the number of the first coils 41 and the second coils 42 formed in the isolation chip 80 is increased. This allows for an increase in the number of signals transmitted in a single isolation chip 80.

FIG. 17 is a schematic diagram used to illustrate inspection of the isolation chip 80.

FIG. 17 shows the first coil 41 and the second coil 42 of the transformer 40A and the first coil 41 and the second coil 42 of the transformer 40B.

The first coil 41 of the transformer 40A has a first end 411A connected to pads P11 and P12. The first coil 41 of the transformer 40A includes a second end 412A connected to a pad P13. The first coil 41 of the transformer 40B includes a second end 412B connected to the pad P13. The first coil 41 of the transformer 40B includes a first end 411B connected to pads P14 and P15. The pads P11 and P12 correspond to “two first pads P1 (refer to FIG. 11) of the first inner electrode 81A connected to the transformer 40A.” The pads P14 and P15 correspond to “two first pads P1 (refer to FIG. 11) of the first inner electrode 81A connected to the transformer 40B.” The pad P13 corresponds to the second pad P2 shown in FIG. 11.

The second coil 42 of the transformer 40A includes a first end 421A connected to the pads P21 and P22. The second coil 42 of the transformer 40A includes a second end 422A connected to a pad P23. The second coil 42 of the transformer 40B has a second end 422B connected to the pad P23. The second coil 42 of the transformer 40B includes a first end 421B connected to pads P24 and P25. The pads P21 and P22 correspond to “two third pads P1 (refer to FIG. 11) of the second inner electrode 82A connected to the transformer 40A.” The pads P24 and P25 correspond to “two third pads P1 (refer to FIG. 11) of the second inner electrode 82A connected to the transformer 40B.” The pad P23 corresponds to the fourth pad P4 shown in FIG. 11.

A constant current source 901 and a voltmeter 902 are used to inspect the isolation chip 80.

In inspection of the isolation chip 80, the constant current source 901 is used to sequentially apply a constant current to the first coil 41 and the second coil 42 of the transformer 40A and the first coil 41 and the second coil 42 of the transformer 40B. Then, the voltmeter 902 is used to sequentially measure the voltage (potential difference) between the first coil 41 and the second coil 42 of the transformer 40A and the first coil 41 and the second coil 42 of the transformer 40B. The state (satisfactory or not satisfactory) of the isolation chip 80 is determined based on the measurement results.

The constant current source 901 is connected between the pad P12 and the pad P13 and applies a constant current to the first coil 41 of the transformer 40A. As a result, a potential difference is generated between the pad P12 and the pad P13 in accordance with the constant current flowing to the first coil 41 and the resistance components of the pads P12 and P13. The voltmeter 902 is connected between the pad P11 and the pad P15, and the voltage (potential difference) between the two terminals of the first coil 41 is measured by the voltmeter 902. Based on the measured voltage, an anomaly in the resistance value of the first coil 41 of the transformer 40A is determined. Examples of such an anomaly include a disconnection between the pads P11 and P15 and a short in the winding of the first coil 41. With this inspection, a defective isolation chip 80 is appropriately rejected.

To measure a potential difference between the two ends of the first coil 41 of the transformer 40A, the second end 412A of the first coil 41 may be provided with two pads. In the present embodiment, the pad P15 is connected to the second end 412A of the first coil 41 of the transformer 40A through the first coil 41 of the transformer 40B. The constant current flows to only the first coil 41 of the transformer 40A and does not flow to the first coil 41 of the transformer 40B. Thus, the potential of the pad P15 is substantially equal to the potential of the second end 412A of the first coil 41. Hence, the voltage is measurable at the two ends of the first coil 41 without providing the second end 412A of the first coil 41 with two pads. Thus, the isolation chip 80 is reduced in size as compared to when the second end of the first coil 41 is provided with two pads.

As indicated by broken lines shown in FIG. 17, the constant current source 901 is connected between the pad P14 and the pad P13 and applies a constant current to the first coil 41 of the transformer 40B. The voltmeter 902 connected between the pad P11 and the pad P15 is used to measure the voltage (potential difference) between the two terminals of the first coil 41. When the constant current source 901 is connected to the pad P14, the state of the first coil 41 of the transformer 40B is determined. This dispenses with the task for changing the connection of the voltmeter 902.

In the same manner, when the constant current source 901 is connected to the pads P22 and P23, the state of the second coil 42 of the transformer 40A is determined based on voltage measured by the voltmeter 902 connected to the pads P21 and P25. Also, when the constant current source 901 is connected to the pads P24 and P23, the state of the second coil 42 of the transformer 40B is determined based on voltage measured by the voltmeter 902 connected to the pads P21 and P25.

### Advantages

As described above, the signal transmission device 100 has the following advantages.
(1) The isolation chip 80 includes the insulation layer 84, the first coil 41 and the second coil 42 arranged in the insulation layer 84, and the second electrode 82 electrically connected to the second coil 42. The second coil 42 is annular in plan view as viewed in the Z-direction. The second electrode 82 includes the second inner electrode 82A extending over the inner region 42A surrounded by the second coil 42 and the region 42B that overlaps the second coil 42 in plan view. The passivation film 160, formed on the upper surface 84s of the insulation layer 84, includes the second inner opening 163 at least partially exposing the second inner electrode 82A. The second inner opening 163 extends above the second inner electrode 82A, and over the inner region 42A and the region 42B, which overlaps the second coil 42.

With the isolation chip 80 having the configuration described above, the inner region 42A surrounded by the second coil 42 is decreased in size in plan view as compared to, for example, a configuration in which the second coil 42 is formed to surround the second electrode 82. Ultimately, the area of the second coil 42 in plan view is reduced. The first coil 41 is opposed to the second coil 42 in the Z-direction. This decreases the area of the first coil 41 in plan view.
(2) The isolation chip 80 of the embodiment reduces the area of the second coil 42 and the first coil 41 in plan view. Thus, the isolation chip 80 reduces the parasitic capacitance between the second coil 42 and the first coil 41. This reduces noise on a signal transmitted between the first coil 41 and the second coil 42, thereby improving the common mode transient immunity (CMTI) of signal transmission. In other words, the signal transmission property of the signal transmission the isolation chip 80 and the signal transmission device 100 is improved.
(3) In the isolation chip 80, the area of the second coil 42 and the first coil 41 in plan view is reduced. Hence, the isolation chip 80 is reduced in size. In addition, while minimizing an increase in the size of the isolation chip 80, the number of the first coils 41 and the second coils 42 formed in the isolation chip 80 is increased. This allows for an increase in the number of signals transmitted in a single isolation chip 80.
(4) The first circuit chip 60 includes the three ground wires 64A, 64B, and 64C isolated from each other. The reception circuits 12A and 12B are connected to the first ground wire 64A. The transmission circuits 11A and 11B are connected to the second ground wire 64B. The ground pad 63C connected to the isolation chip 80 is connected to the third ground wire 64C. The three ground wires 64A, 64B, and 64C, which are isolated from each other, limit erroneous operation of the first circuit chip 60, thereby improving the signal transmission property.

### MODIFIED EXAMPLES

The embodiments may be modified, for example, as follows. The above embodiment and the modified examples described below may be combined as long as there is no technical contradiction. In the following modified examples, the same reference characters are given to those components that are the same as the corresponding components of the above embodiments. Such components will not be described in detail.

The configuration of the isolation chip 80 may be changed.

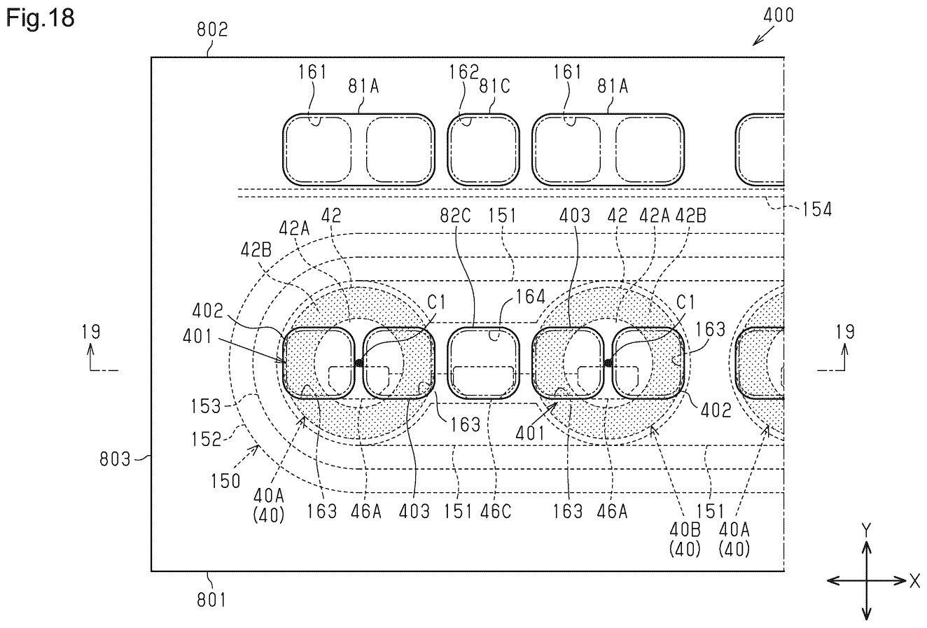

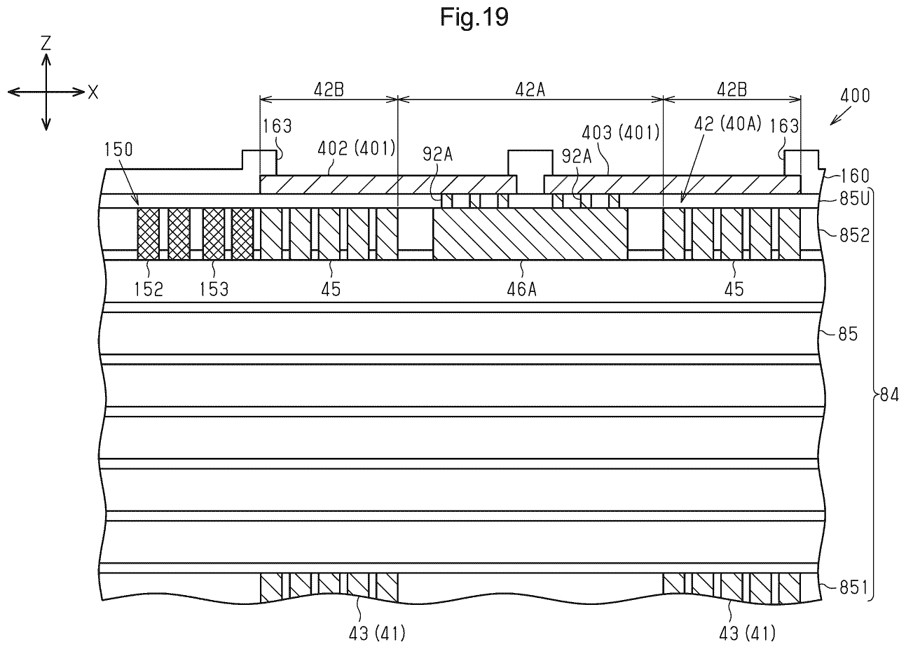

As shown in FIG. 18 and FIG. 19, an isolation chip 400 includes a second inner electrode 401. The second inner electrode 401 may include two electrode plates 402 and 403. The two electrode plates 402 and 403 each extend over the inner region 42A surrounded by the second coil 42 and the region 42B overlapping the second coil 42 in plan view. The two electrode plates 402 and 403 each are electrically connected to the inner end wire 46A by a via 92A. The second inner openings 163 are formed in the passivation film 160 to partially expose the two electrode plates 402 and 403, respectively.

When the second inner electrode 401 includes the two electrode plates 402 and 403, generation of an eddy current in the second inner electrode 401 is limited. In the isolation chip 400, a transmission pulse signal causes current to flow through the first coil 41 and generates a magnetic flux, and the magnetic flux causes a signal to transmit from the first coil 41 to the second coil 42. An eddy current results in a loss of the magnetic flux generated by the current flowing through the first coil 41, thereby decreasing the efficiency of the magnetic coupling between the first coil 41 and the second coil 42. Since generation of an eddy current is limited, the loss of the magnetic flux is reduced, and the efficiency of the magnetic coupling is improved. Thus, the transmission property between the first coil 41 and the second coil 42 is improved.

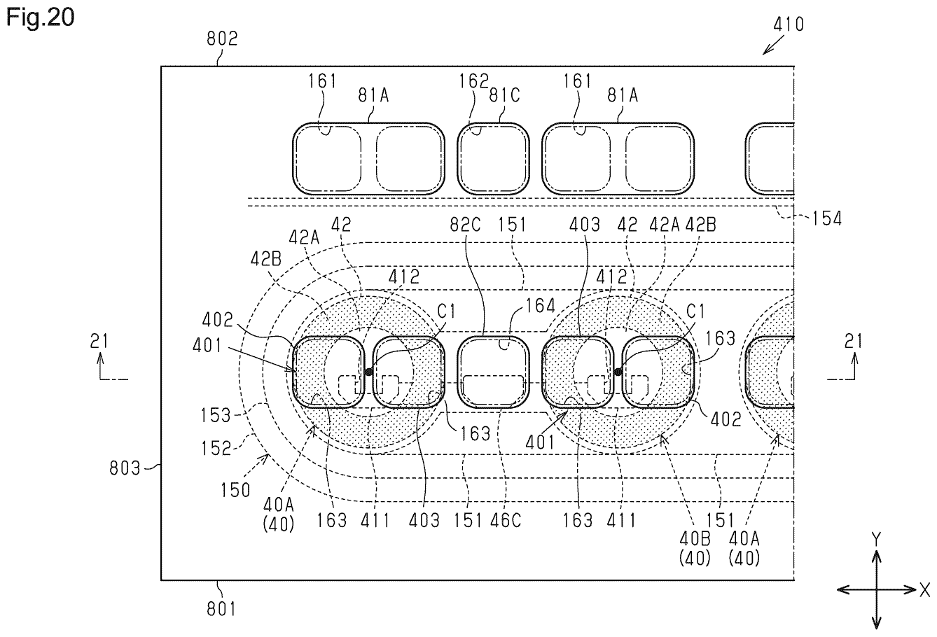

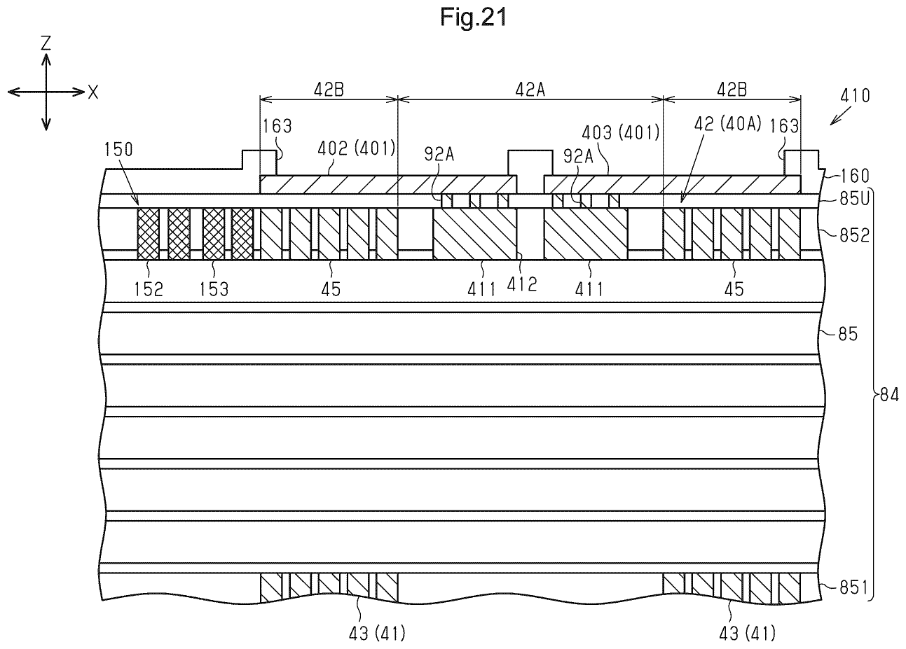

As shown in FIG. 20 and FIG. 21, an isolation chip 410 includes the second inner electrode 401 and an inner end wire 411. The second inner electrode 401 includes two electrode plates 402 and 403. The inner end wire 411 has a slit 412 extending from a center C1 of the second coil 42 to an outer side of the second coil 42. The slit 412 limits generation of an eddy current in the inner end wire 411. Thus, the transmission property between the first coil 41 and the second coil 42 is improved as compared to the isolation chip 410 shown in FIG. 18 and FIG. 19.

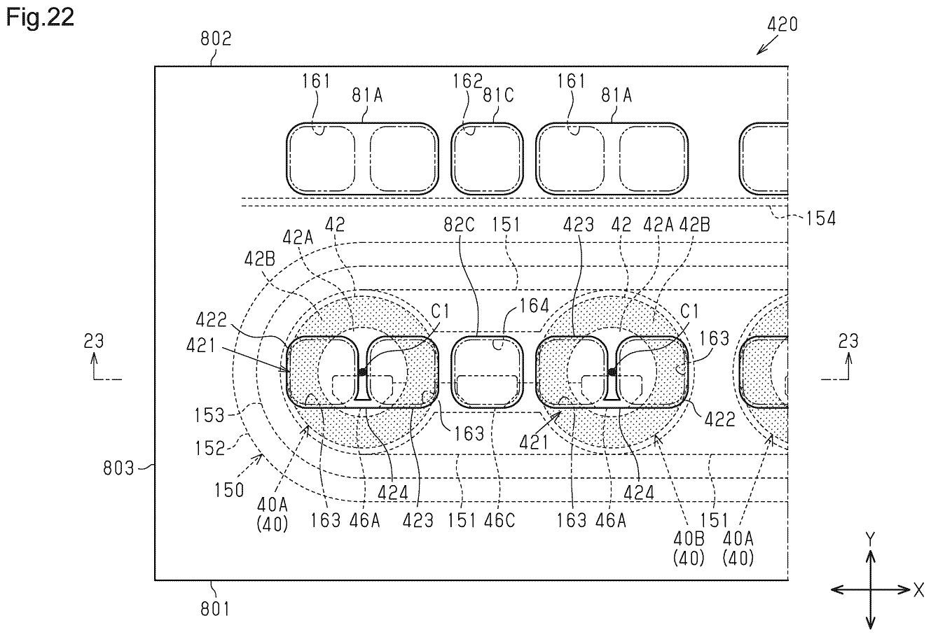

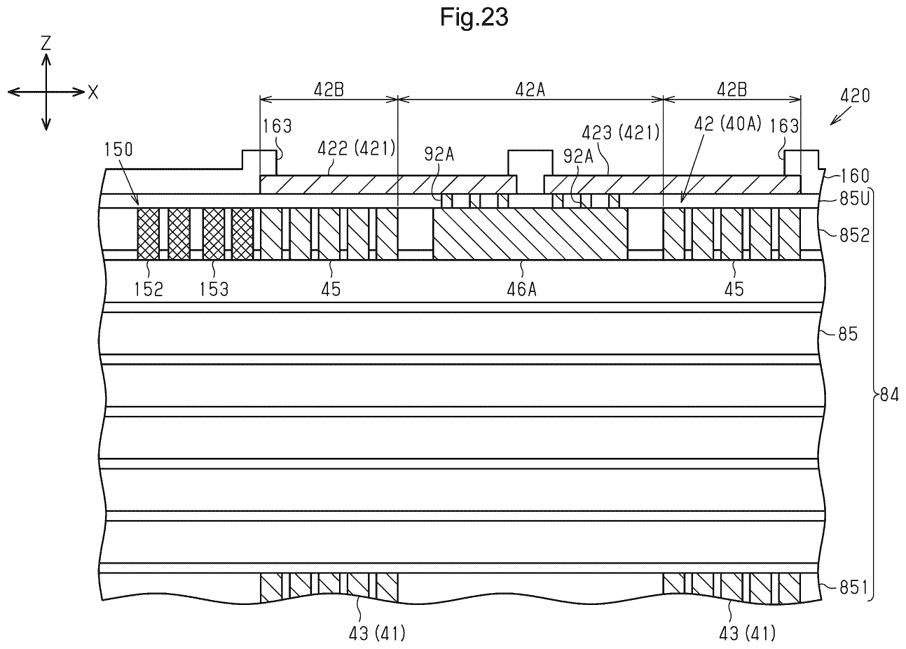

As shown in FIG. 22 and FIG. 23, an isolation chip 420 includes a second inner electrode 421. The second inner electrode 421 includes two electrode plates 422 and 423 and a narrow portion 424 between the two electrode plates 422 and 423. The narrow portion 424 has a smaller width than a portion of the second inner electrode 421 located between the second inner openings 163, which partially expose the electrode plates 422 and 423, where the second inner openings 163 are formed in the Y-direction. The narrow portion 424 electrically connects the electrode plates 422 and 423. This allows the electrode plates 422 and 423 to have the same potential. The narrow portion 424 is displaced from the center C1 of the second coil 42 in the Y-direction. In an example, the narrow portion 424 overlaps the inner end wire 46A in plan view. The position of the narrow portion 424 may be changed. The narrow portion 424 may be arranged, for example, so as not to overlap the inner end wire 46A in plan view. The isolation chip 420 limits generation of an eddy current in the second inner electrode 421, thereby improving the transmission property between the first coil 41 and the second coil 42.

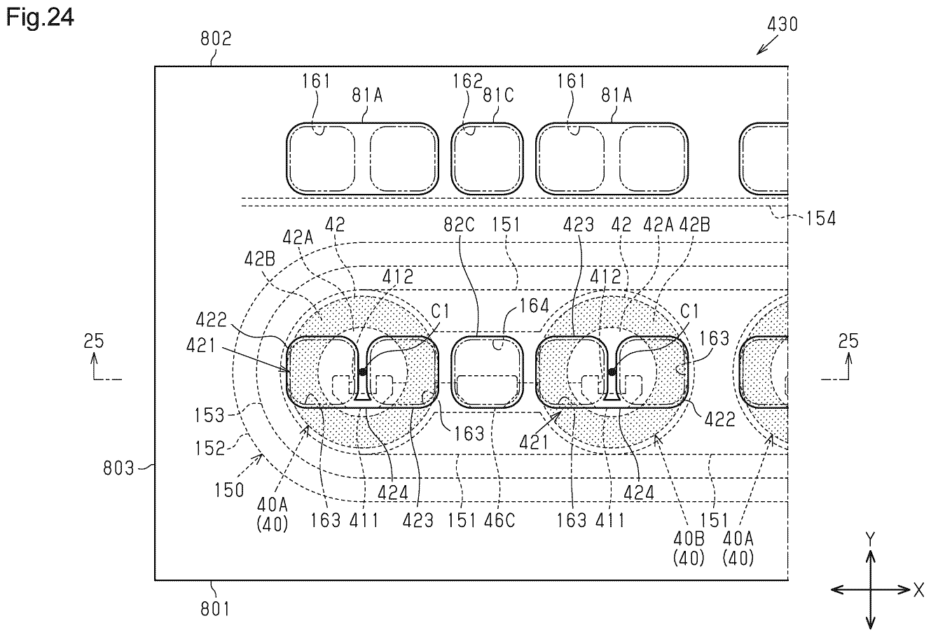

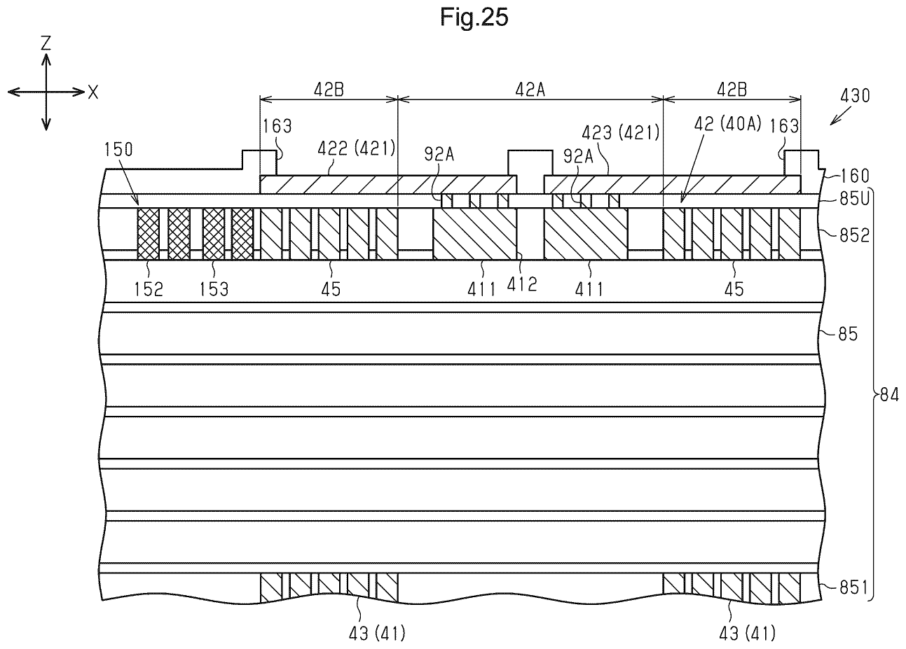

As shown in FIG. 24 and FIG. 25, an isolation chip 430 includes the second inner electrode 421 and the inner end wire 411. The second inner electrode 421 includes two electrode plates 422 and 423 and a narrow portion 424 between the two electrode plates 422 and 423. The inner end wire 411 has a slit 412. The isolation chip 430 further limits generation of an eddy current, thereby improving the transmission property between the first coil 41 and the second coil 42.

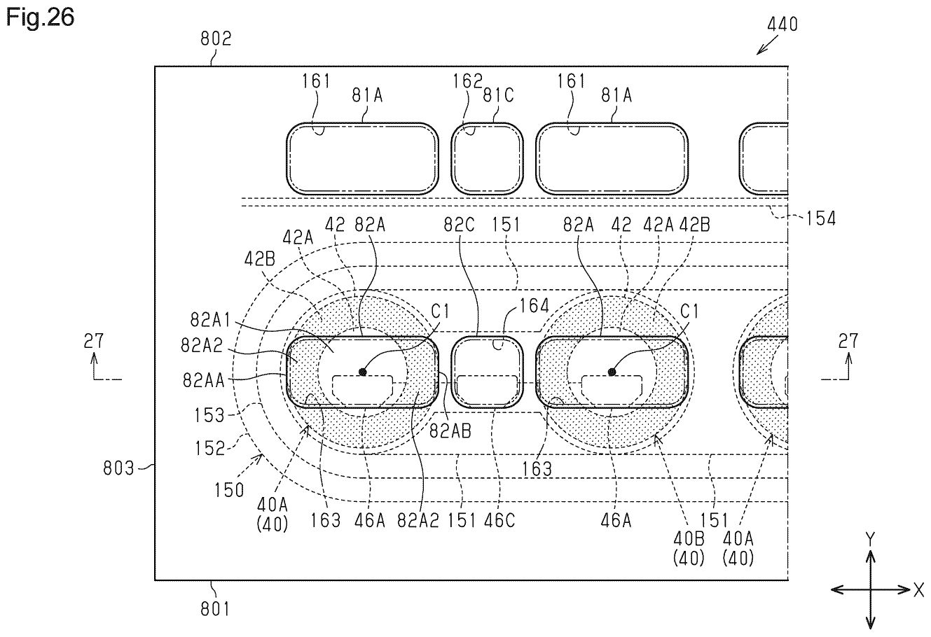

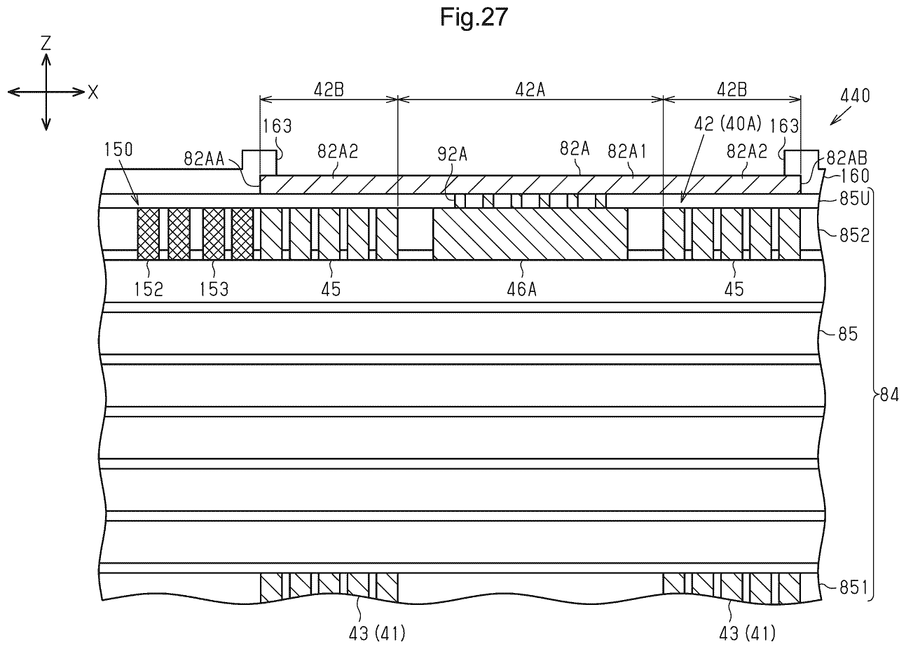

As shown in FIG. 26 and FIG. 27, in an isolation chip 440, the second inner electrode 82A may be partially exposed from a single second inner opening 163. That is, the passivation film 160 includes one second inner opening 163 partially exposing the second inner electrode 82A. The second inner opening 163 extends above the second inner electrode 82A, and over the inner region 42A and the region 42B, which overlaps the second coil 42. The first inner electrode 81A may be partially exposed from a single first inner opening 161. The passivation film 160 includes one first inner opening 161 partially exposing the first inner electrode 81A.

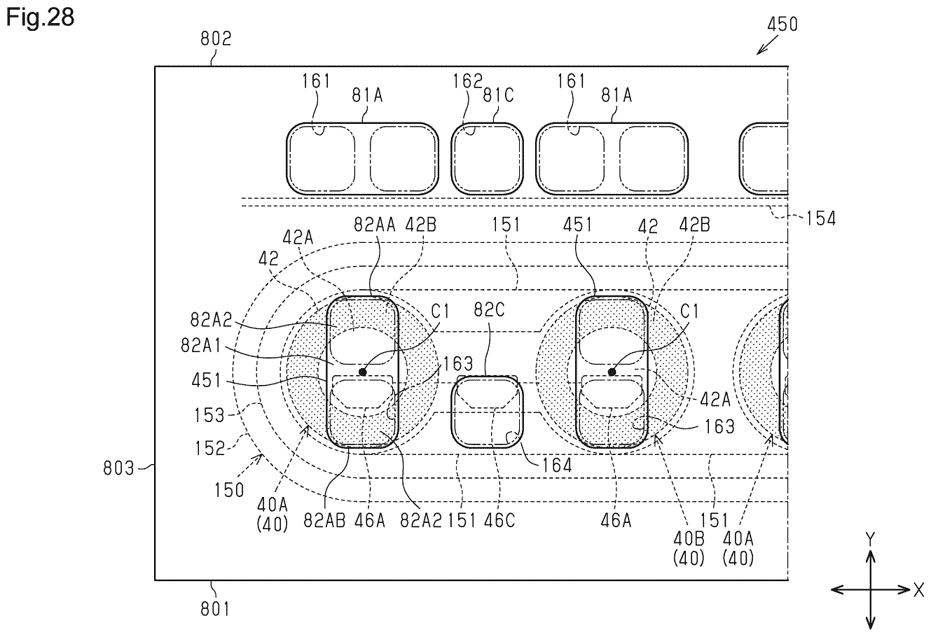

As shown in FIG. 28, an isolation chip 450 includes a second inner electrode 451. The second inner electrode 451 may be rectangular and longer in the Y-direction than in the X-direction. In this configuration, the second outer electrode 82C, which is located between the two second coils 42, may be displaced from the center C1 of the second coil 42 in the Y-direction. Alternatively, the second outer electrode 82C may coincide with the center C1 of the second coil 42 in the Y-direction.

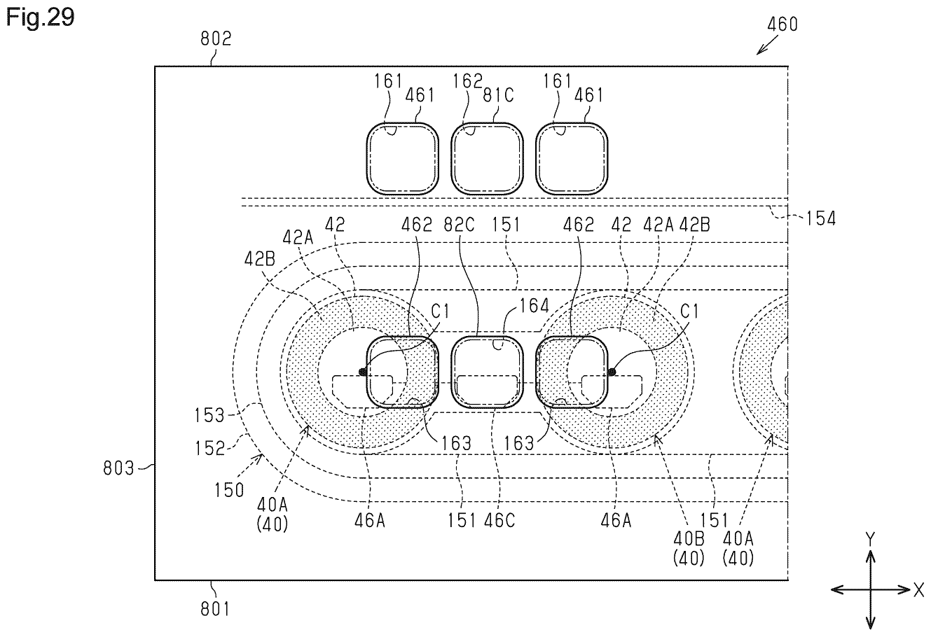

As shown in FIG. 29, an isolation chip 460 includes a first inner electrode 461 and a second inner electrode 462. The first inner electrode 461 may be square and equal in length in the X-direction and the Y-direction. In the same manner as the embodiment, the first inner electrode 461 may be rectangular and elongated in the X-direction. The second inner electrode 462 may be square and equal in length in the X-direction and the Y-direction. In this configuration, the second inner electrode 462 is displaced from the center C1 of the second coil 42 in the X-direction. In an example, the second inner electrode 462 is located toward the second outer electrode 82C. Alternatively, the second inner electrode 462 may be displaced from the center C1 of the second coil 42 toward a side opposite to the second outer electrode 82C. In other words, the second inner electrode 462 is located away from the second outer electrode 82C. In the X-direction, the position of the first inner electrode 461 may be the same as or different from the position of the second inner electrode 462.

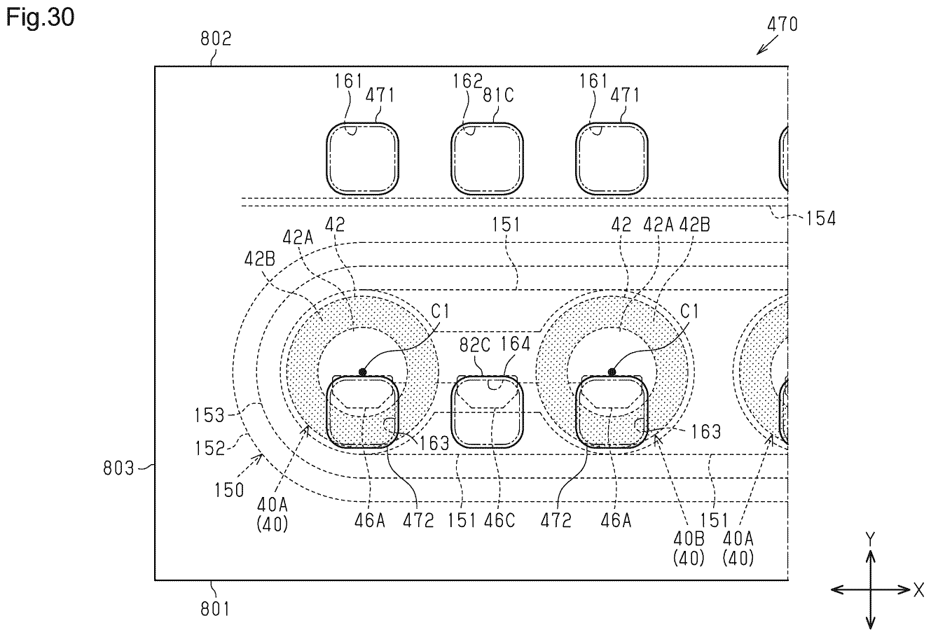

As shown in FIG. 30, an isolation chip 470 includes a first inner electrode 471 and a second inner electrode 472. The first inner electrode 471 may be square and equal in length in the X-direction and the Y-direction. In the same manner as the embodiment, the first inner electrode 471 may be rectangular and elongated in the X-direction. The second inner electrode 472 may be square and equal in length in the X-direction and the Y-direction. The second inner electrode 472 may be displaced from the center C1 of the second coil 42 in the Y-direction. In an example, the second inner electrode 472 may be displaced from the center C1 of the second coil 42 toward a side opposite to the first inner electrode 471. In other words, the second inner electrode 472 is located away from the first inner electrode 471. In the X-direction, the position of the first inner electrode 471 may be the same as or different from the position of the second inner electrode 472.

The second coil 42 may have any shape in plan view.

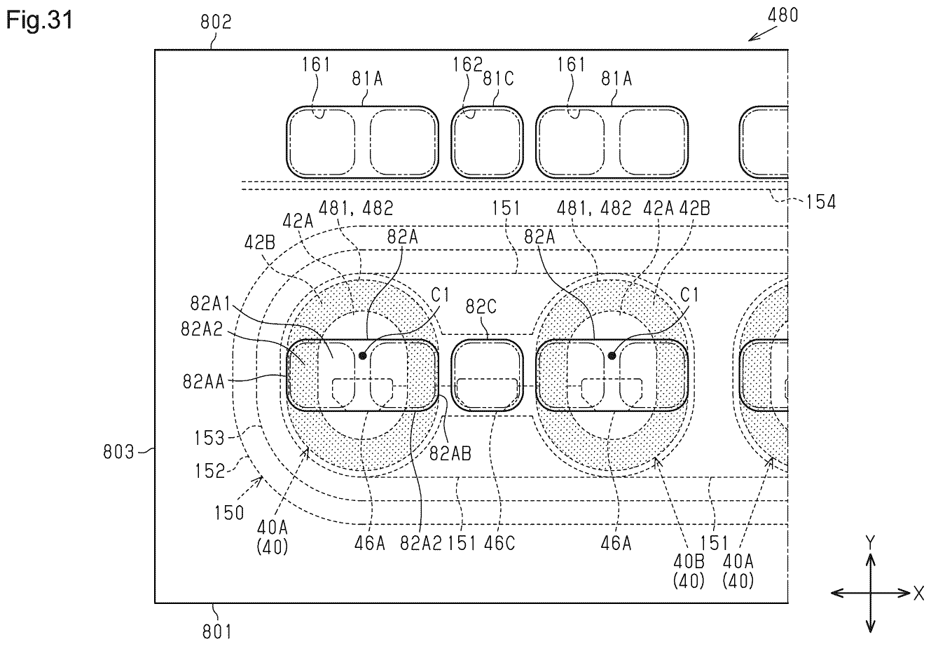

As shown in FIG. 31, an isolation chip 480 includes transformers 40A and 40B, each of which includes a first coil 481 and a second coil 482. In plan view, the first coil 481 and the second coil 482 may each have an oblong spiral shape that is greater in the Y-direction than the X-direction. The shape of the first coil 41 and the second coil 42 in plan view may be a circle, an oblong, an ellipse, a polygon (octagon), or any other shape.

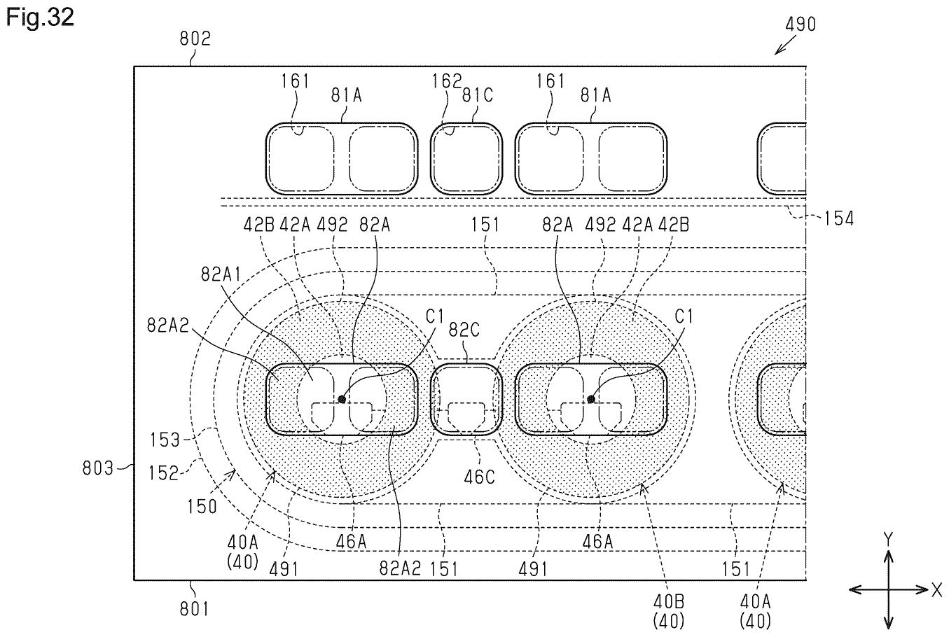

As shown in FIG. 32, an isolation chip 490 includes transformers 40A and 40B, each of which includes a first coil 491 and a second coil 492. The second coil 492 may overlap the second outer electrode 82C in plan view. In an example, the number of wiring turns in the first coil 491 and the second coil 492 is increased to increase the amount of magnetic flux, thereby improving the magnetic coupling. In plan view, the size of the first coil 491 and the second coil 492 may be the same as the size of the first coil 41 and the second coil 42 in the embodiment. In this case, the distance between the second coil 492 of the transformer 40A and the second coil 492 of the transformer 40B may be shortened to reduce the size of the isolation chip 490.

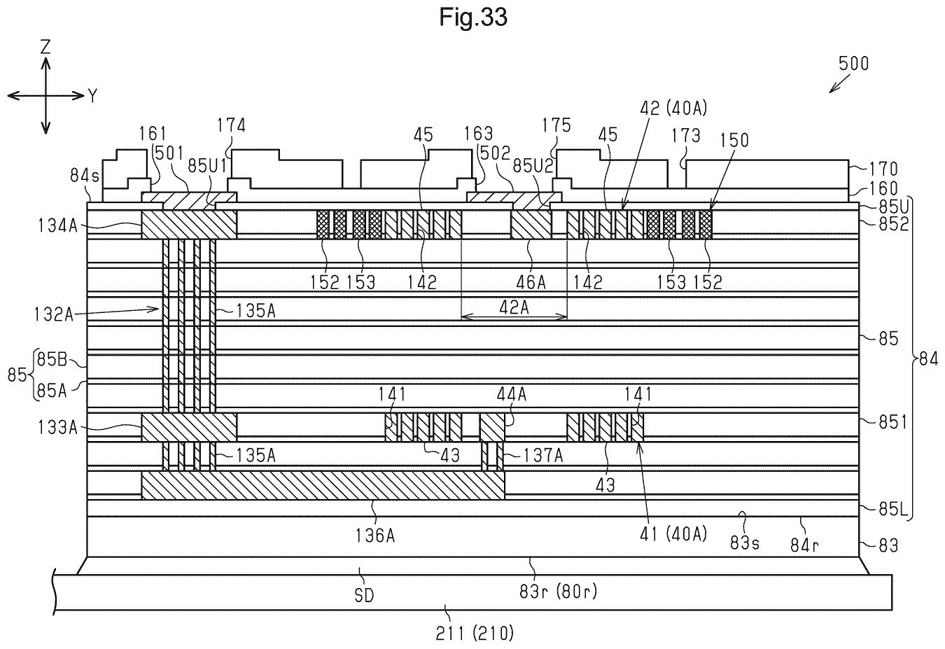

As shown in FIG. 33, an isolation chip 500 includes a first inner electrode 501 and a second inner electrode 502. The first inner electrode 501 and the second inner electrode 502 are formed on the upper surface 84s of the insulation layer 84. The insulation film 85U of the insulation layer 84 includes an opening 85U1 partially exposing the upper surface of the interconnect piece 134A. The first inner electrode 501 is in contact with the upper surface of the interconnect piece 134A in the opening 85U1 of the insulation film 85U and is electrically connected to the interconnect piece 134A.

The insulation film 85U of the insulation layer 84 includes an opening 85U2 partially exposing the upper surface of the inner end wire 46A. The second inner electrode 502 is in contact with the upper surface of the inner end wire 46A in the opening 85U2 of the insulation film 85U and is electrically connected to the inner end wire 46A. Although not shown, the first outer electrode 81C may have the same configuration as the first inner electrode 501. Also, the second outer electrode 82C may have the same configuration as the second inner electrode 502.

In the embodiment, the electrical configuration of the first circuit chip 60 and the second circuit chip 70 may be changed in any manner.

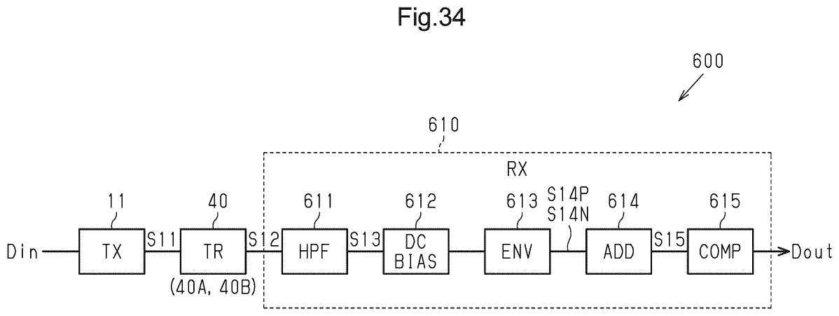

FIG. 34 is a schematic diagram showing the electrical configuration of a signal transmission device 600 in a modified example.

The signal transmission device 600 of the modified example includes the transmission circuit 11, transformers 40 (40A, 40B), and a reception circuit 610. The reception circuit 610 is included in the second circuit chip 70 shown in FIG. 1. The reception circuit 12 of the first circuit chip 60 shown in FIG. 1 may have the same configuration as the reception circuit 610.

The transmission circuit 11 uses at least one of a rising edge and a falling edge of the input pulse signal Din as a trigger to generate the transmission pulse signal S11. The transmission pulse signal S11 may include at least one of a first transmission pulse signal S11R generated when the trigger is the rising edge of the input pulse signal Din and a second transmission pulse signal S11F generated when the trigger is the falling edge of the input pulse signal Din. The transformers 40 transmit the transmission pulse signal S11 as a reception pulse signal S12 while electrically isolating the transmission circuit 11 from the reception circuit 610.

When receiving the reception pulse signal S12 from the transformers 40, the reception circuit 610 outputs an output pulse signal Dout. The reception pulse signal S12 may include at least one of a first reception pulse signal S12R corresponding to the first transmission pulse signal S11R and a second reception pulse signal S12F corresponding to the second transmission pulse signal S11F.

The reception circuit 610 includes a high-pass filter 611, a DC bias circuit 612, an envelope detection circuit 613, an addition circuit 614, and a comparison circuit 615.

The high-pass filter 611 blocks low-frequency components of the reception pulse signal S12 that are lower than the cut-off frequency fc, and passes high-frequency components of the reception pulse signal S12 that are higher than the cut-off frequency fc to generate a filtered reception pulse signal S13. The filtered reception pulse signal S13 may include a filtered reception pulse signal S13R corresponding to the first reception pulse signal S12R and a filtered reception pulse signal S13F corresponding to the second reception pulse signal S12F.

The DC bias circuit 612 is connected to an output end of the high-pass filter 611 and sets a DC-bias of the filtered reception pulse signal S13.

The envelope detection circuit 613 generates a positive envelope signal S14P and a negative envelope signal S14N from the filtered reception pulse signal S13. The envelope detection circuit 613 includes, for example, a positive envelope detection circuit exhibiting high responsiveness to only a positive voltage waveform of the filtered reception pulse signal S13 with respect to the DC bias, and a negative envelope detection circuit exhibiting high responsiveness to only a negative voltage waveform of the filtered reception pulse signal S13 with respect to the DC bias.

The addition circuit 614 receives the positive envelope signal S14P and the negative envelope signal S14N to generate the addition envelope signal S15. The addition circuit 614 may be, for example, an addition amplifier that inverts one of the positive envelope signal S14P and the negative envelope signal S14N and adds the inverted signal to the other to generate the addition envelope signal S15.

In an example, the comparison circuit 615 compares the addition envelope signal S15 with a predetermined threshold value to generate the output pulse signal Dout.

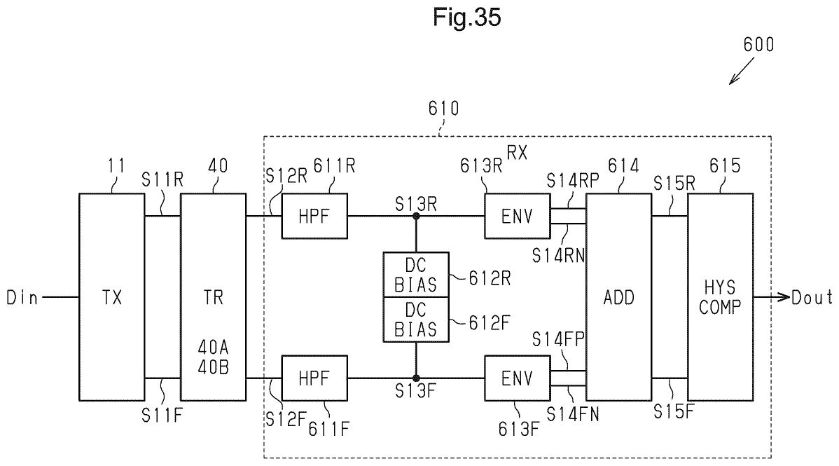

FIG. 35 is an example of a detailed electrical configuration of the signal transmission device 600 shown in FIG. 34.

The transmission circuit 11 generates the first transmission pulse signal S11R when the trigger is the rising edge of the input pulse signal Din, and the second transmission pulse signal S11F when the trigger is the falling edge of the input pulse signal Din. The first transmission pulse signal S11R may include one or more pulses. The second transmission pulse signal S11F may include one or more pulses.

The transformers 40 transmit the first transmission pulse signal S11R as the first reception pulse signal S12R while electrically isolating the transmission circuit 11 from the reception circuit 610.

The transformers 40B transmit the second transmission pulse signal S11F to the second reception pulse signal S12F while electrically isolating the transmission circuit 11 from the reception circuit 610.

The reception circuit 610 includes high-pass filters 611R and 611F, DC bias circuits 612R and 612F, envelope detection circuits 613R and 613F, an addition circuit 614, and a comparison circuit 615.

The high-pass filter 611R blocks low-frequency components of the first reception pulse signal S12R that are lower than the cut-off frequency fc, and passes high-frequency components of the first reception pulse signal S12R that are higher than the cut-off frequency fc to generate a filtered first reception pulse signal S13R.

The high-pass filter 611F blocks low-frequency components of the second reception pulse signal S12F that are lower than the cut-off frequency fc and passes high-frequency components of the second reception pulse signal S12F that are higher than the cut-off frequency fc to generate a filtered second reception pulse signal S13F.

The DC bias circuit 612R is connected to an output end of the high-pass filter 611R and sets a DC-bias of the filtered first reception pulse signal S13R.

The DC bias circuit 612F is connected to an output end of the high-pass filter 611F and sets a DC-bias of the filtered second reception pulse signal S13F.

The envelope detection circuit 613R detects a positive-side envelope from the filtered first reception pulse signal S13R, which oscillates positively and negatively with respect to the DC bias as the reference potential, to generate a first positive envelope signal S14RP. The envelope detection circuit 613R also detects a negative-side envelope from the filtered first reception pulse signal S13R, which oscillates positively and negatively with respect to the DC bias as the reference potential, to generate a first negative envelope signal S14RN.

The envelope detection circuit 613F detects a positive-side envelope from the filtered second reception pulse signal S13F, which oscillates positively and negatively with respect to the DC bias as the reference potential, to generate a second positive envelope signal S14FP. The envelope detection circuit 613F also detects a negative-side envelope from the filtered first reception pulse signal S13F, which oscillates positively and negatively with respect to the DC bias as the reference potential, to generate a second negative envelope signal S14FN.

The addition circuit 614 is configured to receive the first positive envelope signal S14RP, the first negative envelope signal S14RN, the second positive envelope signal S14FP, and the second negative envelope signal S14FN and serves as a signal amplifier and an in-phase noise canceler.

The addition circuit 614 inverts and adds the second positive envelope signal S14FP to the first positive envelope signal S14RP to generate a first addition envelope signal S15R. The addition circuit 614 inverts and adds the second negative envelope signal S14FN to the first negative envelope signal S14RN to generate a second addition envelope signal S15F. The addition circuit 614 may be, for example, a differential-input addition amplifier. The comparison circuit 615 compares a difference value (=S15P−S15N) between the first addition envelope signal S15R and the second addition envelope signal S15F and a predetermined threshold value to generate the output pulse signal Dout. The comparison circuit 615 may include a differential-input hysteresis comparator. The comparison circuit 615 also serves as an in-phase noise canceler for each of the first addition envelope signal S15R and the second addition envelope signal S15F.

The reception circuit 610 of the comparative example, which differs from the reception circuit 21 (refer to FIG. 15) of the nonlinear amplifiers 303R and 303F, does not experience undershoot during application of a signal. This eliminates the need for measures (e.g., subtraction circuit 305 described above) for mitigating undershoot.

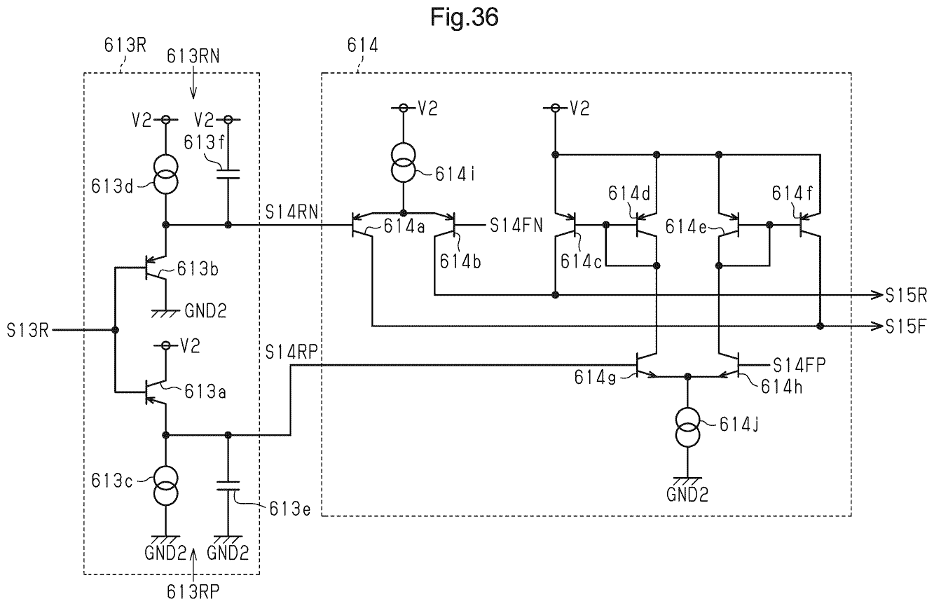

FIG. 36 is a diagram showing an exemplary configuration of the envelope detection circuit 613 and the addition circuit 614.

The envelope detection circuit 613R includes transistors 613a and 613b, current sources 613c and 613d, and capacitors 613e and 613f. The transistor 613a is, for example, an NPN transistor. The transistor 613b is, for example, a PNP transistor.

The second voltage V2 is applied to a collector terminal of the transistor 613a. The filtered first reception pulse signal S13R is input to a gate terminal of the transistor 613a. An emitter terminal of the transistor 613a is connected to a first end of the current source 613c and a first end of the capacitor 613e. The current source 613c generates a constant current that is set to a sufficiently small value. The capacitor 613e may be a parasitic capacitance. A second end of the current source 613c and a second end of the capacitor 613e are connected to the second ground GND2. The transistor 613a, the current source 613c, and the capacitor 613e, which are connected as described above, serve as a positive envelope detection circuit 613RP that receives the filtered first reception pulse signal S13R and outputs the first positive envelope signal S14RP.

The second ground GND2 is connected to a collector terminal of the transistor 613b. The filtered first reception pulse signal S13R is input to a gate terminal of the transistor 613b. An emitter terminal of the transistor 613b is connected to a second end of the current source 613d and a second end of the capacitor 613f. The second voltage V2 is applied to a first end of the current source 613d and a first end of the capacitor 613f. The current source 613d generates a constant current that is set to a sufficiently small value. The capacitor 613f may be a parasitic capacitance. The transistor 613b, the current source 613d, and the capacitor 613f, which are connected as described above, serve as a negative envelope detection circuit 613RN that receives the filtered first reception pulse signal S13R and outputs the first negative envelope signal S14RN.

The positive envelope detection circuit 613RP and the negative envelope detection circuit 613RN each include an emitter follower to achieve high responsiveness. The transistors 613a and 613b may each be a MOSFET. The positive envelope detection circuit 613RP and the negative envelope detection circuit 613RN may each include a source follower.

The positive envelope detection circuit 613RP and the negative envelope detection circuit 613RN, which have the circuit configuration described above, differ in drive performance in accordance with the positive and negative polarities of the filtered first reception pulse signal S13R.

More specifically, the positive envelope detection circuit 613RP is highly responsive to only a positive voltage of the filtered first reception pulse signal S13R with respect to the DC bias to generate the first positive envelope signal S14RP. The negative envelope detection circuit 613RN is highly responsive to only a negative voltage of the filtered first reception pulse signal S13R with respect to the DC bias to generate the first negative envelope signal S14RN.

The envelope detection circuit 613F basically has the same configuration as the envelope detection circuit 613R. The envelope detection circuit 613F responds to the filtered second reception pulse signal S13F to generate the second positive envelope signal S14FP and the second negative envelope signal S14FN.

The addition circuit 614 includes transistors 614a to 614h and current sources 614i and a 614j. The transistors 614a to 614f each are, for example, a PNP transistor. The transistors 614g and 614h each are, for example, an NPN transistor.

The second voltage V2 is applied to a first end of the current source 614i. A second end of the current source 614i is connected to an emitter terminal of each of the transistors 614a and 614b. The first negative envelope signal S14RN is input to a base terminal of the transistor 614a. The second negative envelope signal S14FN is input to a base terminal of the transistor 614b. A collector terminal of the transistor 614a is connected to a collector terminal of the transistor 614f. A collector terminal of the transistor 614b is connected to a collector terminal of the transistor 614c.

The second voltage V2 is applied to an emitter terminal of each of the transistors 614c to 614f. A base terminal of each of the transistors 614c and 614d is connected to a collector terminal of the transistor 614d. A collector terminal of the transistor 614d is connected to a collector terminal of the transistor 614g. A base of each of the transistors 614e and 614f is connected to a collector terminal of the transistor 614e. A collector terminal of the transistor 614e is connected to a collector terminal of the transistor 614h. An emitter terminal of each of the transistors 614g and 614h is connected to a first end of the current source 614j. The second ground GND2 is connected to a second end of the current source 614j. The first positive envelope signal S14RP is input to a base terminal of the transistor 614g. The second positive envelope signal S14FP is input to a base terminal of the transistor 614h.

The addition circuit 614 outputs the first addition envelope signal S15R from a connection point of the collector terminal of each of the transistors 614b and 614c and outputs the second addition envelope signal S15F from a connection point of the collector terminal of each of the transistors 614a and 614f.

The input stage of the addition circuit 614 includes a differential pair of the transistors 614a and 614b and a differential pair of the transistors 614g and 614h. The transistors 614a, 614b, 614g, and 614h are each a bipolar transistor. Thus, the addition circuit 614 limits variations in offset and sensitivity as compared to the reception circuit 21 (refer to FIG. 15) using the nonlinear amplifiers 303R and 303F.

The addition circuit 614 in the modified example also cancels in-phase noise superimposed on each of the filtered first reception pulse signal S13R and the filtered second reception pulse signal S13F. This obtains high CMTI.

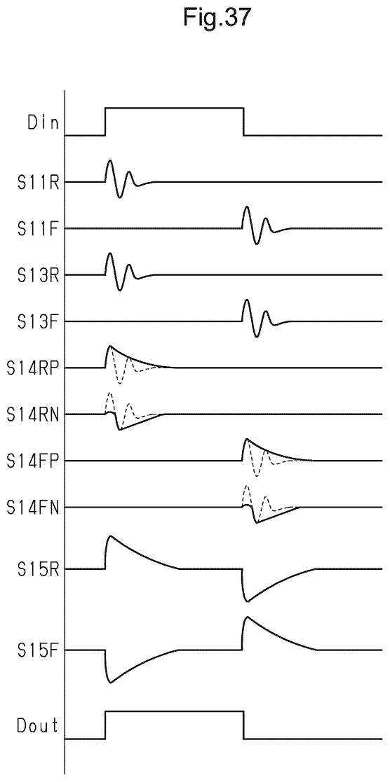

FIG. 37 is an example of signal transmission behavior in the signal transmission device 600 shown in FIG. 35. FIG. 37 shows, sequentially from above, the input pulse signal Din, the first transmission pulse signal S11R, the second transmission pulse signal S11F, the filtered first reception pulse signal S13R, the filtered second reception pulse signal S13F, the first positive envelope signal S14RP, the first negative envelope signal S14RN, the second positive envelope signal S14FP, the second negative envelope signal S14FN, the first addition envelope signal S15R, the second addition envelope signal S15F, and the output pulse signal Dout. The filtered first reception pulse signal S13R is indicated by broken lines on each of the first positive envelope signal S14RP and the first negative envelope signal S14RN. Also, the filtered second reception pulse signal S13F is indicated by broken lines on each of the second positive envelope signal S14FP and the second negative envelope signal S14FN.

When the input pulse signal Din rises from the low level to the high level, the first transmission pulse signal S11R is generated. The filtered first reception pulse signal S13R oscillates positively and negatively, and the first positive envelope signal S14RP and the first negative envelope signal S14RN are each generated.

When the input pulse signal Din falls from the high level to the low level, the second transmission pulse signal S11F is generated. The filtered second reception pulse signal S13F oscillates positively and negatively, and the second positive envelope signal S14FP and the second negative envelope signal S14FN are generated.

The first addition envelope signal S15R has a voltage waveform obtained by inverting and adding the second positive envelope signal S14FP to the first positive envelope signal S14RP. The second addition envelope signal S15F has a voltage waveform obtained by inverting and adding the second negative envelope signal S14FN to the first negative envelope signal S14RN.

The logical level of the output pulse signal Dout switches in accordance with a comparison result of the difference value (=S15R−S15F) between the first addition envelope signal S15R and the second addition envelope signal S15F and a predetermined threshold value.

When the difference value (=S15R−S15F) between the first addition envelope signal S15R and the second addition envelope signal S15F is greater than the predetermined threshold value, the output pulse signal Dout rises from the low level to the high level.

When the difference value (=S15R−S15F) between the first addition envelope signal S15R and the second addition envelope signal S15F is less than the predetermined threshold value, the output pulse signal Dout falls from the high level to the low level.

In the envelope detection process and the comparison process, a positive envelope and a negative envelope of the filtered first reception pulse signal S13R and the filtered second reception pulse signal S13F, which oscillate positively and negatively, are separately detected and added together. This increases the signal amplitude, thereby obtaining high CMTI.

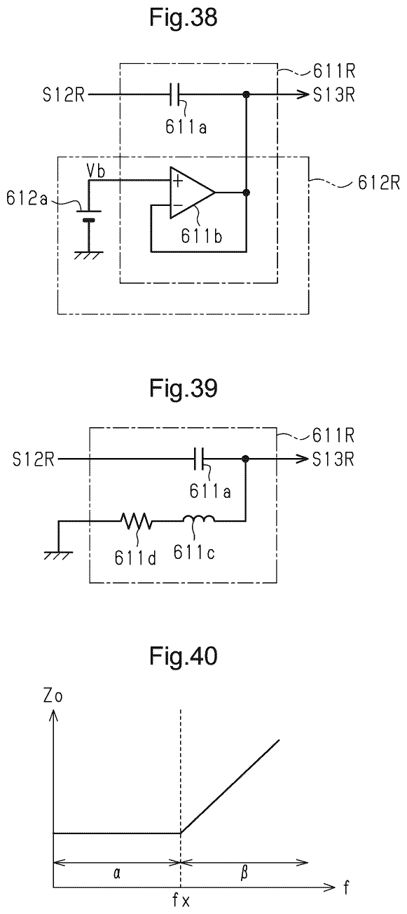

FIG. 38 shows an example of the configuration of the high-pass filter 611R and the DC bias circuit 612R. The high-pass filter 611R includes a capacitor 611a and a buffer circuit 611b. The buffer circuit 611b may be considered to be an element of the DC bias circuit 612R.

The first reception pulse signal S12R is input to a first end of the capacitor 611a. The buffer circuit 611b includes an output terminal connected to a second end of the capacitor 611a. The output terminal of the buffer circuit 611b is connected to an inverting input terminal of the buffer circuit 611b. The buffer circuit 611b includes a non-inverting input terminal connected to a positive terminal of a bias power supply 612a. The second ground GND2 is connected to a negative terminal of the bias power supply 612a. The bias power supply 612a applies a bias voltage Vb to the non-inverting input terminal of the buffer circuit 611b.

The high-pass filter 611F and the DC bias circuit 612F basically have the same configuration as described above and will not be described in detail.

FIG. 39 shows a circuit equivalent to the high-pass filter 611R. The buffer circuit 611b shown in FIG. 38 is equivalent to an output impedance model that includes an inductance 611c and a resistor 611d. The high-pass filter 611R may be considered to be a second-order LCR filter.

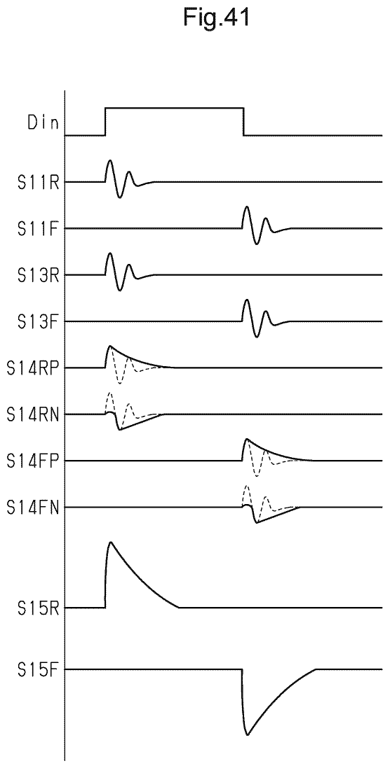

FIG. 40 shows the output impedance characteristic of the buffer circuit 611b. As shown in FIG. 40, the horizontal axis represents a frequency f, and the vertical axis represents an output impedance Zo of the buffer circuit 611μb.

In an in-phase noise bandwidth α where the frequency f is lower than a threshold value fx, the buffer circuit 611b acts as a resistive load in an in-phase noise region. The buffer circuit 611b has an output impedance Zo that is constant and independent from the frequency f. In an in-phase noise bandwidth β where the frequency f is greater than a threshold value fx, the buffer circuit 611b acts as an inductive load in an in-phase noise region. More specifically, the output impedance Zo of the buffer circuit 611b is increased as the frequency f increases.

In particular, to achieve high CMTI of the reception circuit 610, it is preferred that the high-pass filters 611R and 611F are combined with the DC bias circuits 612R and 612F (i.e., active pass filter).

The adding process of the addition circuit 614 may be changed.

FIG. 41 is a diagram showing a modified example of the adding process of the addition circuit 614. FIG. 41 shows, sequentially from above, the input pulse signal Din, the first transmission pulse signal S11R, the second transmission pulse signal S11F, the filtered first reception pulse signal S13R, the filtered second reception pulse signal S13F, the first positive envelope signal S14RP, the first negative envelope signal S14RN, the second positive envelope signal S14FP, the second negative envelope signal S14FN, the first addition envelope signal S15R, and the second addition envelope signal S15F. The filtered first reception pulse signal S13R is indicated by broken lines on each of the first positive envelope signal S14RP and the first negative envelope signal S14RN. Also, the filtered second reception pulse signal S13F is indicated by broken lines on each of the second positive envelope signal S14FP and the second negative envelope signal S14FN.

The addition circuit 614 may invert and add the first negative envelope signal S14RN to the first positive envelope signal S14RP to generate the first addition envelope signal S15R. The addition circuit 614 may invert and add the second positive envelope signal S14FP to the second negative envelope signal S14FN to generate the second addition envelope signal S15F.

In this adding process, in the same manner as the adding process shown in FIG. 37, a positive envelope and a negative envelope of the filtered first reception pulse signal S13R and the filtered second reception pulse signal S13F, which oscillate positively and negatively, are separately detected and added. This increases the signal amplitude to obtain high CMTI. When this modified example is applied, the comparison circuit 615 may be a single-input comparator.

Although not shown, when it is sufficient to transmit only one of the rising edge and the falling edge of the input pulse signal Din, one of the first reception pulse signal S12R and the second reception pulse signal S12F may be a fixed value (=DC bias value).

The first support member 210 and the second support member 220 may be changed.

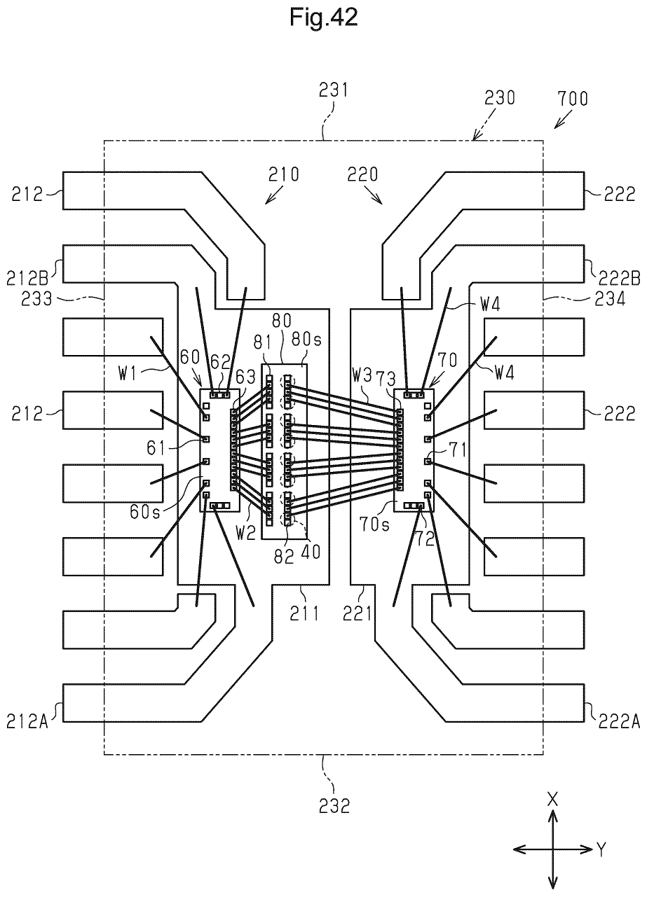

FIG. 42 is a schematic plan view showing the configuration of a signal transmission device 700 in a modified example. The signal transmission device 700 of the modified example differs in the shapes of the first support member 210 and the second support member 220 from the signal transmission device 100 shown in FIG. 2. The first die pad 211 is connected to the first lead terminal 212A and a first lead terminal 212B located at a side of the first die pad 211 opposite from the first lead terminal 212 in the X-direction. The first die pad 211 and the first lead terminals 212A and 212B are formed integrally as an integrated structure. As viewed in the Y-direction, the first die pad 211 is located between the first lead terminals 212A and 212B.

In the same manner, the second die pad 221 is connected to the second lead terminal 222A and a second lead terminal 222B located at a side of the second die pad 221 opposite from the second lead terminal 222A in the X-direction. The second die pad 221 and the second lead terminals 222A and 222B are formed integrally as an integrated structure. As viewed in the Y-direction, the second die pad 221 is located between the second lead terminals 222A and 222B.

In the process of manufacturing the signal transmission device 700, the first die pad 211 is supported by two first lead terminals 212A and 212B. Thus, the first circuit chip 60 and the isolation chip 80 are readily mounted on the first die pad 211. The second die pad 221 is supported by the two second lead terminals 222A and 222B. Thus, the second circuit chip 70 is readily mounted on the second die pad 221.

The configuration of the signal transmission device may be changed.

Multiple isolation chips may be used to transmit a signal between the first circuit chip 60 and the second circuit chip 70.

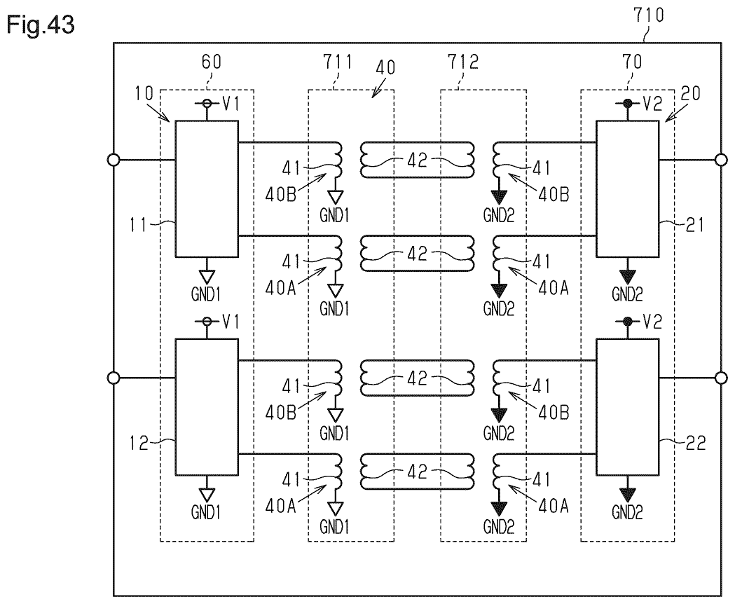

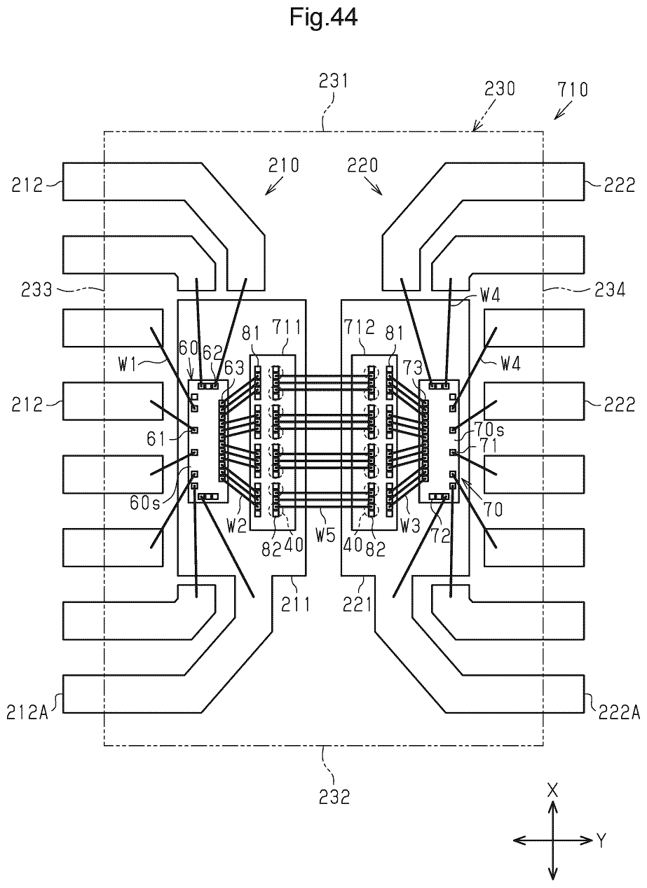

FIG. 43 shows an example of the electrical configuration of a signal transmission device 710 in a modified example. FIG. 44 shows the schematic configuration of the signal transmission device 710 shown in FIG. 43.

The signal transmission device 710 includes the first circuit chip 60, the second circuit chip 70, and second isolation chips 711 and 712. In an example, the two isolation chips 711 and 712 have the same configuration as the isolation chip 80. A pulse signal is output from the transmission circuit 11 in the first circuit chip 60 and is transmitted to the reception circuit 21 of the second circuit chip 70 through the transformers 40A and 40B of the first isolation chip 711 and the transformers 40A and 40B of the second isolation chip 712. A pulse signal is output from the transmission circuit 22 in the second circuit chip 70 and is transmitted to the reception circuit 12 of the first circuit chip 60 through the transformers 40A and 40B of the second isolation chip 712 and the transformers 40A and 40B of the first isolation chip 711.

As shown in FIG. 44, the first circuit chip 60, the first isolation chip 711, the second isolation chip 712, and the second circuit chip 70 are separated from each other in the Y-direction. The first circuit chip 60, the first isolation chip 711, the second isolation chip 712, and the second circuit chip 70 are arranged in the X-direction, in which the first die pad 211 and the second die pad 221 are arranged. In the modified example shown in FIG. 44, the first circuit chip 60, the first isolation chip 711, the second isolation chip 712, and the second circuit chip 70 are arranged in this order from the first lead terminals 212 toward the second lead terminals 222.

The first circuit chip 60 and the first isolation chip 711 are mounted on the first die pad 211 of the first support member 210. The second circuit chip 70 and the second isolation chip 712 are mounted on the second die pad 221 of the second support member 220.

The first electrodes 81 of the second isolation chip 712 are electrically connected to the second circuit chip 70 by wires W3. The second electrodes 82 of the second isolation chip 712 are electrically connected to the second electrodes 82 of the first isolation chip 711 by wires W5. The first isolation chip 711 and the second isolation chip 712 are connected to each other in series between the first circuit chip 60 and the second circuit chip 70.

The second isolation chip 712 has the same configuration as the first isolation chip 711. Thus, the second isolation chip 712 and the first isolation chip 711 have a similar breakdown voltage. The signal transmission device 710 has a breakdown voltage corresponding to the breakdown voltages of the first isolation chip 711 and the second isolation chip 712, which are connected in series.

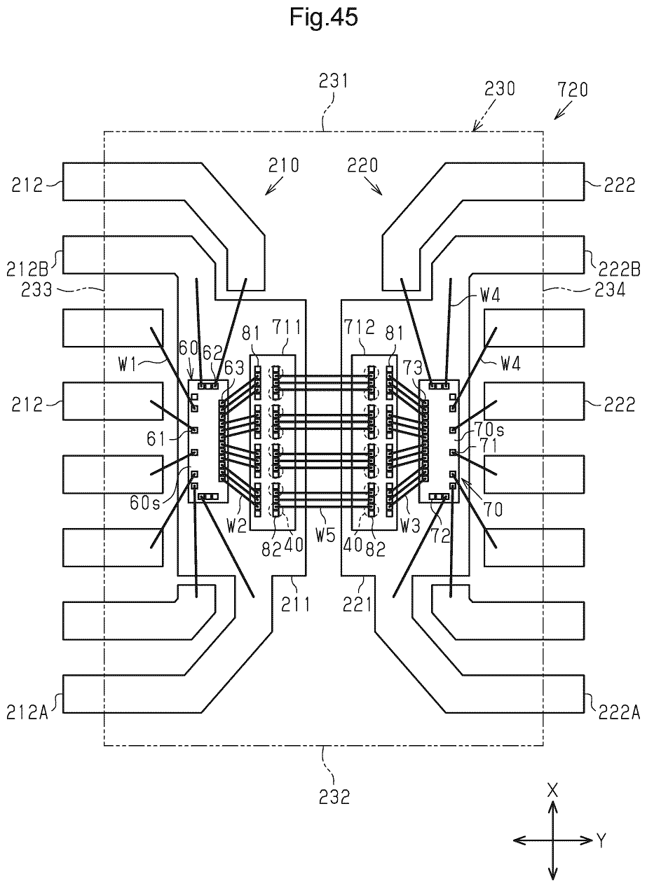

As shown in FIG. 45, a signal transmission device 720 differs in the shapes of the first support member 210 and the second support member 220 from the signal transmission device 710 shown in FIG. 44. The first die pad 211 may be connected to the two first lead terminals 212A and 212B. The second die pad 221 may be connected to the two second lead terminals 222A and 222B.

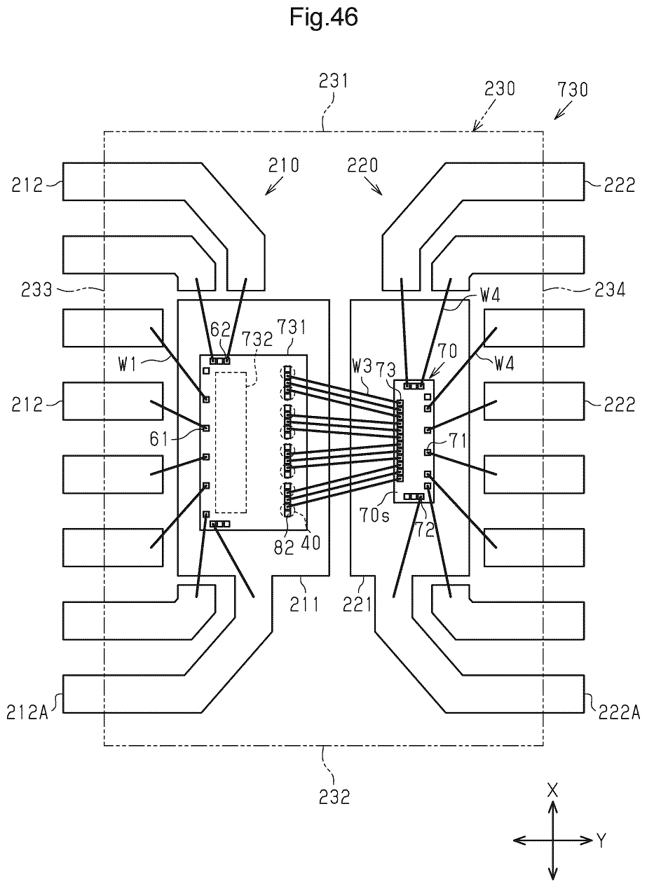

FIG. 46 shows a signal transmission device 730 that includes an isolation chip 731 mounted on the first die pad 211 and the second circuit chip 70 mounted on the second die pad 221. The isolation chip 731 includes a first circuit 732 and the multiple transformers 40. In an example, the first circuit 732 may include the transmission circuit 11 and the reception circuit 12 shown in FIG. 1. The isolation chip 731 includes the first electrodes 61, the second electrodes 62, and the second electrodes 82 in the same manner as the first circuit chip 60 and the isolation chip 80 shown in FIG. 2. The isolation chip 731 may include the third electrodes 63 and the first electrodes 81 shown in FIG. 2. In the signal transmission device 730, the isolation chip 731 and the second circuit chip 70 are mounted on the first die pad 211 and the second die pad 221, respectively. This simplifies the mounting. In addition, the isolation chip 731 includes the transformers 40 and the first circuit 732. This eliminates the need for the wires W2 shown in FIG. 2.

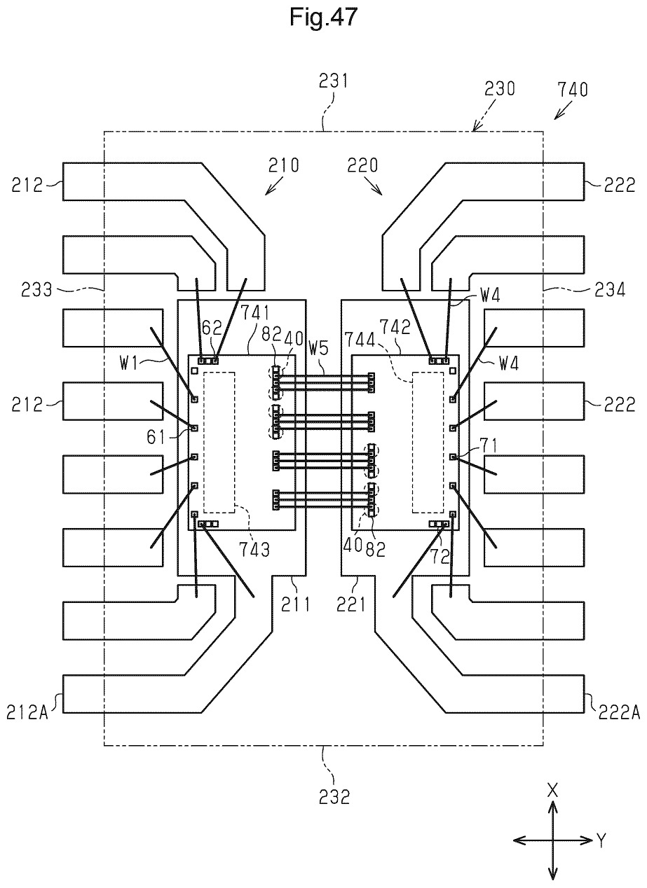

FIG. 47 shows a signal transmission device 740 that includes a first isolation chip 741 mounted on the first die pad 211 and a second isolation chip 742 mounted on the second die pad 221. The first isolation chip 741 includes a first circuit 743 and the multiple transformers 40. In an example, the first circuit 743 may include the transmission circuit 11 and the reception circuit 12 shown in FIG. 1. The first isolation chip 741 includes the first electrodes 61, the second electrodes 62, the first electrodes 81, and the second electrodes 82 in the same manner as the first circuit chip 60 and the isolation chip 80 shown in FIG. 2. The first isolation chip 741 may include the third electrodes 63 of the first circuit chip 60 shown in FIG. 2.

The second isolation chip 742 includes the second circuit 744 and the multiple transformers 40. In an example, the second circuit 744 may include the reception circuit 21 and the transmission circuit 22 shown in FIG. 1. The second isolation chip 742 includes the first electrodes 71, the second electrodes 72, the first electrodes 81, and the second electrodes 82 in the same manner as the second circuit chip 70 and the isolation chip 80 shown in FIG. 2. The second isolation chip 742 may include the third electrodes 73 of the second circuit chip 70 shown in FIG. 2.

In the signal transmission device 740, the first isolation chip 741 and the second isolation chip 742 are mounted on the first die pad 211 and the second die pad 221, respectively. This simplifies the mounting. In addition, the first isolation chip 741 includes the transformers 40 and the first circuit 743. The second isolation chip 742 includes the transformers 40 and the second circuit 744. This eliminates the need for the wires W2 and W3 shown in FIG. 44.

In the present disclosure, the term “on” includes the meaning of “above” in addition to the meaning of “on” unless otherwise clearly indicated in the context. Accordingly, a phrase such as “first layer formed on second layer” may mean that the first layer is formed directly contacting the second layer in one embodiment and that the first layer is located above the second layer without contacting the second layer in another embodiment. Thus, the word “on” will also allow for a structure in which another layer is arranged between the first layer and the second layer.

The Z-axis direction as referred to in the present disclosure does not necessarily have to be the vertical direction and does not necessarily have to fully conform to the vertical direction. In the structures according to the present disclosure (e.g., the structure shown in FIG. 1), “upward” and “downward” in the Z-axis direction as referred to in the present description are not limited to “upward” and “downward” in the vertical direction. For example, the X-axis direction may be the vertical direction. Alternatively, the Y-axis direction may be the vertical direction.

### CLAUSES

Technical concepts that can be understood from each of the above embodiments and modified examples will now be described. It should be noted that, for the purpose of facilitating understanding with no intention to limit, elements described in clauses are given the reference characters of the corresponding elements of the embodiments. The reference signs are used as examples to facilitate understanding, and the elements in each clause are not limited to those elements given with the reference signs.
[Clause A1] An isolation chip, including:
an insulation layer (84) having an upper surface (84s) and a lower surface (84r) facing opposite directions in a thickness-wise direction;
a first coil (41) arranged in the insulation layer (84) closer to the lower surface than to the upper surface;
a second coil (42) arranged in the insulation layer (84) closer to the upper surface than to the lower surface and opposed to the first coil (41) in the thickness-wise direction;
a first electrode (81) formed on the upper surface of the insulation layer (84) and electrically connected to the first coil (41);
a second electrode (82) formed on the upper surface of the insulation layer (84) and electrically connected to the second coil (42); and
a passivation film (160) formed on the upper surface of the insulation layer (84), in which
the second coil (42) is annular in plan view as viewed in the thickness-wise direction,
the second electrode (82) includes a second inner electrode (82A) extending over an inner region (42A) surrounded by the second coil (42) and a region overlapping the second coil (42) in plan view,
the passivation film (160) includes a second opening (163) at least partially exposing the second inner electrode (82A), and
the second opening (163) extends above the second inner electrode (82A), and over the inner region (42A) and the region overlapping the second coil (42).
[Clause A2] The isolation chip according to clause A1, in which the second opening (163) is one of two or more second openings separated from each other in a first direction and extending above the second inner electrode (82A), and over the inner region (42A) and the region overlapping the second coil (42).
[Clause A3] The isolation chip according to clause A2, in which the second inner electrode (82A) extends out from opposite sides of the inner region (42A) in the first direction and is continuous from one end to another end of the second inner electrode (82A).
[Clause A4] The isolation chip according to clause A2 or A3, in which the second inner electrode (421) includes a narrow portion (424) arranged between two of the second openings (163), and the narrow portion (424) is less in width than a portion of the second inner electrode (421) where the second opening (163) is formed.
[Clause A5] The isolation chip according to clause A4, in which the narrow portion (424) is displaced from a center of the second coil (42).
[Clause A6] The isolation chip according to any one of clauses A1 to A5, in which
the second inner electrode (82A) is one of multiple second inner electrodes (82A) separated from each other in a first direction, and
the second opening (163) is one of multiple second openings (163) separated from each other in accordance with the multiple second inner electrodes (82A).
[Clause A7] The isolation chip according to any one of clauses A1 to A6, in which
the second inner electrode (82A) includes a first region (82A1) overlapping the inner region (42A) and a second region (82A2) overlapping the second coil (42) in plan view, and
the second region (82A2) is greater in area than the first region (82A1).
[Clause A8] The isolation chip according to any one of clauses A1 to A7, in which the second coil (42) has a circular spiral shape.
[Clause A9] The isolation chip according to any one of clauses A1 to A8, in which
the second coil (42) is one of multiple second coils (42) separated from each other in a first direction,
the second electrode includes a second outer electrode (82C) arranged on the upper surface of the insulation layer (84) between the second coils (42), and
the second outer electrode (82C) is sandwiched between the second coils (42).
[Clause A10] The isolation chip according to any one of clauses A1 to A9, in which
the first coil (41) has a circular spiral shape in plan view as viewed in the thickness-wise direction, and
the first electrode (81) is arranged on the upper surface of the insulation layer (84) at a position separated from the second coil (42) in a second direction orthogonal to the first direction.
[Clause A11] The isolation chip according to any one of clauses A1 to A10, including:
a dummy wire (150) surrounding the second coil (42).
[Clause A12] The isolation chip according to any one of clauses A1 to A11, further including:
a circuit (732, 742) electrically connected to the first coil (41).
[Clause A13] A signal transmission device, including:
a first die pad (211);
a first isolation chip (80) mounted on the first die pad; and
an encapsulation resin encapsulating the first die pad and the first isolation chip, in which
the first isolation chip includes
   an insulation layer (84) having an upper surface and a lower surface facing opposite directions in a thickness-wise direction,
   a first coil (41) arranged in the insulation layer (84) closer to the lower surface than to the upper surface,
   a second coil (42) arranged in the insulation layer (84) closer to the upper surface than to the lower surface and opposed to the first coil (41) in the thickness-wise direction,
   a first electrode (81) formed on the upper surface of the insulation layer (84) and electrically connected to the first coil (41),
   a second electrode (82) formed on the upper surface of the insulation layer (84) and electrically connected to the second coil (42), and
   a passivation film (160) formed on the upper surface of the insulation layer (84),
the second coil (42) is annular in plan view as viewed in the thickness-wise direction,
the second electrode includes a second inner electrode (82A) extending over an inner region (42A) surrounded by the second coil (42) and a region overlapping the second coil (42) in plan view,
the passivation film (160) includes a second opening (163) at least partially exposing the second inner electrode (82A), and
the second opening (163) extends above the second inner electrode (82A), and over the inner region (42A) and the region overlapping the second coil (42).
[Clause A14] The signal transmission device according to clause A13, including:
a first circuit chip (60) mounted on the first die pad; and
in which the first circuit chip includes a first circuit (10) electrically connected to the first coil (41).
[Clause A15] The signal transmission device according to clause A13, in which the first isolation chip includes a first circuit (10) electrically connected to the first coil (41).
[Clause A16] The signal transmission device according to any one of clauses A13 to A15, including:
a second die pad (221) arranged separately from the first die pad; and
a second circuit chip (70) mounted on the second die pad,
in which the second circuit chip includes a second circuit (20) electrically connected to the second coil (42).
[Clause A17] The signal transmission device according to any one of clauses A13 to A15, including:
a second die pad (221) arranged separately from the first die pad; and
a second isolation chip mounted on the second die pad, in which
the second isolation chip includes
   an insulation layer having an upper surface and a lower surface facing opposite directions in a thickness-wise direction,
   a first coil arranged in the insulation layer closer to the lower surface than to the upper surface,
   a second coil arranged in the insulation layer closer to the upper surface than to the lower surface and opposed to the first coil in the thickness-wise direction,
   a first electrode formed on the upper surface of the insulation layer and electrically connected to the first coil,
   a second electrode formed on the upper surface of the insulation layer and electrically connected to the second coil, and
   a passivation film formed on the upper surface of the insulation layer,
the second coil of the second isolation chip is annular in plan view as viewed in the thickness-wise direction,
the second electrode of the second isolation chip includes a second inner electrode extending over an inner region surrounded by the second coil of the second isolation chip and a region overlapping the second coil of the second isolation chip in plan view,
the passivation film of the second isolation chip includes a second opening at least partially exposing the second inner electrode of the second isolation chip,
the second opening of the second isolation chip extends above the second inner electrode of the second isolation chip, and over the inner region of the second isolation chip and the region overlapping the second coil of the second isolation chip, and
the second coil (42) of the second isolation chip is electrically connected to the second coil (42) of the first isolation chip.
[Clause A18] The signal transmission device according to clause A17, including:
a second circuit chip mounted on the second die pad,
in which the second circuit chip includes a second circuit electrically connected to the first coil (41) of the second isolation chip.
[Clause A19] The signal transmission device according to clause A18, in which the second isolation chip includes a second circuit (744) electrically connected to the first coil (41) of the second isolation chip.
[Clause A20] The signal transmission device according to any one of clauses A16 to A19, including:
multiple first lead terminals arranged along a first side surface of the encapsulation resin,
in which the first die pad is sandwiched between two of the first lead terminals and is connected to at least one of the two of the first lead terminals.
[Clause A21] The signal transmission device according to clause A20, including:
multiple second lead terminals arranged along a second side surface opposite to the first side surface,
in which the second die pad is sandwiched between two of the second lead terminals and is connected to at least one of the two of the second lead terminals.
[Clause A22] The signal transmission device according to clause A14, in which
the first circuit chip includes
   a grounding pad, and
   a first ground wire and a second ground wire electrically connected to the grounding pad, each of the first ground wire and the second ground wire being laid out in a different path,
the first circuit includes a transmission circuit outputting a signal to the first isolation chip and a reception circuit receiving a signal from the first isolation chip,
the reception circuit is electrically connected to the first ground wire, and
the transmission circuit is electrically connected to the second ground wire.
[Clause A23] The signal transmission device according to clause A22, further including:
a third ground wire electrically connected to the grounding pad and laid out in a path differing from the path of the first ground wire and the path of the second ground wire;
a signal pad electrically connected to the transmission circuit or the reception circuit; and
a ground pad electrically connected to the third ground wire,
in which the signal pad and the ground pad are electrically connected to the first electrode (81) of the first isolation chip.
[Clause A24] The signal transmission device according to clause A14, in which
the first circuit chip includes
   a signal pad and a ground pad electrically connected to the first electrode (81) of the first isolation chip,
   a grounding pad, and
   a first ground wire and a second ground wire electrically connected to the grounding pad, each of the first ground wire and the second ground wire being laid out in a different path,
the signal pad is electrically connected to the first circuit,
the first circuit is electrically connected to the first ground wire, and
the ground pad is electrically connected to the second ground wire.
[Clause A25] The signal transmission device according to clause A24, in which the first circuit includes a transmission circuit outputting a signal to the signal pad.
[Clause A26] The signal transmission device according to clause A24, in which the first circuit includes a reception circuit receiving a signal from the signal pad.
[Clause A27] The signal transmission device according to clause A24, in which
the signal pad includes a transmission pad and a reception pad,
the first circuit includes a transmission circuit outputting a signal to the transmission pad and a reception circuit receiving a signal from the reception pad,
the first ground wire includes a transmission ground wire and a reception ground wire each laid out in a different path,
the transmission circuit is electrically connected to the transmission ground wire, and
the reception circuit is electrically connected to the reception ground wire.
[Clause B1] A reception circuit, including:
a first envelope detection circuit configured to generate a first positive envelope signal and a first negative envelope signal from a first reception signal;
a second envelope detection circuit configured to generate a second positive envelope signal and a second negative envelope signal from a second reception signal;
an addition circuit configured to receive the first positive envelope signal, the first negative envelope signal, the second positive envelope signal, and the second negative envelope signal to generate a first addition envelope signal and a second addition envelope signal; and
a comparison circuit configured to receive the first addition envelope signal and the second addition envelope signal to generate an output pulse signal.
[Clause B2] The reception circuit according to clause B1, including a DC bias circuit configured to set a DC bias for each of the first reception signal and the second reception signal.
[Clause B3] The reception circuit according to clause B2, in which
the first reception signal oscillates positively and negatively with respect to the DC bias, and
the second reception signal oscillates positively and negatively with respect to the DC bias.
[Clause B4] The reception circuit according to clause B2, in which
the first reception signal oscillates positively and negatively with respect to the DC bias, and
the second reception signal has a fixed value.
[Clause B5] The reception circuit according to any one of clauses B1 to B4, in which the addition circuit inverts and adds the second positive envelope signal to the first positive envelope signal to generate the first addition envelope signal and inverts and adds the second negative envelope signal to the first negative envelope signal to generate the second addition envelope signal.
[Clause B6] The reception circuit according to any one of clauses B1 to B4, in which the addition circuit inverts and adds the first negative envelope signal to the first positive envelope signal to generate the first addition envelope signal and inverts and adds the second positive envelope signal to the second negative envelope signal to generate the second addition envelope signal.
[Clause B7] The reception circuit according to any one of clauses B1 to B6, including:
a high-pass filter configured to be arranged at a preceding stage of the first envelope detection circuit to output the first reception signal; and
a high-pass filter configured to be arranged at a preceding stage of the second envelope detection circuit to output the second reception signal.
[Clause B8] The reception circuit according to any one of clauses B1 to B7, in which each of the first envelope detection circuit and the second envelope detection circuit includes one of an emitter follower and a source follower and a capacitor connected to an output end of the one of the emitter follower and the source follower.
[Clause B9] The reception circuit according to clause B8, in which the capacitor includes a parasitic capacitor.
[Clause B10] The reception circuit according to any one of clauses B1 to B9, in which an input stage of the addition circuit includes a differential pair formed of bipolar transistors.
[Clause B11] The reception circuit according to any one of clauses B1 to B10, in which the comparison circuit includes a hysteresis comparator configured to compare a difference value between the first addition envelope signal and the second addition envelope signal with a predetermined threshold value to generate the output pulse signal.
[Clause B12] A reception circuit, including:
an envelope detection circuit configured to generate a positive envelope signal and a negative envelope signal from a reception signal;
an addition circuit configured to receive the positive envelope signal and the negative envelope signal to generate an addition envelope signal; and
a comparison circuit configured to compare the addition envelope signal and a predetermined threshold value to generate an output pulse signal.
[Clause B13] A signal transmission device, including:
a transmission circuit (11) configured to receive an input pulse signal and generate a transmission pulse signal;
the reception circuit (21) according to any one of clauses B1 to B12, the reception circuit (21) being configured to receive a reception pulse signal and generate the output pulse signal; and
a transformer (40) configured to transmit the transmission pulse signal as the reception pulse signal while insulating the transmission circuit and the reception circuit.

The description above illustrates examples. One skilled in the art may recognize further possible combinations and replacements of the components and methods (manufacturing processes) in addition to those listed for purposes of describing the techniques of the present disclosure. All replacements, modifications, and variations within the scope of the claims are intended to be encompassed in the present disclosure.

What is claimed is:

1. An isolation chip, comprising:
an insulation layer having an upper surface and a lower surface facing opposite directions in a thickness-wise direction;
a first coil arranged in the insulation layer closer to the lower surface than to the upper surface;
a second coil arranged in the insulation layer closer to the upper surface than to the lower surface and opposed to the first coil in the thickness-wise direction;
a first electrode formed on the upper surface of the insulation layer and electrically connected to the first coil;
a second electrode formed on the upper surface of the insulation layer and electrically connected to the second coil; and
a passivation film formed on the upper surface of the insulation layer, wherein
the second coil is annular in plan view as viewed in the thickness-wise direction,
the second electrode includes a second inner electrode extending over an inner region surrounded by the second coil and a region overlapping the second coil in plan view,
the passivation film includes a second opening at least partially exposing the second inner electrode, and
the second opening extends above the second inner electrode, and over the inner region and the region overlapping the second coil.

2. The isolation chip according to claim 1, wherein the second opening is one of two or more second openings separated from each other in a first direction and extending above the second inner electrode, and over the inner region and the region overlapping the second coil.

3. The isolation chip according to claim 2, wherein the second inner electrode extends out from opposite sides of the inner region in the first direction and is continuous from one end to another end of the second inner electrode.

4. The isolation chip according to claim 2, wherein
the second inner electrode includes a narrow portion arranged between two of the second openings, and
the narrow portion is less in width than a portion of the second inner electrode where the second opening is formed.

5. The isolation chip according to claim 4, wherein the narrow portion is displaced from a center of the second coil.

6. The isolation chip according to claim 1, wherein
the second inner electrode is one of multiple second inner electrodes separated from each other in a first direction, and
the second opening is one of multiple second openings separated from each other in accordance with the multiple second inner electrodes.

7. The isolation chip according to claim 1, wherein
the second inner electrode includes a first region overlapping the inner region and a second region overlapping the second coil in plan view, and
the second region is greater in area than the first region.

8. The isolation chip according to claim 1, wherein the second coil has a circular spiral shape.

9. The isolation chip according to claim 1, wherein
the second coil is one of multiple second coils separated from each other in a first direction,
the second electrode includes a second outer electrode arranged on the upper surface of the insulation layer between the second coils, and
the second outer electrode is sandwiched between the second coils.

10. The isolation chip according to claim 1, wherein
the first coil has a circular spiral shape in plan view as viewed in the thickness-wise direction, and
the first electrode is arranged on the upper surface of the insulation layer at a position separated from the second coil in a second direction orthogonal to the first direction.

11. The isolation chip according to claim 1, comprising:
a dummy wire surrounding the second coil.

12. The isolation chip according to claim 1, further comprising:
a circuit electrically connected to the first coil.

13. A signal transmission device, comprising:
a first die pad;
a first isolation chip mounted on the first die pad; and
an encapsulation resin encapsulating the first die pad and the first isolation chip, wherein
the first isolation chip includes
an insulation layer having an upper surface and a lower surface facing opposite directions in a thickness-wise direction,
a first coil arranged in the insulation layer closer to the lower surface than to the upper surface,
a second coil arranged in the insulation layer closer to the upper surface than to the lower surface and opposed to the first coil in the thickness-wise direction,
a first electrode formed on the upper surface of the insulation layer and electrically connected to the first coil,
a second electrode formed on the upper surface of the insulation layer and electrically connected to the second coil, and
a passivation film formed on the upper surface of the insulation layer,
the second coil is annular in plan view as viewed in the thickness-wise direction,
the second electrode includes a second inner electrode extending over an inner region surrounded by the second coil and a region overlapping the second coil in plan view,
the passivation film includes a second opening at least partially exposing the second inner electrode, and
the second opening extends above the second inner electrode, and over the inner region and the region overlapping the second coil.

14. The signal transmission device according to claim 13, comprising:
a first circuit chip mounted on the first die pad; and
wherein the first circuit chip includes a first circuit electrically connected to the first coil.

15. The signal transmission device according to claim 13, wherein the first isolation chip includes a first circuit electrically connected to the first coil.

16. The signal transmission device according to claim 13, comprising:
a second die pad arranged separately from the first die pad; and
a second circuit chip mounted on the second die pad,
wherein the second circuit chip includes a second circuit electrically connected to the second coil.

17. The signal transmission device according to claim 13, comprising:
a second die pad arranged separately from the first die pad; and
a second isolation chip mounted on the second die pad, wherein
the second isolation chip includes
an insulation layer having an upper surface and a lower surface facing opposite directions in a thickness-wise direction,
a first coil arranged in the insulation layer closer to the lower surface than to the upper surface,
a second coil arranged in the insulation layer closer to the upper surface than to the lower surface and opposed to the first coil in the thickness-wise direction,
a first electrode formed on the upper surface of the insulation layer and electrically connected to the first coil,
a second electrode formed on the upper surface of the insulation layer and electrically connected to the second coil, and
a passivation film formed on the upper surface of the insulation layer,
the second coil of the second isolation chip is annular in plan view as viewed in the thickness-wise direction,
the second electrode of the second isolation chip includes a second inner electrode extending over an inner region surrounded by the second coil of the second isolation chip and a region overlapping the second coil of the second isolation chip in plan view,
the passivation film of the second isolation chip includes a second opening at least partially exposing the second inner electrode of the second isolation chip,
the second opening of the second isolation chip extends above the second inner electrode of the second isolation chip, and over the inner region of the second isolation chip and the region overlapping the second coil of the second isolation chip, and
the second coil of the second isolation chip is electrically connected to the second coil of the first isolation chip.

18. The signal transmission device according to claim 17, comprising:
a second circuit chip mounted on the second die pad,
wherein the second circuit chip includes a second circuit electrically connected to the first coil of the second isolation chip.

19. The signal transmission device according to claim 18, wherein the second isolation chip includes a second circuit electrically connected to the first coil of the second isolation chip.
